(19) United States
(12) Patent Application Publication
(10) Pub. No.: US 2012/0208124 A1
(43) Pub. Date: Aug. 16, 2012

(54) RESIST COMPOSITION FOR EUV, METHOD FOR PRODUCING RESIST COMPOSITION FOR EUV, AND METHOD OF FORMING RESIST PATTERN

(75) Inventors: Jun Iwashita, Kawasaki-shi (JP); Kenri Konno, Kawasaki-shi (JP)

(73) Assignee: Tokyo Ohka Kogyo Co., Ltd., Kawasaki-shi (JP)

(21) Appl. No.: 13/366,718

(22) Filed: Feb. 6, 2012

(30) Foreign Application Priority Data
Feb. 10, 2011 (JP) 2011-027589

(51) Int. Cl. G03F 7/20; G03F 7/004

(52) U.S. Cl. 430/270.1; 430/325

(57) ABSTRACT

The present invention is related to a resist composition for EUV exhibiting E0_{KrF} greater than E0_{EUV}, wherein E0_{KrF} is a sensitivity to KrF light of 248 nm, and E0_{EUV} is a sensitivity to EUV light, and a method of producing a resist composition for EUV including preparing the resist composition so that E0_{KrF} is greater than E0_{EUV}, and a method of forming a resist pattern, including: applying the resist composition for EUV to a substrate to form a resist film on the substrate; conducting EUV exposure of the resist film; and developing the resist film to form a resist pattern.

According to the present invention, a resist composition for EUV exhibiting excellent lithography properties and pattern shape in EUV lithography, a method of producing the resist composition for EUV, and a method of forming a resist pattern that uses the resist composition for EUV can be provided.

### BACKGROUND OF THE INVENTION

1. Field of the Invention

The present invention relates to a resist composition for processes using extreme ultraviolet (EUV) radiation (namely, a resist composition for EUV), a method of producing the resist composition for EUV, and a method of forming a resist pattern that uses the resist composition for EUV.

Priority is claimed on Japanese Patent Application No. 2011-027589, filed Feb. 10, 2011, the content of which is incorporated herein by reference.

2. Description of Related Art

In recent years, in the production of semiconductor elements and liquid crystal display elements, advances in lithography techniques have led to rapid progress in the field of pattern miniaturization.

Typically, these miniaturization techniques involve shortening the wavelength of the exposure light source. Conventionally, ultraviolet radiation typified by g-line and i-line radiation has been used, but nowadays KrF excimer lasers and ArF excimer lasers are now starting to be introduced in mass production. Furthermore, research is also being conducted into lithography techniques that use an exposure light source having a wavelength shorter than these excimer lasers, such as electron beam (EB), EUV, and X-ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified resist composition is used, which includes a base component that exhibits a changed solubility in a developing solution under the action of acid and an acid generator component that generates acid upon exposure.

For example, in the case where the above developing solution is an alkali developing solution (alkali developing process), a chemically amplified positive resist composition which contains a resin component (base resin) that exhibits increased solubility in an alkali developing solution under the action of acid, and an acid generator component is typically used. If the resist film formed using this resist composition is selectively exposed during formation of a resist pattern, then acid is generated from the acid generator component within the exposed portions, and the action of this acid causes an increase in the solubility of the resin component in an alkali developing solution, making the exposed portions soluble in the alkali developing solution. In this manner, the unexposed portions remain to form a positive resist pattern. Here, a resin that exhibits increased polarity by the action of acid has been used as the base resin, and the solubility in an alkali developing solution increases while the solubility in an organic solvent reduces. For this reason, when such a base resin is applied to a process using a developing solution containing an organic solvent (organic developing solution) (hereafter, this process is sometimes referred to as a “solvent developing process” or “negative developing process”) instead of an alkali developing process, the solubility of the exposed portions in an organic developing solution is relatively reduced. As a result, in the solvent developing process, the unexposed portions of the resist film are dissolved and removed by the organic developing solution, and a negative resist pattern in which the exposed portions are remaining is formed. For example, a negative developing process has been proposed in Patent Document 1.

In recent years, attempts have been made to form a resist pattern by using EB or EUV as the exposure light source, in order to form extremely fine patterns of several tens of nanometers. Particularly in EUV lithography, since the optical mechanism of the exposure apparatus and the reaction mechanism of the resist are different from those of lithography processes using other exposure light sources, development of resist materials for EUV has been demanded.

In the EUV exposure apparatus, the EUV light serving as pattern light is split from the continuous light emitted from the plasma light source using a reflective mirror made of a Mo/Si multilayer film that exhibits a local maximum of reflectance to the EUV light, and is irradiated onto a wafer through a reflective optical system using a plurality of reflective mirrors. Because the plurality of reflective mirrors also exhibit reflective properties to the light having a different wavelength from the exposure wavelength of EUV light, unintended light having a wavelength different from that of EUV light (namely, out of band light (OoB light)) may be irradiated onto a substrate. When a resist is exposed using the OoB light, the image contrast deteriorates and the quality of transferred images is impaired. It has been reported in Non-patent Document 1 that an EUV resist that fully uses EUV photons while being insensitive to the OoB light is required for the formation of appropriate patterns.

In Non-patent Document 2, the sensitivity (OoB sensitivity) of a resist to the light having a wavelength within the range from 157 to 400 nm is estimated by measuring the absorption of each deep ultraviolet (DUV) light beam by the resist. Furthermore, from the aspect of apparatus, reduction of the OoB light has also been examined by applying a coating agent onto a mirror to be installed in a reflective optical system or by attaching a spectral purity filter (SPF) to a light source, although there is a concern for a decrease in the intensity of EUV light in these cases.

### DOCUMENTS OF RELATED ART

### Patent Document

[Patent Document 1] Japanese Unexamined Patent Application, First Publication No. 2008-292975

### Non-Patent Document

[Non-Patent Document 1] Proceedings of SPIE (U.S.), vol. 6921, 69213L-1 (2008)
[Non-Patent Document 2] Proceedings of SPIE (U.S.), vol. 7273, 72731W-1 (2009)

### SUMMARY OF THE INVENTION

Among the OoB light, the EUV lithography is adversely affected, in particular, by the DUV light having a wavelength from 150 to 300 nm. Because photoacid generators, in particular, onium salts exhibit absorption properties for DUV light, the image contrast on the wafer is reduced due to the exposure to DUV light, which results in poor lithography properties.

The present invention takes the above circumstances into consideration, with an object of providing a resist composition for EUV that exhibits low sensitivity to the DUV light and also exhibits high sensitivity to the EUV light, a method of producing the resist composition for EUV, and a method of forming a resist pattern that uses the resist composition for EUV.

For solving the above-mentioned problems, the present invention employs the following aspects.

That is, a first aspect of the present invention is a resist composition for EUV exhibiting E0_{KrF} greater than E0_{EUV}, wherein E0_{KrF} is a sensitivity to KrF light of 248 nm, and E0_{EUV} is a sensitivity to EUV light.

A second aspect of the present invention is a method of producing the resist composition for EUV according to the above first aspect, including: preparing the resist composition so that E0_{KrF} is greater than E0_{EUV}, wherein E0_{KrF} is a sensitivity to KrF light of 248 nm, and E0_{EUV} is a sensitivity to EUV light.

A third aspect of the present invention is a method of forming a resist pattern, including: applying the resist composition for EUV according to the first aspect to a substrate to form a resist film on the substrate; conducting EUV exposure of the resist film; and developing the resist film to form a resist pattern.

In the present specification, the term “alkyl group” includes linear, branched or cyclic, monovalent saturated hydrocarbon, unless otherwise specified.

The term “alkylene group” includes linear, branched or cyclic divalent saturated hydrocarbon, unless otherwise specified.

A “lower alkyl group” is an alkyl group of 1 to 5 carbon atoms.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

The term “aliphatic” is a relative concept used in relation to the term “aromatic”, and defines a group or compound that has no aromaticity.

The term “structural unit” refers to a monomer unit that contributes to the formation of a polymeric compound (polymer, copolymer).

The term “exposure” is used as a general concept that includes irradiation with any form of radiation.

The term “(meth)acrylic acid” is a generic term that includes either or both of acrylic acid having a hydrogen atom bonded to the α-position and methacrylic acid having a methyl group bonded to the α-position.

The term “(meth)acrylate ester” is a generic term that includes either or both of the acrylate ester having a hydrogen atom bonded to the α-position and the methacrylate ester having a methyl group bonded to the α-position.

The term “(meth)acrylate” is a generic term that includes either or both of the acrylate having a hydrogen atom bonded to the α-position and the methacrylate having a methyl group bonded to the α-position.

According to the present invention, there are provided a resist composition for EUV exhibiting excellent lithography properties and pattern shape in the EUV lithography, a method of producing the resist composition for EUV, and a method of forming a resist pattern that uses the resist composition for EUV.

### DETAILED DESCRIPTION OF THE INVENTION

### <<Resist Composition for EUV>>

A resist composition for EUV according to the first aspect of the present invention is a resist composition for EUV for forming a resist film used in EUV lithography, and exhibiting E0_{KrF} greater than E0_{EUV}, wherein E0_{KrF} is a sensitivity to KrF light of 248 nm, and E0_{EUV} is a sensitivity to EUV light.

The above E0_{KrF} and E0_{EUV} refer to the minimum exposure dose of KrF light and EUV light, respectively, which is required to completely dissolve the film of the aforementioned resist composition for EUV by exposure to the light of each wavelength (as well as post exposure baking (PEB) if necessary) and developing.

As described above, E0_{KrF} (which is a sensitivity to KrF light of 248 nm) refers to the minimum exposure dose of KrF light which is required for completely dissolving the aforementioned resist film by exposure using a KrF excimer laser of 248 nm (hereafter, referred to as KrF light), (as well as PEB if necessary) and developing.

Further, E0_{EUV} (which is a sensitivity to EUV light) refers to the minimum exposure dose of EUV light which is required for completely dissolving the aforementioned resist film by exposure using the EUV light, (as well as PEB if necessary) and developing.

The conditions for measuring this minimum exposure dose (hereafter, referred to as E0 sensitivity) will be described.

Firstly, a resist composition described later is applied onto a substrate to form a resist film.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

An inorganic film can be formed, for example, by coating an inorganic antireflection film composition such as a silicon-based material on a substrate, followed by baking.

An organic film can be formed, for example, by dissolving a resin component and the like for forming the film in an organic solvent to obtain an organic film forming material, coating the organic film forming material on a substrate using a spinner or the like, and baking under heating conditions preferably in the range of 200 to 300° C. for 30 to 300 seconds, more preferably for 60 to 180 seconds.

The thickness of the inorganic and/or organic film is preferably within the range from 30 to 500 nm, and more preferably from 30 to 100 nm.

The resist composition can be applied by a conventional method using a spinner or the like.

More specifically, the resist film can be formed by applying the resist composition onto a substrate using a spinner or the like, and vaporizing organic solvents by conducting a bake treatment (prebake) at a temperature of 80 to 150° C., preferably 80 to 110° C., for 40 to 120 seconds, preferably 60 to 90 seconds.

The thickness of the resist film is preferably within the range from 20 to 500 nm, and more preferably from 30 to 100 nm.

With respect to the wavelength of light used for exposure of the resist film, the KrF light of 248 nm is used in the measurement of E0_{KrF}, and the EUV light of 13.5 nm is used in the measurement of E0_{EUV}.

In order to measure the minimum exposure dose required for complete dissolution of the resist film, exposure is conducted by changing the exposure dose in a stepwise manner.

Following exposure, the resist film is subjected to a bake treatment (post exposure bake (PEB)) at a temperature of 80 to 150° C., preferably 80 to 110° C., for 40 to 120 seconds, preferably 60 to 90 seconds, and then to alkali developing using an aqueous solution of tetramethylammonium hydroxide (TMAH) having a concentration of, for example, 0.1 to 10% by weight, and preferably 1 to 5% by weight, thereby measuring the minimum exposure dose required for complete dissolution of the resist film.

Because the aforementioned E0_{KrF} is greater than the aforementioned E0_{EUV}, the resist composition for EUV according to the present invention can be provided with a property so as to exhibit low sensitivity to the DUV light and to also exhibit high sensitivity to the EUV light. Furthermore, in order to improve such a property, the aforementioned E0_{KrF} is preferably at least 1.2 times as large as the aforementioned E0_{EUV}.

The resist composition for EUV according to the present invention will be described below in more detail.

The resist composition for EUV according to the first aspect of the present invention preferably includes a base component (A) which exhibits changed solubility in a developing solution under the action of acid (hereafter, referred to as “component (A)”) and an acid generator component (B) which generates acid upon exposure (hereafter, referred to as “component (B)”).

With respect to a resist film formed using the resist composition, when a selective exposure is conducted during formation of a resist pattern, acid generated from the component (B) acts on the component (A) to change the solubility of the component (A) in a developing solution. As a result, the solubility of the exposed portions of this resist film in a developing solution is changed, whereas the solubility of the unexposed portions in a developing solution remains unchanged. Therefore, the exposed portions are dissolved and removed by developing in the case of a positive pattern, whereas unexposed portions are dissolved and removed in the case of a negative pattern, and hence, a resist pattern can be formed.

The resist composition for EUV according to the present invention may be either a negative resist composition or a positive resist composition.

In the present specification, a resist composition which forms a positive pattern by dissolving and removing the exposed portions is called a positive resist composition, and a resist composition which forms a negative pattern by dissolving and removing the unexposed portions is called a negative resist composition.

In the formation of a resist pattern, the resist composition for EUV according to the present invention can be applied to an alkali developing process using an alkali developing solution in the developing treatment, or a solvent developing process (negative developing process) using a developing solution containing an organic solvent (organic developing solution) in the developing treatment.

### <Component (A)>

As the component (A), an organic compound typically used as a base component for a chemically amplified resist composition can be used alone, or two or more of such organic compounds can be mixed together.

Here, the term “base component” refers to an organic compound capable of forming a film, and is preferably an organic compound having a molecular weight of 500 or more. When the organic compound has a molecular weight of 500 or more, the organic compound exhibits a satisfactory film-forming ability, and a resist pattern of nano level can be easily formed.

The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

As the component (A), a resin component which exhibits changed solubility in a developing solution under the action of acid may be used. Alternatively, as the component (A), a low molecular weight compound which exhibits changed solubility in a developing solution under the action of acid may be used.

When the resist composition for EUV according to the present invention is a “negative resist composition for alkali developing process” which forms a negative pattern in an alkali developing process, for example, as the component (A), a base component that is soluble in an alkali developing solution is used, and a cross-linking agent is further blended in the negative resist composition.

In the negative resist composition for alkali developing process, when acid is generated from the component (B) upon exposure, the action of the generated acid causes cross-linking between the base component and the cross-linking agent, and the cross-linked portion becomes substantially insoluble in an alkali developing solution. Therefore, in the formation of a resist pattern, by conducting selective exposure of a resist film formed by applying the negative resist composition onto a substrate, the exposed portions become insoluble in an alkali developing solution, whereas the unexposed portions remain soluble in an alkali developing solution, and hence, a resist pattern can be formed by alkali developing.

Generally, as the component (A) for a negative resist composition for alkali developing process, a resin that is soluble in an alkali developing solution (hereafter, referred to as “alkali-soluble resin”) is used.

Examples of the alkali soluble resin include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin or polycycloolefin resin which has a sulfoneamide group and may have the hydrogen atom bonded to the carbon atom on the α-position substituted with a substituent, as disclosed in U.S. Pat. No. 6,949,325; an acrylic resin which may have the hydrogen atom bonded to the carbon atom on the α-position substituted with a substituent and having a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable in that a favorable resist pattern can be formed with minimal swelling.

Here, the term “α-(hydroxyalkyl)acrylic acid” refers to, among the acrylic acids which may have a hydrogen atom bonded to the carbon atom on the α-position substituted with a sub stituent, one or both of acrylic acid in which a hydrogen atom is bonded to the carbon atom on the α-position having the carboxyl group bonded thereto, and α-hydroxyalkylacrylic acid in which a hydroxyalkyl group (and preferably a hydroxyalkyl group of 1 to 5 carbon atoms) is bonded to the carbon atom on the α-position.

As the cross-linking agent, typically, an amino-based cross-linking agent such as a glycoluril having a methylol group or alkoxymethyl group, or a melamine-based cross-linking agent is preferable, as it enables formation of a favorable resist pattern with minimal swelling. The amount of the cross-linker added is preferably within a range from 1 to 50 parts by weight, relative to 100 parts by weight of the alkali-soluble resin.

In the case where the resist composition for EUV according to the present invention is a resist composition which forms a positive pattern in an alkali developing process and a negative pattern in a solvent developing process, as the component (A), it is preferable to use a base component (hereafter, referred to as “component (A0)”) which exhibits increased polarity by the action of acid. By using the component (A0), since the polarity of the base component changes prior to and after exposure, an excellent development contrast can be obtained not only in an alkali developing process, but also in a solvent developing process.

In the case of applying an alkali developing process, the component (A0) is substantially insoluble in an alkali developing solution prior to exposure, but when acid is generated from the component (B) upon exposure, the action of this acid causes an increase in the polarity of the base component, thereby increasing the solubility of the component (A0) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A0) exhibits high solubility in an organic developing solution prior to exposure, and when acid is generated from the component (B) upon exposure, the polarity of the component (A0) is increased by the action of the generated acid, thereby decreasing the solubility of the component (A0) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the resist composition for EUV according to the present invention, the component (A) is preferably a base component which exhibits increased polarity by the action of acid (i.e., the component (A0)). That is, the resist composition for EUV according to the present invention is preferably a chemically amplified resist composition which becomes a positive type in the case of an alkali developing process, and a negative type in the case of a solvent developing process.

The component (A0) may be a resin component (A1) that exhibits increased polarity under the action of acid (hereafter, frequently referred to as “component (A1)”), a low molecular weight compound (A2) that exhibits increased polarity under the action of acid (hereafter, frequently referred to as “component (A2)”), or a mixture thereof

### [Component (A1)]

As the component (A1), a resin component (base resin) typically used as a base component for a chemically amplified resist composition can be used alone, or two or more of such resin components can be mixed together.

The component (A1) in the present invention preferably includes a structural unit (a0) containing an acid decomposable group that exhibits increased polarity by the action of acid. The structural unit (a0) is preferably a structural unit (a1) derived from an acrylate ester which may have the hydrogen atom bonded to the carbon atom on the α-position substituted with a substituent and contains an acid decomposable group which exhibits increased polarity by the action of acid; or a structural unit (a11) derived from a hydroxystyrene derivative and contains an acid decomposable group that exhibits increased polarity by the action of acid. The component (A1) may contain both of the structural units (a1) and (a11) or may contain either one of them.

Further, it is preferable that the component (A1) further include, in addition to the structural unit (a1), at least one type of structural unit (a2) selected from the group consisting of structural units derived from an acrylate ester which contains a —SO₂-containing cyclic group and may have the hydrogen atom bonded to the carbon atom on the α-position substituted with a substituent, and structural units derived from an acrylate ester which contains a lactone-containing cyclic group and may have the hydrogen atom bonded to the carbon atom on the α-position substituted with a substituent.

Furthermore, it is preferable that the component (A1) further include a structural unit (a3) derived from an acrylate ester which contains a polar group-containing aliphatic hydrocarbon group and may have the hydrogen atom bonded to the carbon atom on the α-position substituted with a substituent, as well as the structural unit (a1), or the structural unit (a1) and the structural unit (a2).

Examples of the substituent which may be bonded to the carbon atom on the α-position include a halogen atom, an alkyl group of 1 to 5 carbon atoms, a halogenated alkyl group of 1 to 5 carbon atoms, and a hydroxyalkyl group.

It should be noted that the carbon atom on the α-position of an acrylic acid ester refers to the carbon atom bonded to the carbonyl group.

Examples of the halogen atom which may be bonded to the carbon atom on the α-position include a fluorine atom, a chlorine atom, a bromine atom, an iodine atom, and a fluorine atom is particularly preferable.

The alkyl group which may be bonded to the carbon atom on the α-position is preferably a linear or branched alkyl group of 1 to 5 carbon atoms, and specific examples include a methyl group, an ethyl group, a propyl group, an isopropyl group, a n-butyl group, an isobutyl group, a tert-butyl group, a pentyl group, an isopentyl group, a neopentyl group.

In addition, specific examples of the halogenated alkyl group which may be bonded to the carbon atom on the α-position include groups in which part or all of the hydrogen atoms of the aforementioned “alkyl group which may be bonded to the carbon atom on the α-position” are substituted with halogen atoms. Examples of the halogen atom include a fluorine atom, a chlorine atom, a bromine atom and an iodine atom, and a fluorine atom is particularly desirable.

Further, specific examples of the hydroxyalkyl group which may be bonded to the carbon atom on the α-position include groups in which part or all of the hydrogen atoms of the aforementioned “alkyl group which may be bonded to the carbon atom on the α-position” are substituted with hydroxy groups.

It is preferable that a hydrogen atom, an alkyl group of 1 to 5 carbon atoms or a halogenated alkyl group of 1 to 5 carbon atoms is bonded to the carbon atom on the α-position, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

(Structural Unit (a1))

The structural unit (a1) is a structural unit derived from an acrylate ester which may have the hydrogen atom bonded to the carbon atom on the α-position substituted with a substituent and contains an acid decomposable group which exhibits increased polarity by the action of acid.

The term “acid decomposable group” refers to a group exhibiting acid decomposability in which at least a part of the bond within the structure of this acid decomposable group may be cleaved by the action of an acid (including the acid generated from the component (B) upon exposure).

Examples of acid decomposable groups that exhibit increased polarity by the action of an acid include groups which are decomposed by the action of acid to form a polar group.

Examples of the polar group include a carboxyl group, a hydroxyl group, an amino group and a sulfo group (—SO₃H). Of these, a polar group containing —OH within the structure thereof (hereafter, sometimes referred to as an “OH-containing polar group”) is preferable, a carboxyl group or a hydroxyl group is more preferable, and a carboxyl group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

An “acid dissociable group” is a group exhibiting acid dissociability in which at least the bond between the acid dissociable group and the atom adjacent to this acid dissociable group may be cleaved by the action of an acid (including the acid generated from the component (B) upon exposure). It is necessary that the acid dissociable group constituting the acid decomposable group is a group which exhibits a lower polarity than that of the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. Due to the increase in the polarity, in the case of applying an alkali developing process, the solubility in an alkali developing solution is relatively increased. On the other hand, in the case of applying a solvent developing process, the solubility in an organic developing solution containing an organic solvent decreases.

As the acid dissociable group for the structural unit (a1), any of those which have been proposed as acid dissociable groups for a base resin of a chemically amplified resist may be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxyl group. As a result, the polarity of the component (A1) is increased.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

In the present specification, the term “aliphatic branched” refers to a branched structure having no aromaticity.

The “aliphatic branched, acid dissociable group” is not limited to be constituted of only carbon atoms and hydrogen atoms (not limited to hydrocarbon groups), but is preferably a hydrocarbon group.

Further, the “hydrocarbon group” may be either saturated or unsaturated, but is preferably saturated.

Examples of aliphatic branched, acid dissociable groups include tertiary alkyl groups of 4 to 8 carbon atoms, and specific examples include a tert-butyl group, a tert-pentyl group and a tert-heptyl group.

The term “aliphatic cyclic group” refers to a monocyclic group or polycyclic group that has no aromaticity.

The “aliphatic cyclic group” within the structural unit (a1) may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated. Furthermore, the “aliphatic cyclic group” is preferably a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

As the aliphatic cyclic group-containing acid dissociable group, for example, a group which has a tertiary carbon atom on the ring structure of the cyclic alkyl group can be used. Specific examples include groups represented by any one of general formulas (1-1) to (1-9) shown below, such as a 2-methyl-2-adamantyl group and a 2-ethyl-2-adamantyl group.

Further, as examples of aliphatic branched acid dissociable group, groups having an aliphatic cyclic group such as an adamantyl group, cyclohexyl group, cyclopentyl group, norbornyl group, tricyclodecyl group or tetracyclododecyl group, and a branched alkylene group having a tertiary carbon atom bonded thereto, as those represented by general formulas (2-1) to (2-6) shown below, can be given.

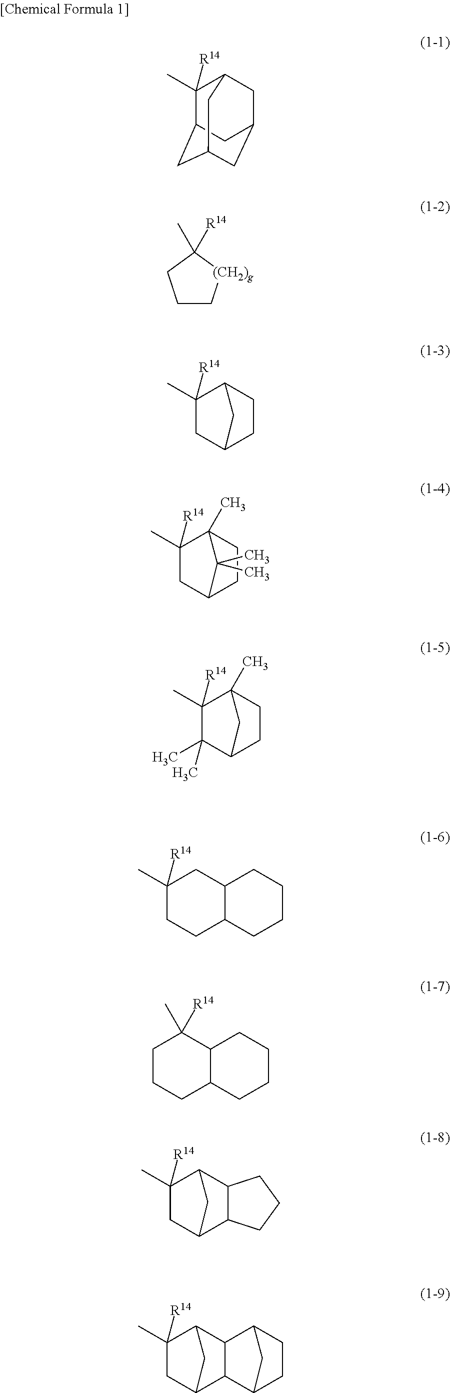

In the formulas above, R¹⁴ represents an alkyl group; and g represents an integer of 0 to 8.

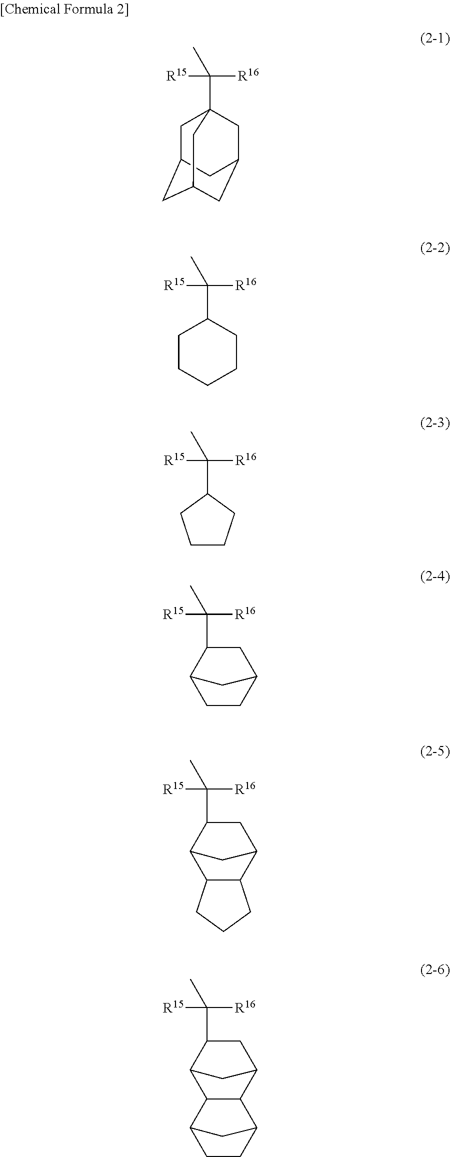

In the formulas, each of R¹⁵ and R¹⁶ independently represents an alkyl group (which may be linear or branched, and preferably has 1 to 5 carbon atoms).

As the alkyl group for R¹⁴, a linear or branched alkyl group is preferable.

The linear alkyl group preferably has 1 to 5 carbon atoms, more preferably 1 to 4 carbon atoms, and still more preferably 1 or 2 carbon atoms. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5 carbon atoms. Specific examples of such branched alkyl groups include an isopropyl group, an isobutyl group, a tert-butyl group, an isopentyl group and a neopentyl group, and an isopropyl group is particularly desirable.

g is preferably an integer of 0 to 3, more preferably an integer of 1 to 3, and still more preferably 1 or 2.

As the alkyl group for R¹⁵ and R¹⁶, the same alkyl groups as those for R¹⁴ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxyl group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxyl group or a hydroxyl group. As a result, the polarity of the component (A1) is increased.

Examples of acetal-type acid dissociable groups include groups represented by general formula (p1) shown below.

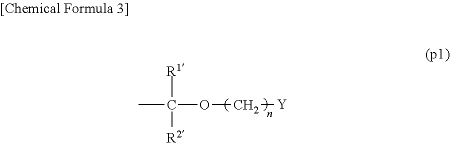

In the formula, each of R¹′ and R²′ independently represents a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1) above, n is preferably an integer of 0 to 2, more preferably 0 or 1, and most preferably 0.

As the alkyl group of 1 to 5 carbon atoms for R¹′ and R²′, the same alkyl groups of 1 to 5 carbon atoms as those described below for R can be used, although a methyl group or an ethyl group is preferable, and a methyl group is particularly desirable.

In the present invention, it is preferable that at least one of R¹′ and R²′ be a hydrogen atom. That is, it is preferable that the acid dissociable group (p1) is a group represented by general formula (p1-1) shown below.

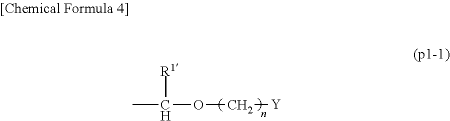

In the formula, R¹′, n and Y are the same as defined above.

As the alkyl group of 1 to 5 carbon atoms for Y, the same alkyl groups of 1 to 5 carbon atoms as those described below for R can be used.

As the aliphatic cyclic group for Y, any of the aliphatic monocyclic/polycyclic groups which have been proposed for conventional ArF resists and the like can be appropriately selected for use. For example, the same groups described above in connection with the “aliphatic cyclic group” can be used.

Further, as the acetal-type, acid dissociable group, groups represented by general formula (p2) shown below can also be used.

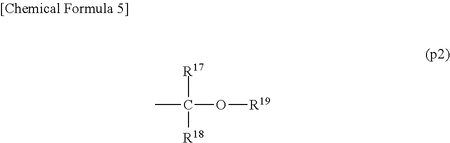

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and R¹⁷ is bonded to R¹⁹ to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable. It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cyclic alkyl group, it preferably has 4 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and R¹⁹ may be bonded to R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include a tetrahydropyranyl group and a tetrahydrofuranyl group.

As the structural unit (a1), it is preferable to use at least one member selected from the group consisting of structural units represented by general formula (a1-0-1) shown below and structural units represented by general formula (a1-0-2) shown below.

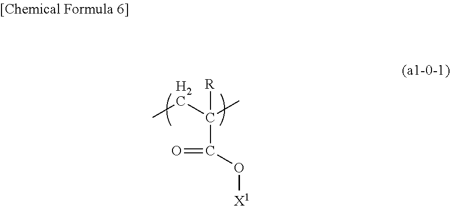

In the formula, R represents a hydrogen atom, an alkyl group of 1 to 5 carbon atoms or a halogenated alkyl group of 1 to 5 carbon atoms; and X¹ represents an acid dissociable group.

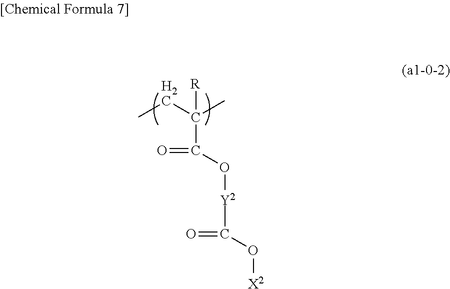

In the formula, R represents a hydrogen atom, an alkyl group of 1 to 5 carbon atoms or a halogenated alkyl group of 1 to 5 carbon atoms; X² represents an acid dissociable group; and Y² represents a divalent linking group.

In general formula (a1-0-1) above, the alkyl group of 1 to 5 carbon atoms or halogenated alkyl group of 1 to 5 carbon atoms for R are the same as the alkyl group of 1 to 5 carbon atoms or halogenated alkyl group of 1 to 5 carbon atoms which can be used as the sub stituent for the hydrogen atom bonded to the carbon atom on the α-position of the aforementioned acrylate ester.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a1-0-2), R is the same as defined above.

X² is the same as defined for X¹ in general formula (a1-0-1).

Examples of the divalent linking group for Y² include an alkylene group, a divalent aliphatic cyclic group and a divalent linking group containing a hetero atom.

As the aliphatic cyclic group, the same as those used above in connection with the explanation of “aliphatic cyclic group” can be used, except that two or more hydrogen atoms have been removed therefrom.

When Y² represents an alkylene group, it preferably has 1 to 10 carbon atoms, more preferably 1 to 6 carbon atoms, still more preferably 1 to 4 carbon atoms, and most preferably 1 to 3 carbon atoms.

When Y² represents a divalent aliphatic cyclic group, it is particularly desirable that the divalent aliphatic cyclic group be a group in which two or more hydrogen atoms have been removed from cyclopentane, cyclohexane, norbornane, isobornane, adamantane, tricyclodecane or tetracyclododecane.

When Y² represents a divalent linking group containing a hetero atom, examples thereof include —O—, —C(═O)—O—, —C(═O)—, —C(═O)—NH—, —NH— (H may be substituted with a substituent such as an alkyl group or an acyl group), —S—, —S(═O)₂—, —S(═O)₂—O—, “-A-O—B— (wherein O is an oxygen atom, and each of A and B independently represents a divalent hydrocarbon group which may have a sub stituent)” and a combination of an alkylene group with a divalent linking group containing a hetero atom.

When Y² represents —NH—, the substituent (an alkyl group, an acyl group or the like) preferably has 1 to 10 carbon atoms, more preferably 1 to 8 carbon atoms, and most preferably 1 to 5 carbon atoms.

When Y² is “A-O—B”, each of A and B independently represents a divalent hydrocarbon group which may have a substituent.

The description that the hydrocarbon group “may have a substituent” means that some or all of the hydrogen atoms within the hydrocarbon group may be substituted with an atom other than a hydrogen atom or with a group.

The hydrocarbon group for A may be either an aliphatic hydrocarbon group, or an aromatic hydrocarbon group. An “aliphatic hydrocarbon group” refers to a hydrocarbon group that has no aromaticity.

The aliphatic hydrocarbon group for A may be either saturated or unsaturated. In general, the aliphatic hydrocarbon group is preferably saturated.

As specific examples of the aliphatic hydrocarbon group for A, a linear or branched aliphatic hydrocarbon group, and an aliphatic hydrocarbon group having a ring in the structure thereof can be given.

The linear or branched aliphatic hydrocarbon group preferably has 1 to 10 carbon atoms, more preferably 1 to 8 carbon atoms, still more preferably 2 to 5 carbon atoms, and most preferably 2 carbon atoms.

As a linear aliphatic hydrocarbon group, a linear alkylene group is preferable, and specific examples include a methylene group, an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂— and —CH(CH₂CH₃)CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of the substituent include a fluorine atom, a fluorinated alkyl group of 1 to 5 carbon atoms, and an oxygen atom (═O).

As examples of the hydrocarbon group containing a ring, a cyclic aliphatic hydrocarbon group (a group in which two hydrogen atoms have been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane.

As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

As A, a linear aliphatic hydrocarbon group is preferred, a linear alkylene group is more preferred, a linear alkylene group of 2 to 5 carbon atoms is still more preferred, and an ethylene group is particularly desirable.

Examples of the aromatic hydrocarbon group for A include a divalent aromatic hydrocarbon group in which one hydrogen atom has been removed from a benzene ring of a monovalent aromatic hydrocarbon group such as a phenyl group, a biphenyl group, a fluorenyl group, a naphthyl group, an anthryl group or a phenanthryl group; an aromatic hydrocarbon group in which part of the carbon atoms constituting the ring of the aforementioned divalent aromatic hydrocarbon group has been substituted with a hetero atom such as an oxygen atom, a sulfur atom or a nitrogen atom; and an aromatic hydrocarbon group in which one hydrogen atom has been further removed from a benzene ring of an arylalkyl group such as a benzyl group, a phenethyl group, a 1-naphthylmethyl group, a 2-naphthylmethyl group, a 1-naphthylethyl group or a 2-naphthylethyl group.

The aromatic hydrocarbon group may or may not have a substituent. Examples of the sub stituent include an alkyl group of 1 to 5 carbon atoms, a fluorine atom, a fluorinated alkyl group of 1 to 5 carbon atoms, and an oxygen atom (═O).

As the hydrocarbon group for B, the same divalent hydrocarbon groups as those described above for A can be used.

As B, a linear or branched aliphatic hydrocarbon group is preferable, and a methylene group or an alkylmethylene group is particularly desirable.

The alkyl group within the alkyl methylene group is preferably a linear alkyl group of 1 to 5 carbon atoms, more preferably a linear alkyl group of 1 to 3 carbon atoms, and most preferably a methyl group.

Specific examples of the structural unit (a1) include structural units represented by general formulas (a1-1) to (a1-4) shown below.

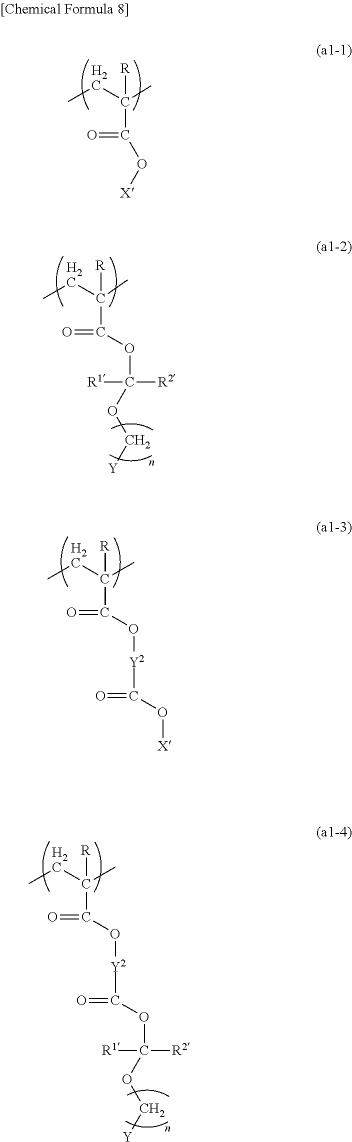

In the formulas, X′ represents a tertiary alkyl ester-type acid dissociable group; Y represents an alkyl group of 1 to 5 carbon atoms or an aliphatic cyclic group; n represents an integer of 0 to 3; Y² represents a divalent linking group; R is the same as defined above; and each of R¹′ and R²′ independently represents a hydrogen atom or an alkyl group of 1 to 5 carbon atoms.

In the above formulas, examples of the tertiary alkyl ester-type acid dissociable group for X′ include the same tertiary alkyl ester-type acid dissociable groups as those described above for X¹.

As R¹′, R²′, n and Y are respectively the same as defined for R¹′, R²′, n and Y in general formula (p1) described above in connection with the “acetal-type acid dissociable group”.

As examples of Y², the same groups as those described above for Y² in general formula (a1-0-2) can be given.

Specific examples of structural units represented by general formula (a1-1) to (a1-4) are shown below.

In the formulas shown below, R^{α} represents a hydrogen atom, a methyl group or a trifluoromethyl group.

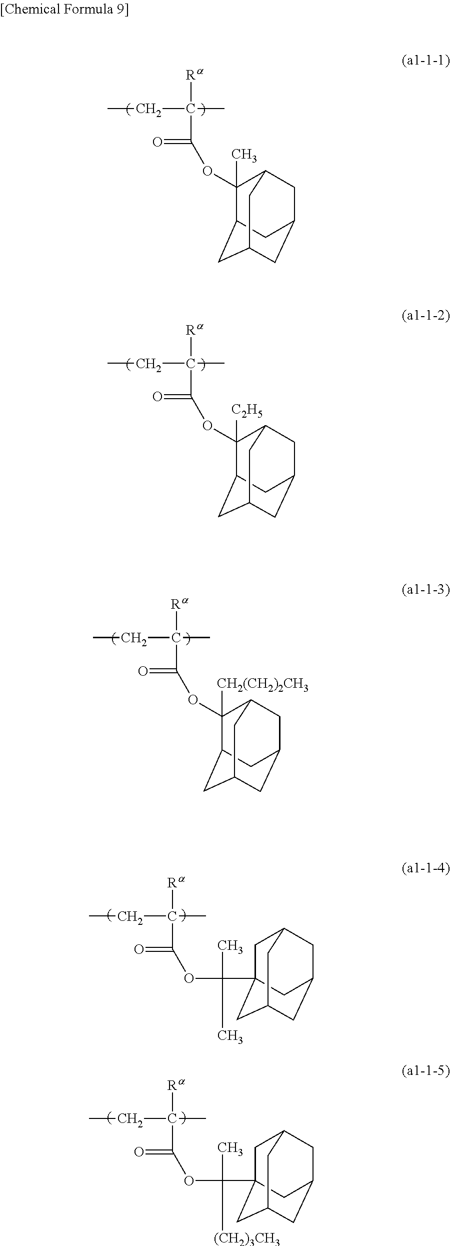

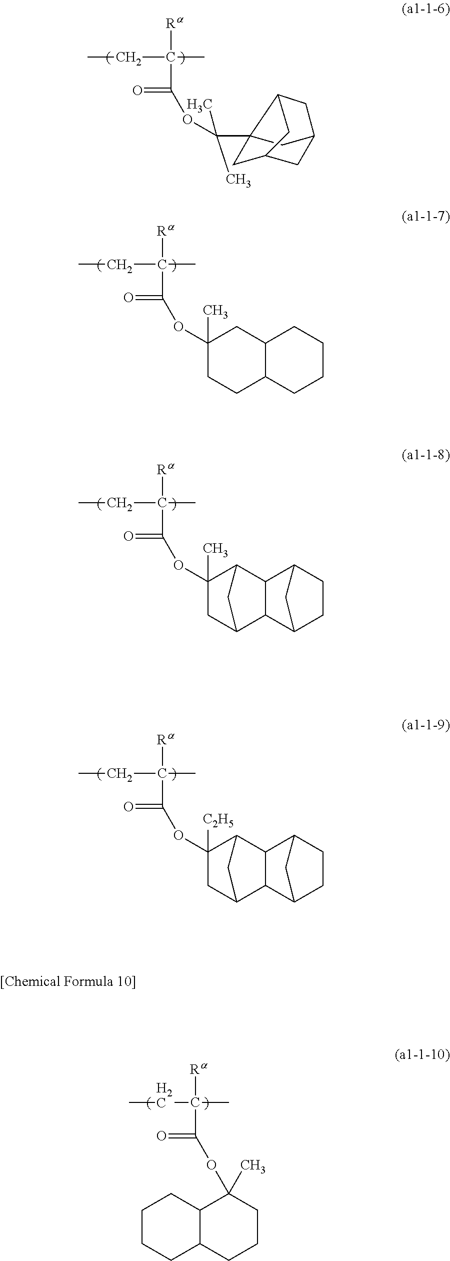

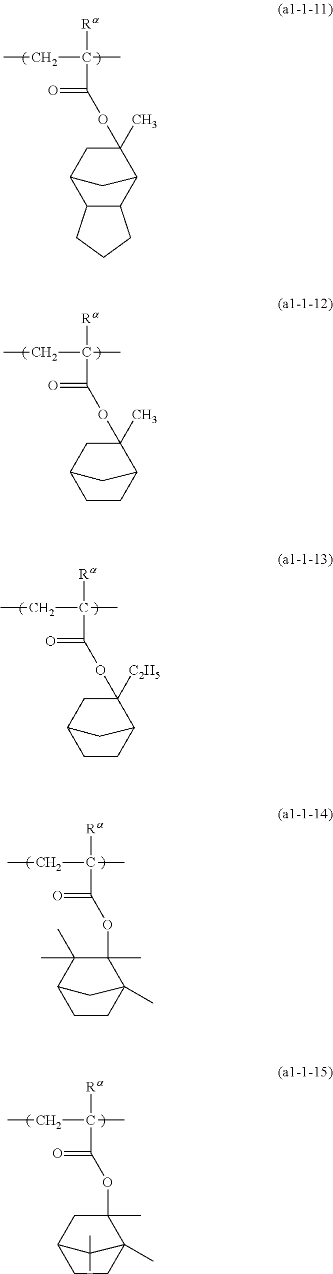

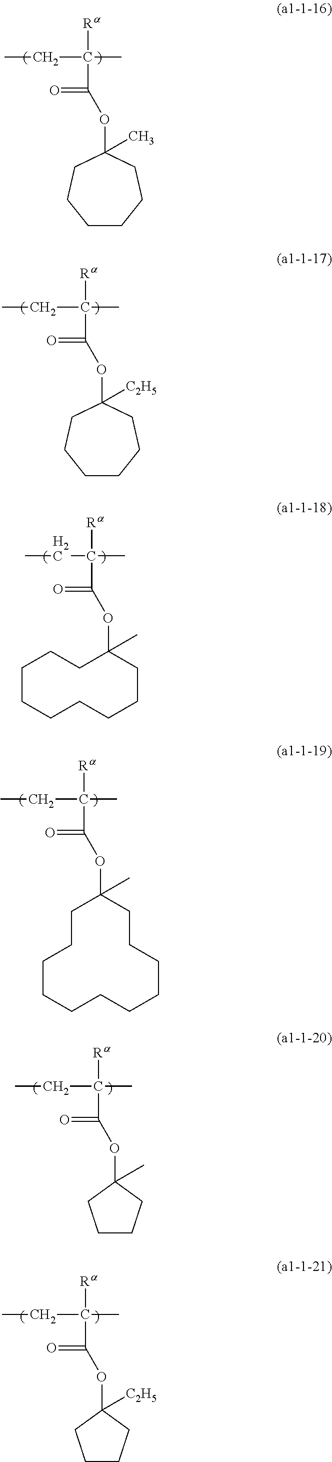

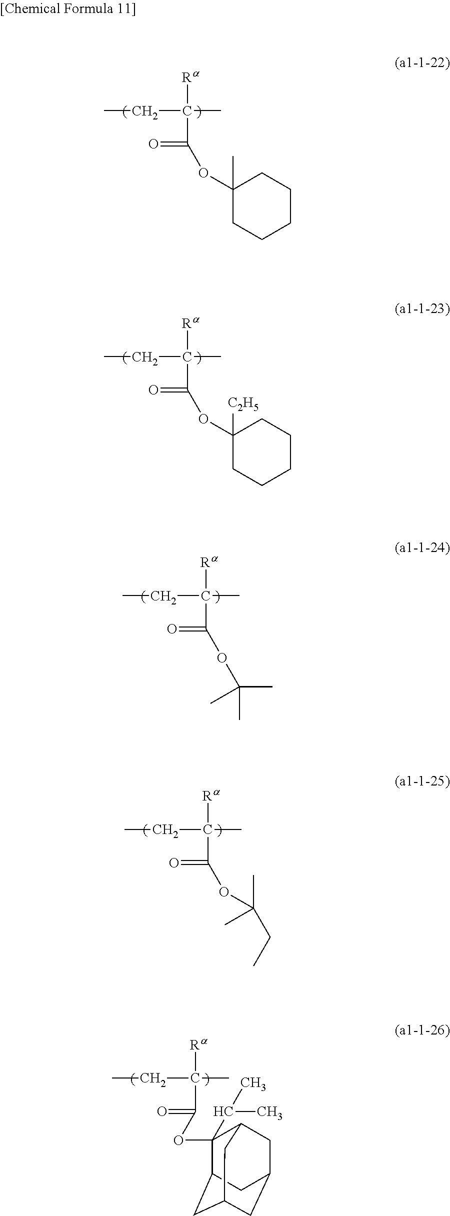

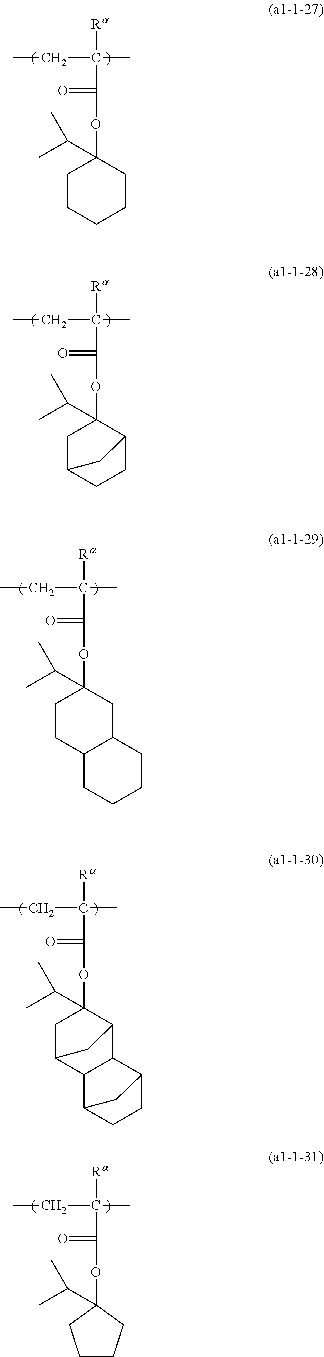

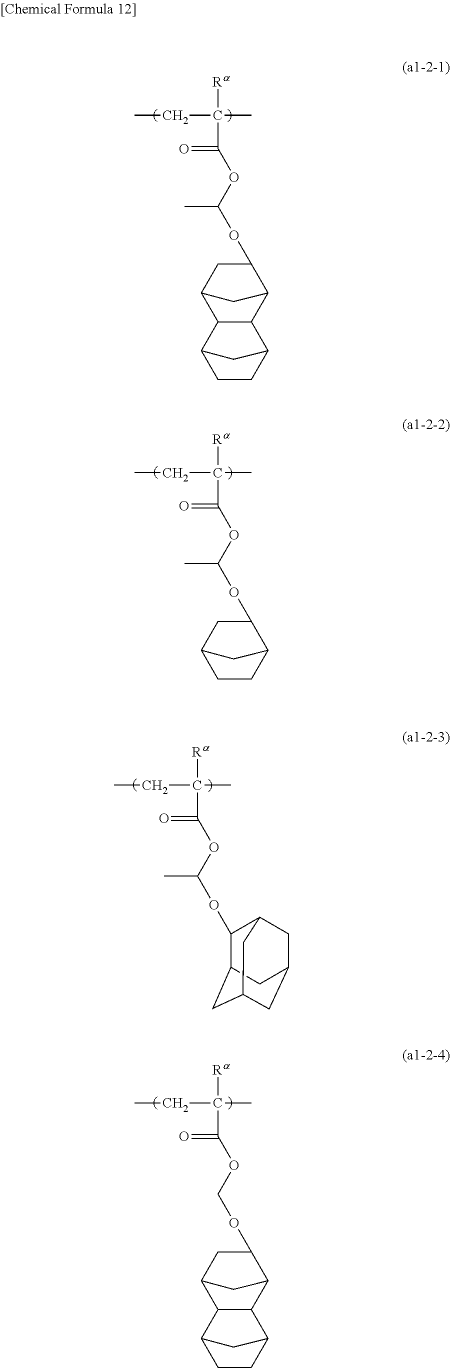

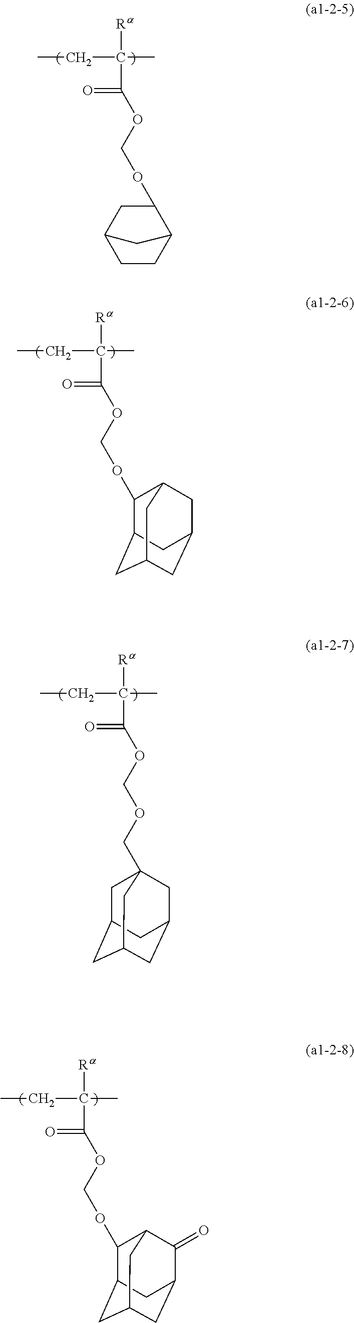

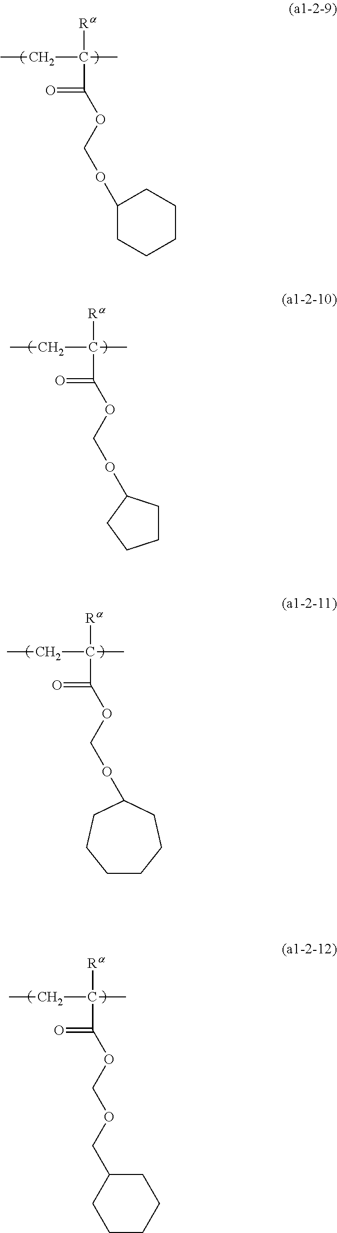

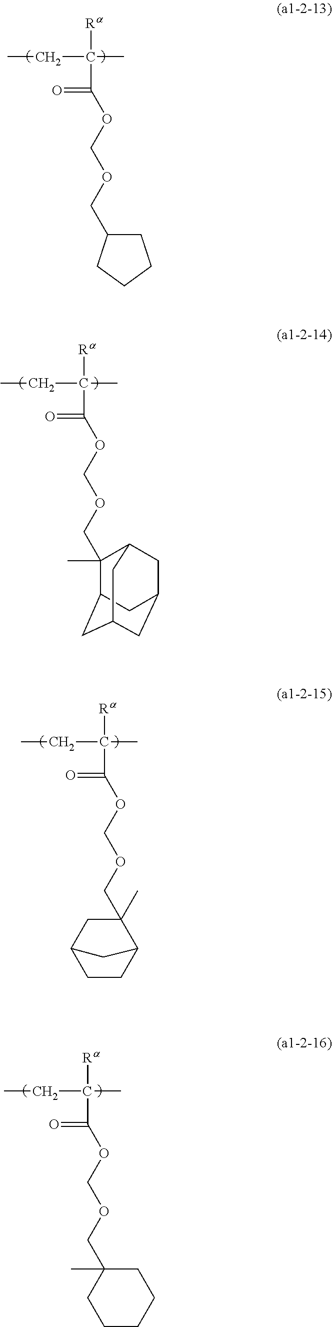

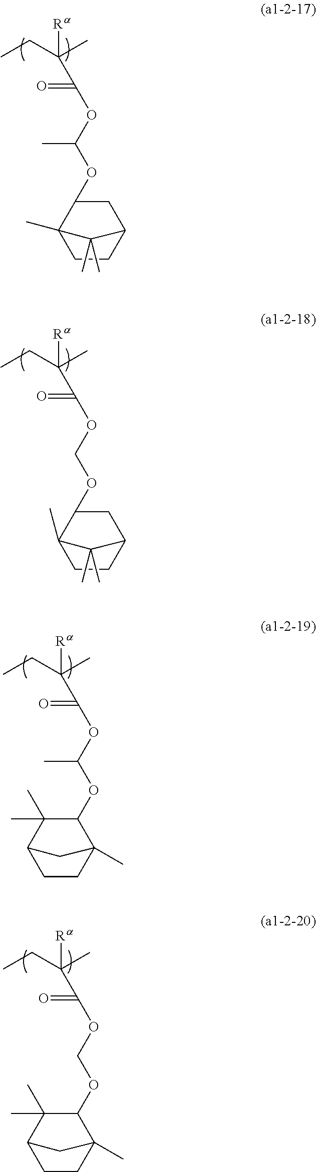

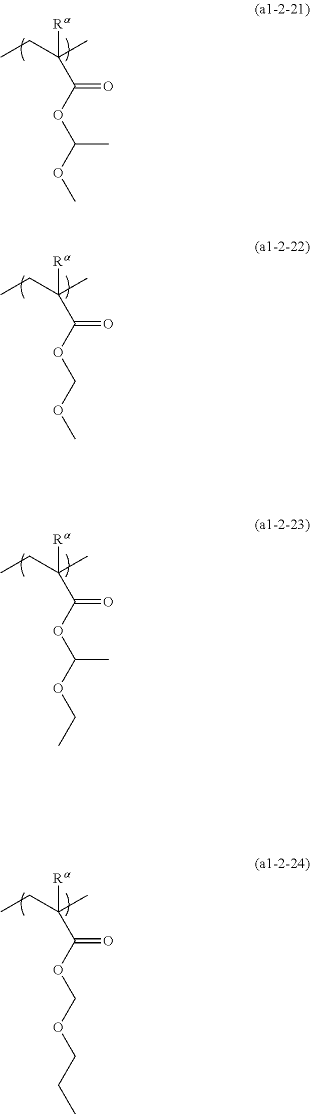

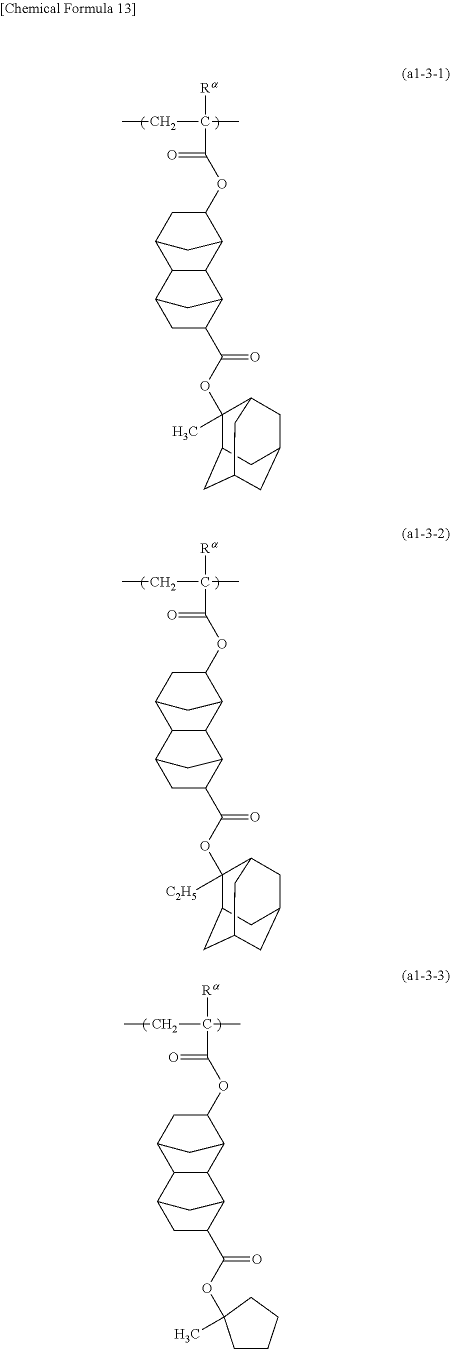

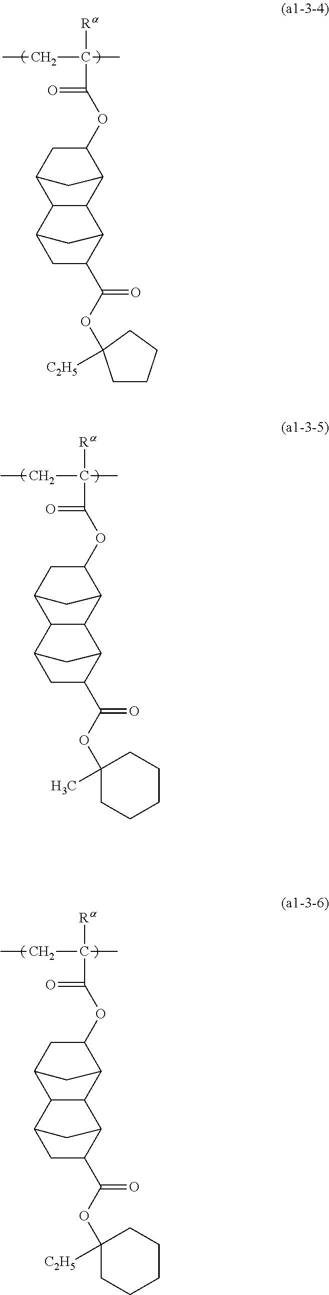

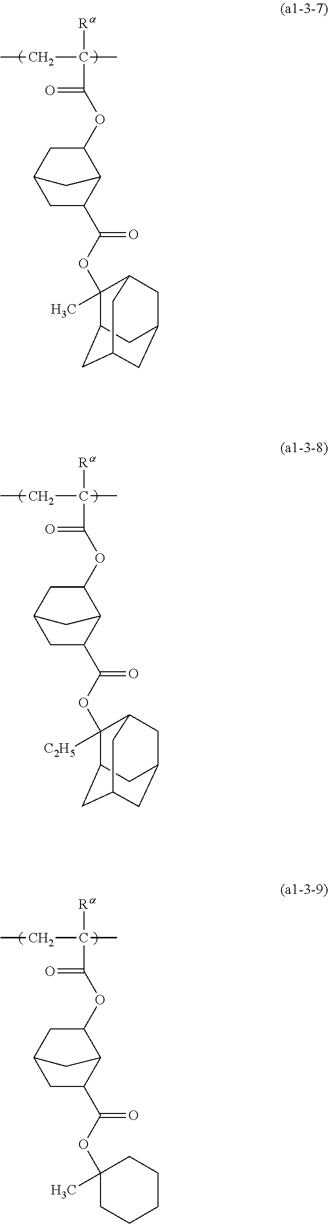

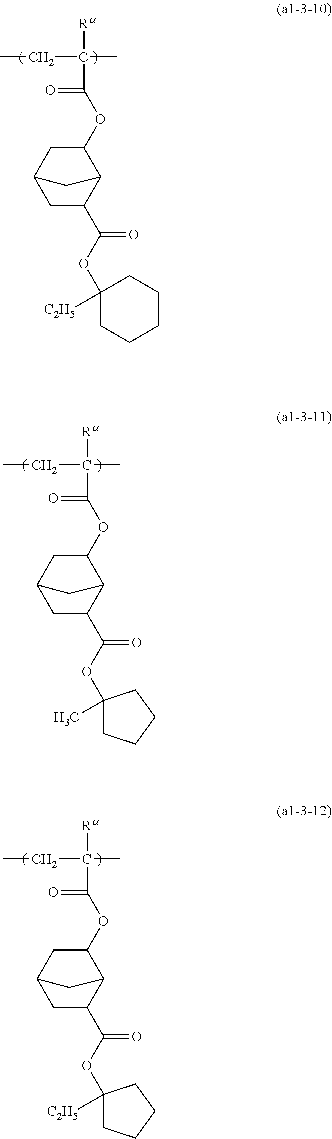

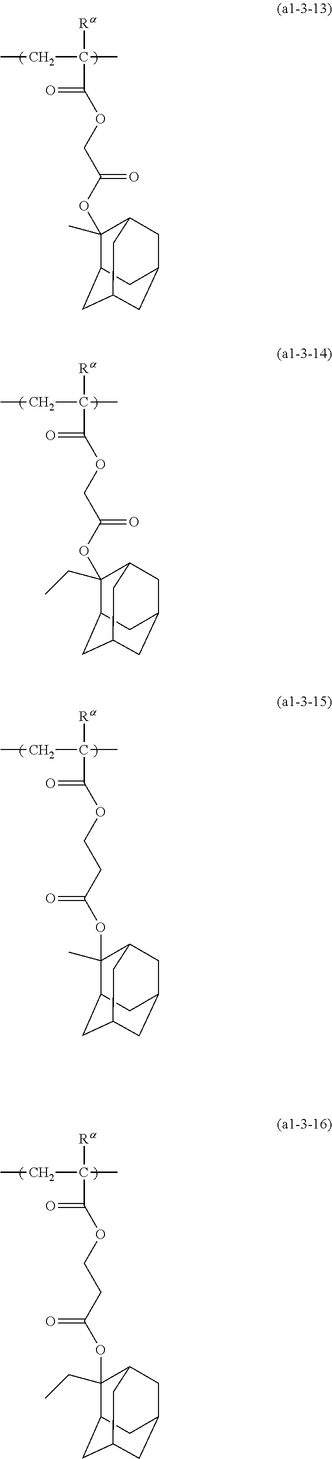

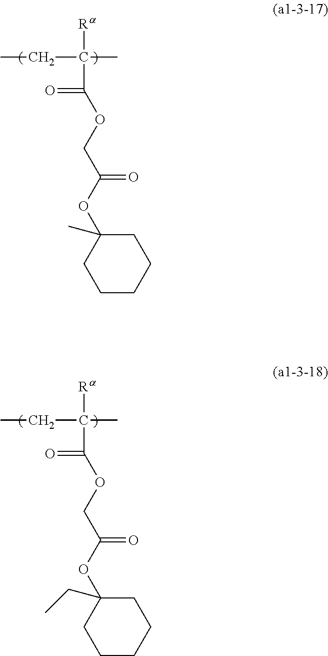

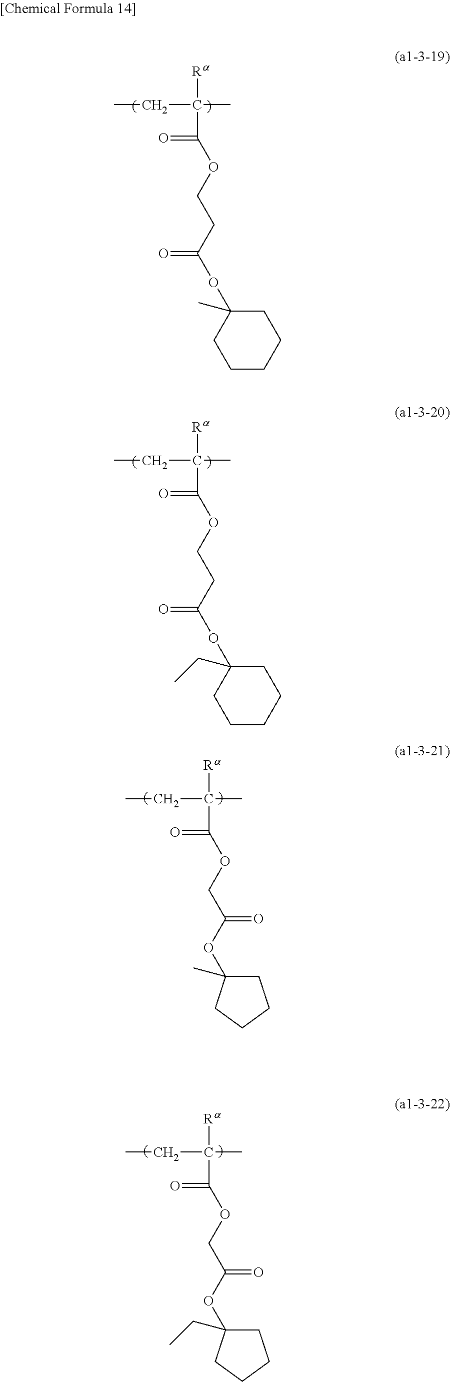

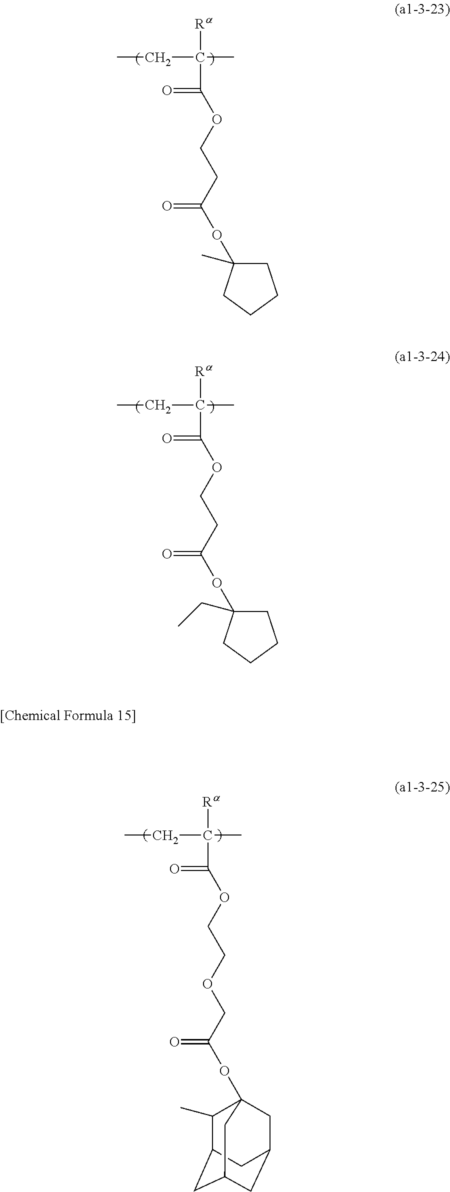

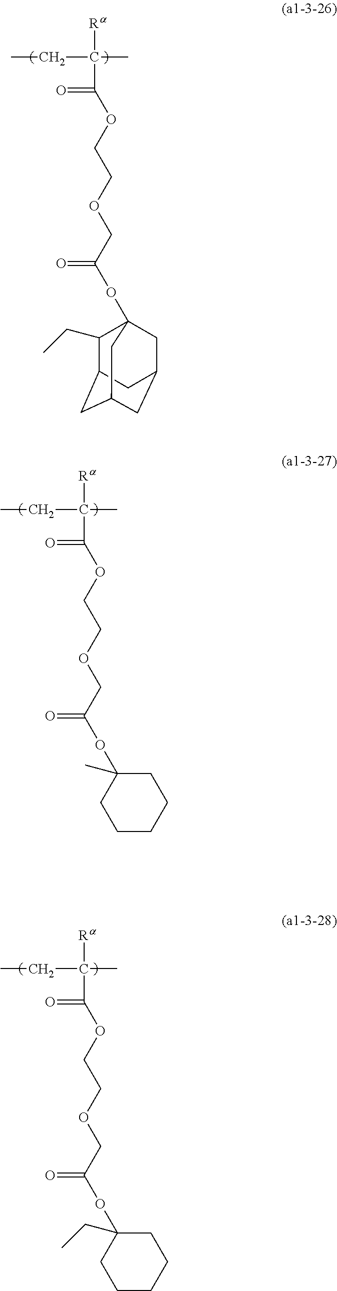

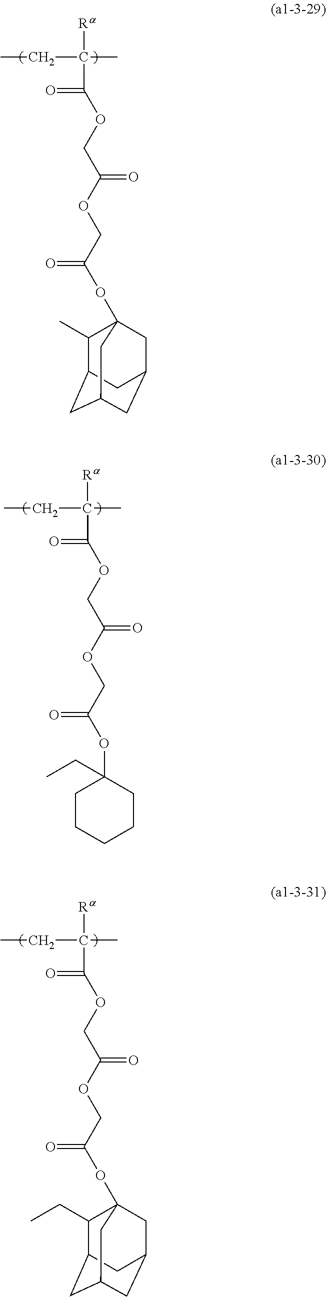

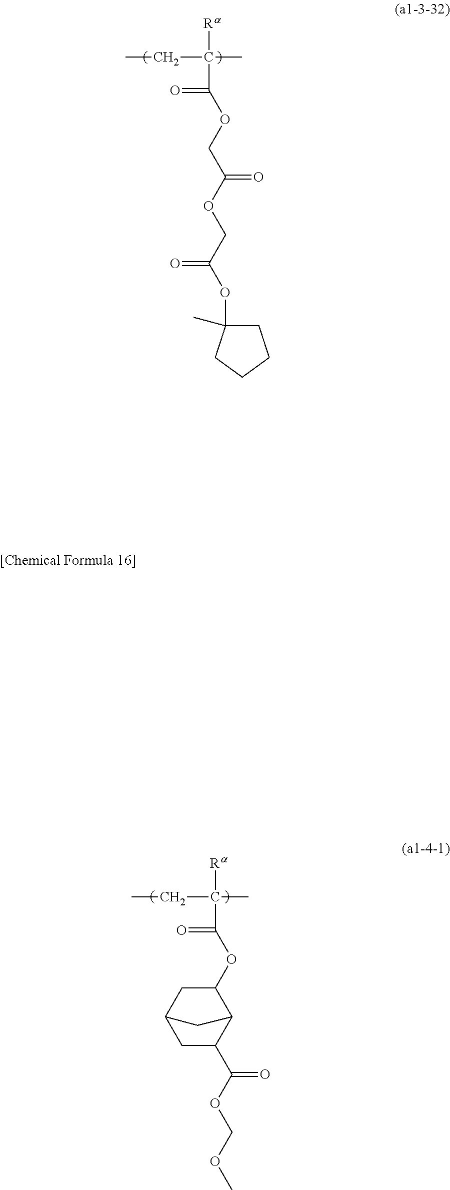

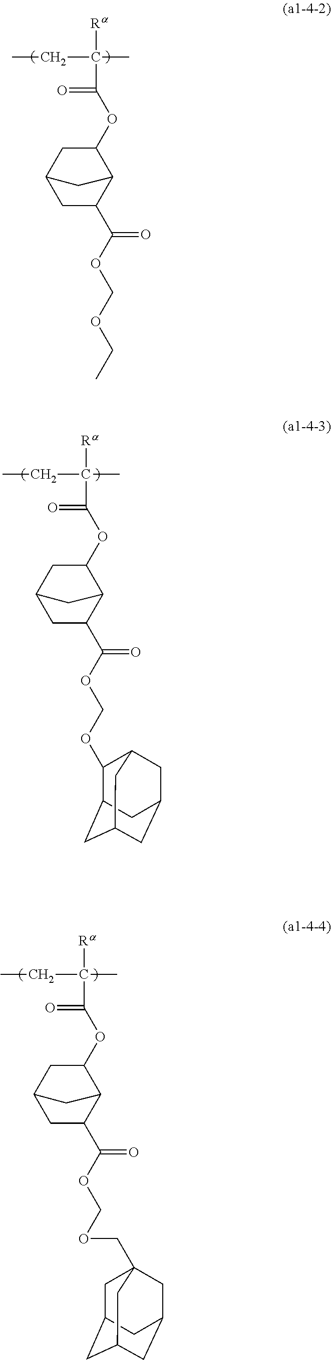

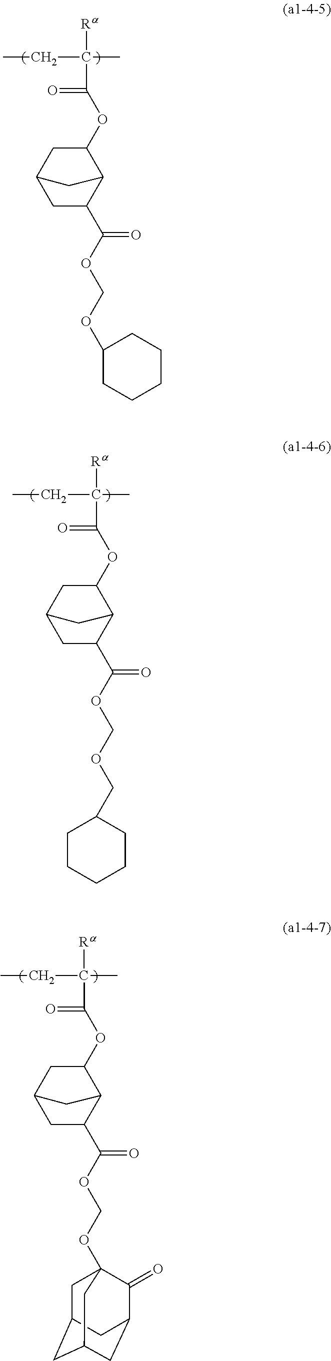

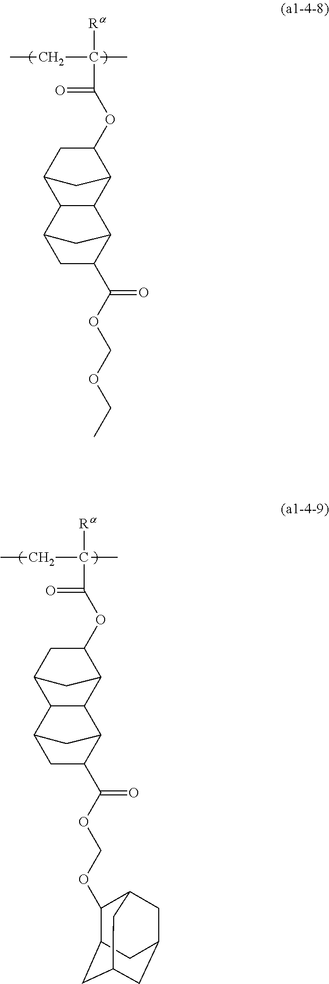

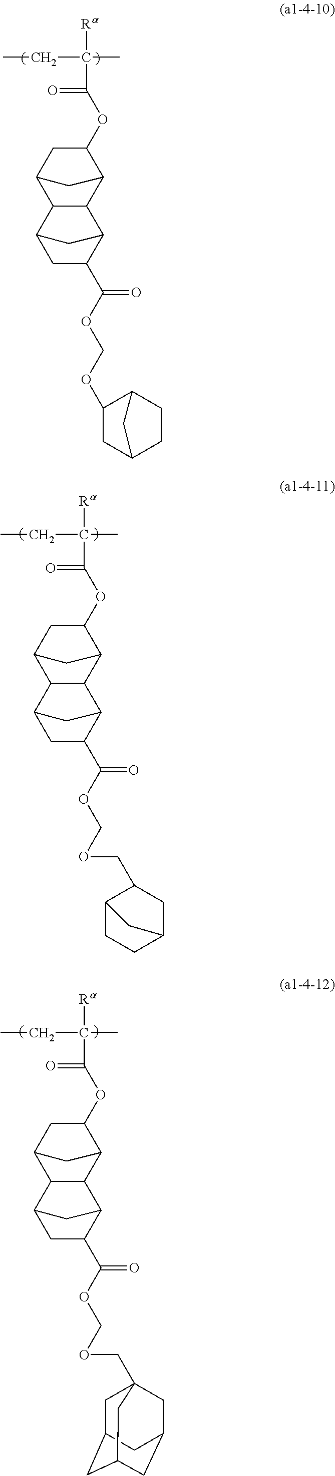

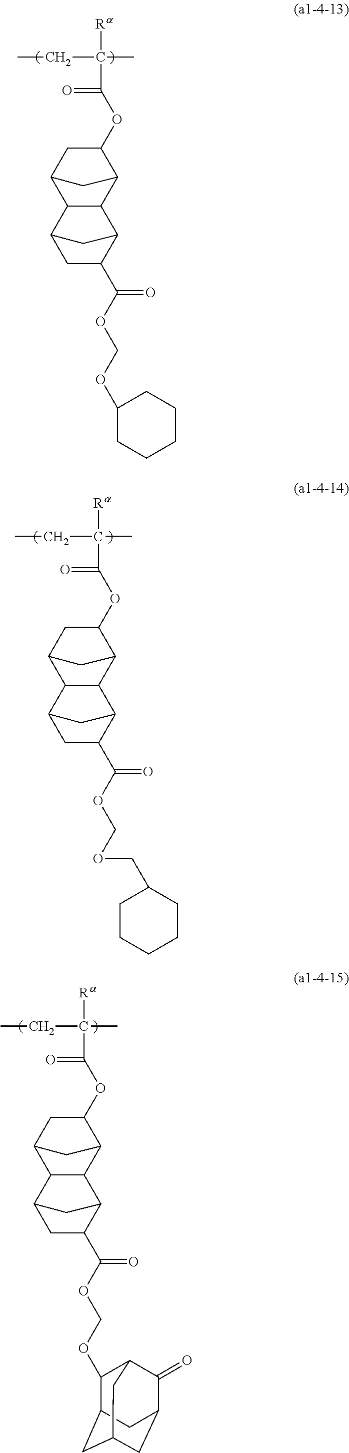

As the structural unit (a1), one type of structural unit may be used alone, or two or more types of structural units may be used in combination.

Among these, structural units represented by general formula (a1-1), (a1-2) or (a1-3) are preferable. More specifically, at least one structural unit selected from the group consisting of structural units represented by formulas (a1-1-1) to (a-1-1-4), (a1-1-20) to (a1-1-23), (a1-1-26), (a1-2-1) to (a1-2-24) and (a1-3-25) to (a1-3-28) is more preferable.

Furthermore, as the structural unit (a1), structural units represented by general formula (a1-1-01) shown below which includes the structural units represented by formulas (a1-1-1) to (a1-1-3) and (a1-1-26), structural units represented by general formula (a1-1-02) shown below which includes the structural units represented by formulas (a1-1-16) to (a1-1-17) and (a1-1-20) to (a1-1-23), structural units represented by general formula (a1-2-01) shown below which includes the structural units represented by formulas (a1-2-3), (a1-2-6) and (a1-2-14), structural units represented by general formula (a1-3-01) shown below which includes the structural units represented by formulas (a1-3-25) to (a1-3-26), structural units represented by general formula (a1-3-02) shown below which includes the structural units represented by formulas (a1-3-27) to (a1-3-28), or structural units represented by general formula (a1-3-03) shown below which includes the structural units represented by formulas (a1-3-29) to (a1-3-30) are also particularly desirable.

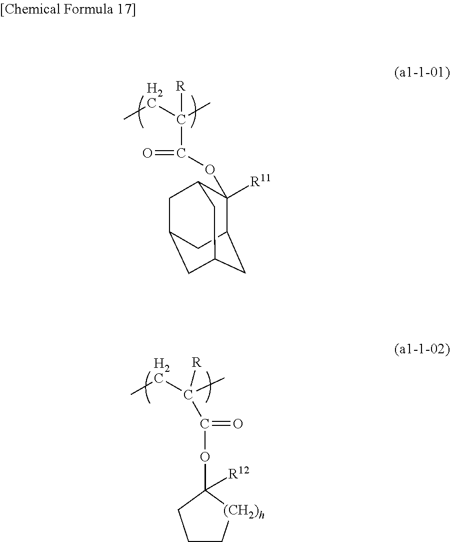

In the formulas, each R independently represents a hydrogen atom, an alkyl group of 1 to 5 carbon atoms or a halogenated alkyl group of 1 to 5 carbon atoms; R¹¹ represents an alkyl group of 1 to 5 carbon atoms; R¹² represents an alkyl group of 1 to 7 carbon atoms; and h represents an integer of 1 to 6.

In general formula (a1-1-01), R is the same as defined above. As the alkyl group of 1 to 5 carbon atoms for R¹¹, the same alkyl groups of 1 to 5 carbon atoms as those described above for R can be used, and a methyl group, an ethyl group or an isopropyl group is preferable.

In general formula (a1-1-02), R is the same as defined above. As the alkyl group of 1 to 5 carbon atoms for R¹², the same alkyl groups of 1 to 5 carbon atoms as those described above for R can be used, and a methyl group, an ethyl group or an isopropyl group is preferable. h is preferably 1 or 2, and most preferably 2.

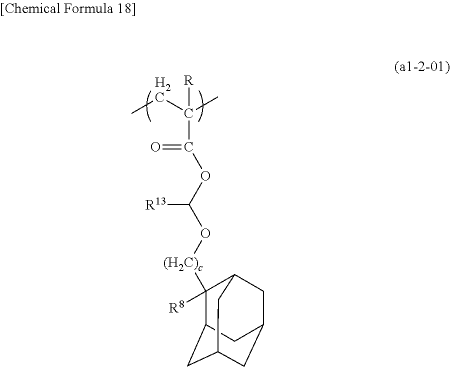

In the formula, R represents a hydrogen atom, an alkyl group of 1 to 5 carbon atoms or a halogenated alkyl group of 1 to 5 carbon atoms; R¹³ represents a hydrogen atom or a methyl group; R⁸ represents a hydrogen atom or an alkyl group of 1 to 5 carbon atoms; and c represents an integer of 0 to 3.

In general formula (a1-2-01), R is the same as defined above. As the alkyl group of 1 to 5 carbon atoms for R⁸, the same alkyl groups of 1 to 5 carbon atoms as those described above for R can be used, and a methyl group, an ethyl group or an isopropyl group is preferable. As R⁸, a hydrogen atom, a methyl group, an ethyl group or an isopropyl group is preferable. c is preferably 0 to 2, and more preferably 0 or 1.

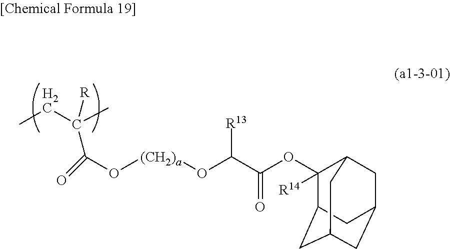

In the formula, R represents a hydrogen atom, an alkyl group of 1 to 5 carbon atoms or a halogenated alkyl group of 1 to 5 carbon atoms; R¹⁴ is the same as defined above; R¹³ represents a hydrogen atom or a methyl group; and a represents an integer of 1 to 10.

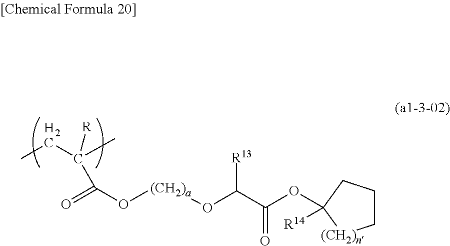

In the formula, R represents a hydrogen atom, an alkyl group of 1 to 5 carbon atoms or a halogenated alkyl group of 1 to 5 carbon atoms; R¹⁴ is the same as defined above; R¹³ represents a hydrogen atom or a methyl group; a represents an integer of 1 to 10; and n′ represents an integer of 1 to 6.

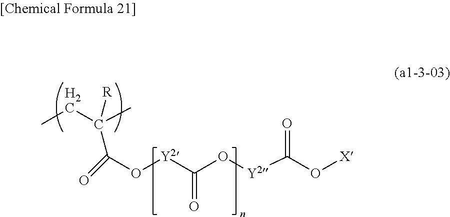

In the formula, R is the same as defined above; each of Y²′ and Y²″ independently represents a divalent linking group; X′ represents an acid dissociable group; and n represents an integer of 0 to 3.

In the above general formulas (a1-3-01) to (a1-3-03), R is the same as defined above.

R¹³ is preferably a hydrogen atom.

n′ is preferably 1 or 2, and most preferably 2.

a is preferably an integer of 1 to 8, more preferably an integer of 2 to 5, and most preferably 2.

As the divalent linking group for Y²′ and Y²″, the same groups as those described above for Y² in general formula (a1-3) can be used.

As Y²′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As Y²″, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As the acid dissociable group for X′, the same groups as those described above can be used. X′ is preferably a tertiary alkyl ester-type acid dissociable group, more preferably the aforementioned group which has a tertiary carbon atom on the ring structure of a monovalent aliphatic cyclic group. Among the aforementioned groups, a group represented by general formula (1-1) above is preferable.

n represents an integer of 0 to 3, preferably an integer of 0 to 2, more preferably 0 or 1, and most preferably 1.

In the component (A1), the amount of the structural unit (a1) based on the combined total of all structural units constituting the component (A1) is preferably 5 to 80 mol %, more preferably 10 to 80 mol %, and still more preferably 15 to 75 mol %. When the amount of the structural unit (a1) is at least as large as the lower limit of the above-mentioned range, a pattern can be easily formed using a resist composition prepared from the component (A1). On the other hand, when the amount of the structural unit (a1) is no more than the upper limit of the above-mentioned range, a good balance can be achieved with the other structural units.

(Structural Unit (a11))

The structural unit (a11) is a structural unit derived from a hydroxystyrene derivative and contains an acid decomposable group that exhibits increased polarity by the action of acid. Examples of the acid decomposable group for the structural unit (a11) include the same groups as those described above for the structural unit (a1).

Examples of the acid decomposable group include groups in which the hydrogen atoms of —OH within the phenolic hydroxyl groups for the structural unit (a11) have been substituted with acetal-type acid dissociable groups; and groups in which the hydrogen atoms of —OH within the phenolic hydroxyl groups for the structural unit (a11) have been substituted with tertiary alkyl ester-type acid dissociable groups or acetal-type acid dissociable groups, through —C(═O)O— or a linking group such as (—Y²—C(═O)—O—) in the above formula (a1-0-2).

In the component (A1), the amount of the structural unit (a11) based on the combined total of all structural units constituting the component (A1) is preferably 5 to 80 mol %, more preferably 10 to 80 mol %, and still more preferably 15 to 75 mol %. When the amount of the structural unit (a11) is at least as large as the lower limit of the above-mentioned range, a pattern can be easily formed using a resist composition prepared from the component (A1). On the other hand, when the amount of the structural unit (a11) is no more than the upper limit of the above-mentioned range, a good balance can be achieved with the other structural units.

(Structural Unit (a2))

The structural unit (a2) is a structural unit derived from an acrylate ester which may have the hydrogen atom bonded to the carbon atom on the α-position substituted with a sub stituent, and is at least one structural unit selected from the group consisting of structural units derived from an acrylate ester and contains a —SO₂— containing cyclic group (hereafter, referred to as “structural unit (a2^{S})”) and structural units derived from an acrylate ester and contains a lactone-containing cyclic group (hereafter, referred to as “structural unit (a2^{L})”).

By virtue of the structural unit (a2) containing a —SO₂— containing cyclic group or a lactone-containing cyclic group, a resist composition containing the component (A1) including the structural unit (a2) is capable of improving the adhesion of a resist film to a substrate and the compatibility with the developing solution containing water, thereby contributing to improvement of lithography properties.

Structural Unit (a2^{S}):

The structural unit (a2^{S}) is a structural unit derived from an acrylate ester in which a hydrogen atom bonded to the carbon atom on the α-position may be substituted with a substituent, and containing a —SO₂— containing cyclic group.

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂— containing cyclic group preferably has 3 to 30 carbon atoms, more preferably 4 to 20 carbon atoms, still more preferably 4 to 15 carbon atoms, and most preferably 4 to 12 carbon atoms. Herein, the number of carbon atoms refers to the number of carbon atoms constituting the ring skeleton, excluding the number of carbon atoms within a sub stituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton thereof has been substituted with a —O—SO₂— group and has at least one hydrogen atom removed therefrom.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic alicyclic hydrocarbon group, a group in which two hydrogen atoms have been removed from a monocycloalkane of 3 to 6 carbon atoms is preferable. Examples of the monocycloalkane include cyclopentane and cyclohexane. As the polycyclic alicyclic hydrocarbon group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxy group, an oxygen atom (═O), —COOR″, —OC(═O)R″, a hydroxyalkyl group and a cyano group.

The alkyl group for the substituent is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

As the alkoxy group for the sub stituent, an alkoxy group of 1 to 6 carbon atoms is preferable. Further, the alkoxy group is preferably a linear alkoxy group or a branched alkyl group. Specific examples of the alkoxy group include the aforementioned alkyl groups for the substituent having an oxygen atom (—O—) bonded thereto.

Examples of the halogen atom for the sub stituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

As examples of the halogenated lower alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

In those cases where R″ represents a cyclic alkyl group, the cyclic alkyl group preferably has 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the sub stituent preferably has 1 to 6 carbon atoms, and specific examples thereof include the aforementioned alkyl groups for the substituent in which at least one hydrogen atom has been substituted with a hydroxyl group.

More specific examples of the —SO₂— containing cyclic group include groups represented by general formulas (3-1) to (3-4) shown below.

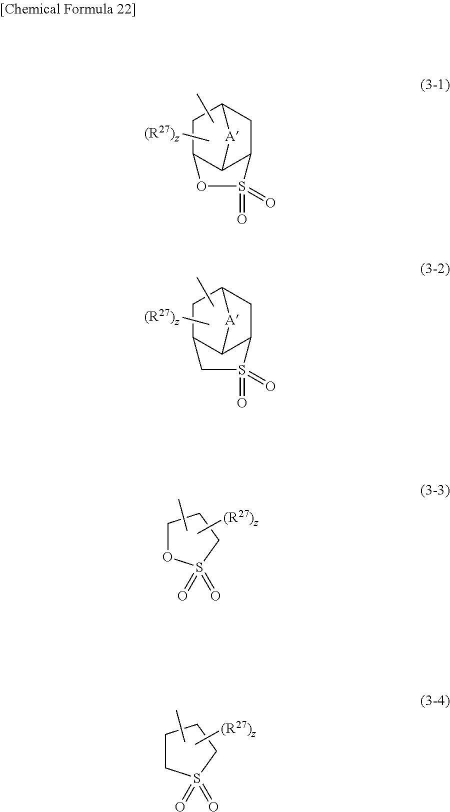

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂—, —CH₂—S—CH₂—.

A′ is preferably an alkylene group of 1 to 5 carbon atoms or —O—, is more preferably an alkylene group of 1 to 5 carbon atoms, and is most preferably a methylene group.

z represents an integer of 0 to 2, and is most preferably 0.

When z is 2, the plurality of R²⁷ may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent which the —SO₂— containing cyclic group may have can be used.

Specific examples of the —SO₂— containing cyclic groups represented by general formulas (3-1) to (3-4) are shown below. In the formulas shown below, “Ac” represents an acetyl group.

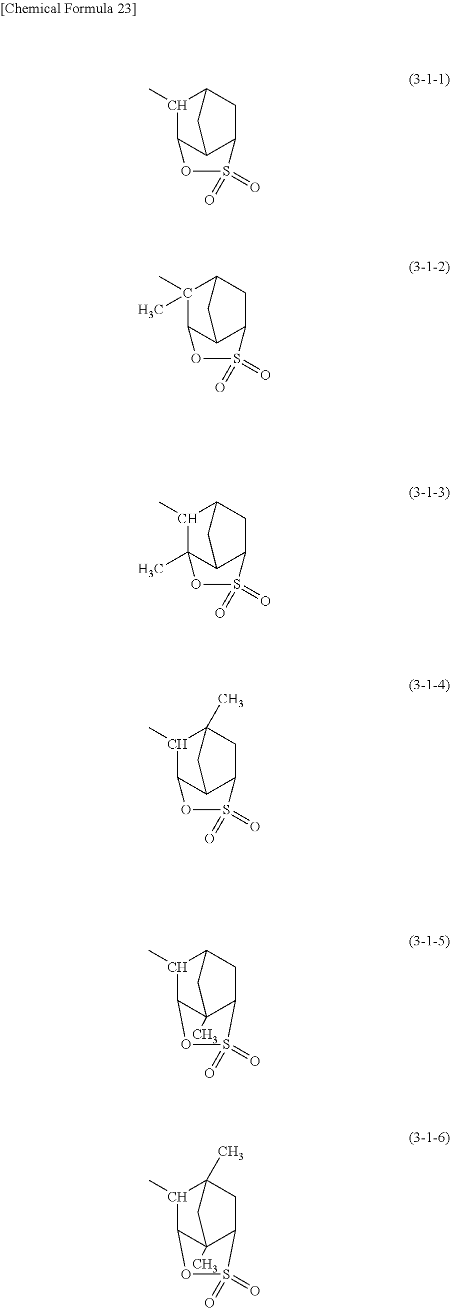

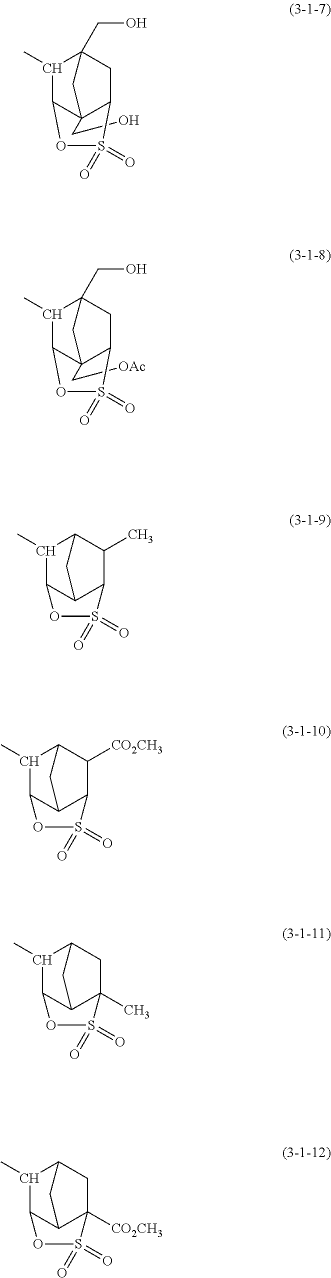

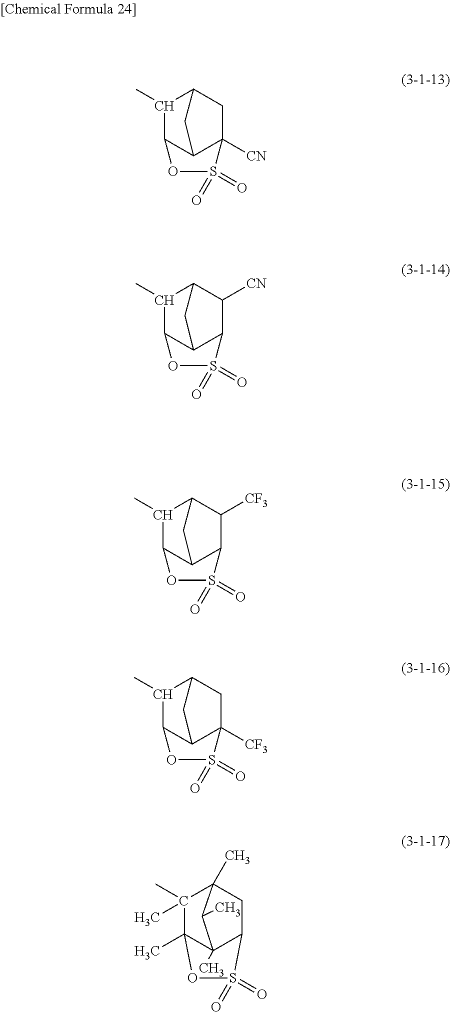

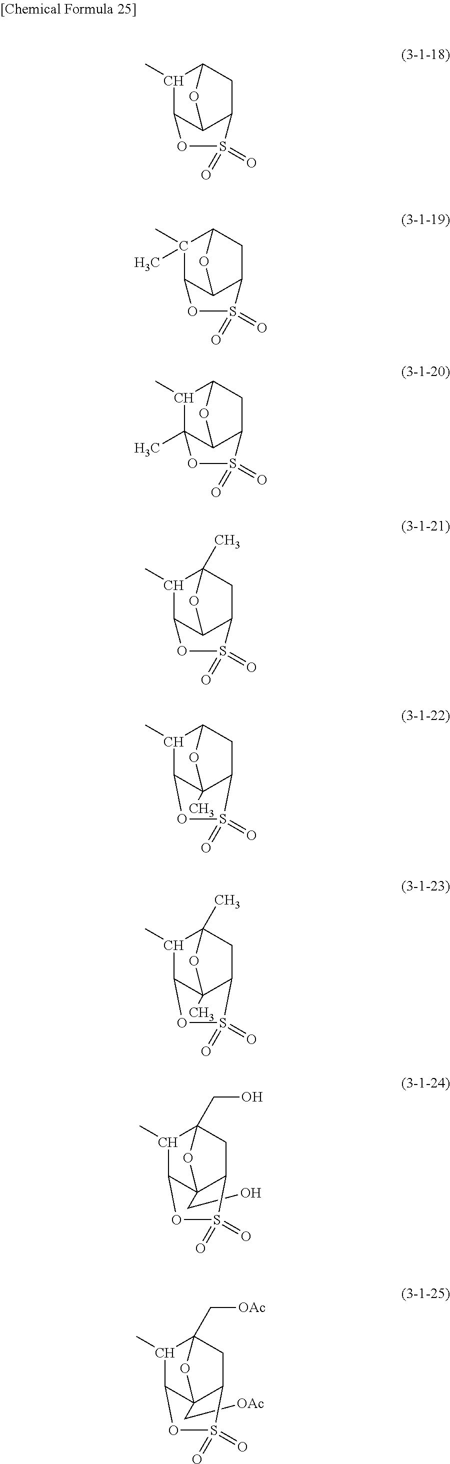

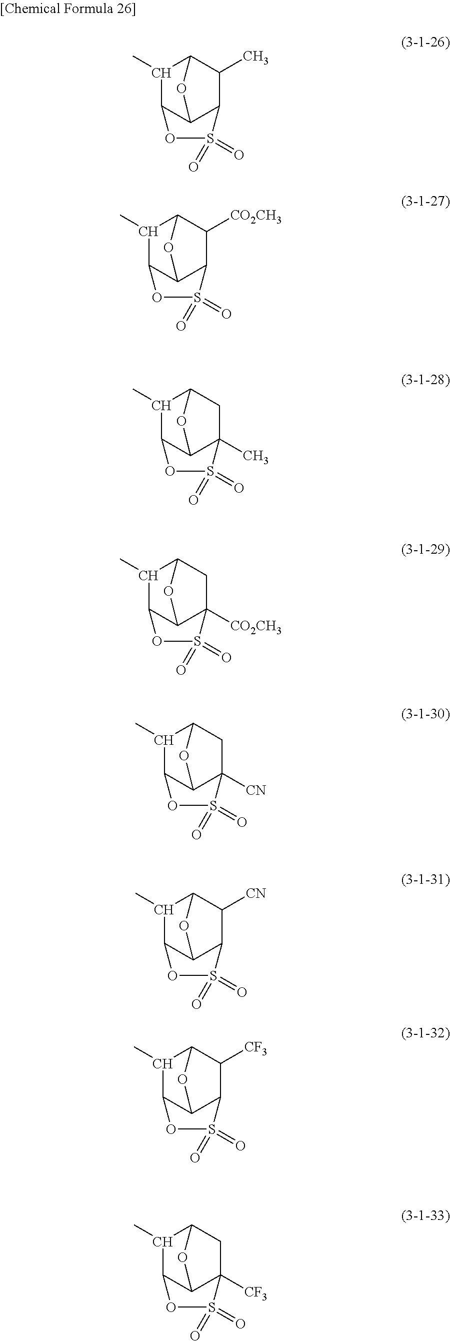

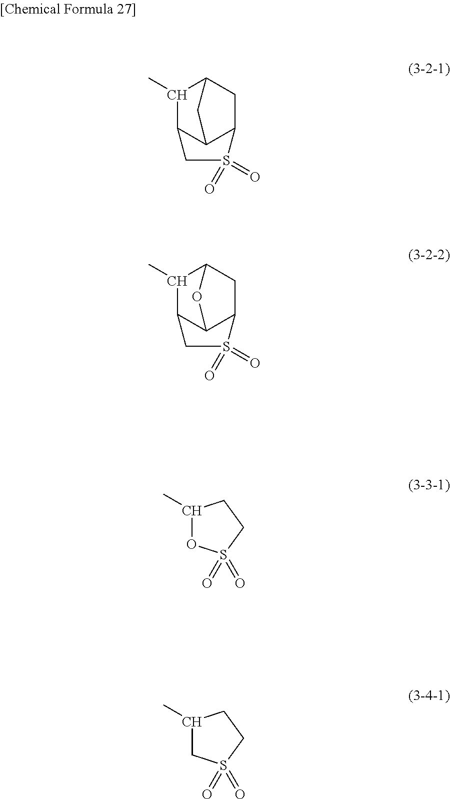

Of the various possibilities described above, as the —SO₂— containing cyclic group, a group represented by any of the aforementioned general formulas (3-1), (3-3) and (3-4) is preferable, at least one member selected from the group consisting of groups represented by the aforementioned chemical formulas (3-1-1), (3-1-18), (3-3-1) and (3-4-1) is more preferable, and a group represented by the aforementioned chemical formula (3-1-1) is most preferable.

More specific examples of the structural unit (a2^{S}) include structural units represented by general formula (a2-0) shown below.

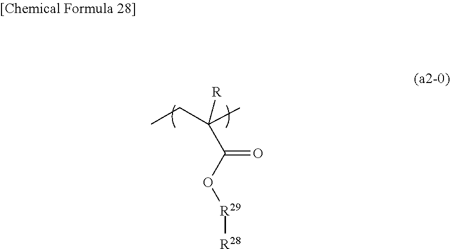

In the formula, R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

In genera formula (a2-0), R is the same as defined above.

R²⁸ is the same as defined for the aforementioned —SO₂— containing cyclic group.

R²⁹ may be either a single bond or a divalent linking group. In terms of the effects of the present invention, a divalent linking group is preferable.

The divalent linking group for R²⁹ is not particularly limited. For example, the same divalent linking groups as those described for Y² in general formula (a1-0-2) explained above in relation to the structural unit (a1) can be mentioned. Among these, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above for the aliphatic hydrocarbon group represented by Y².

As the divalent linking group containing an ester bond, a group represented by general formula: —R³⁰—C(═O)—O— (in the formula, R³⁰ represents a divalent linking group) is particularly desirable. That is, the structural unit (a2^{S}) is preferably a structural unit represented by general formula (a2-O-1) shown below.

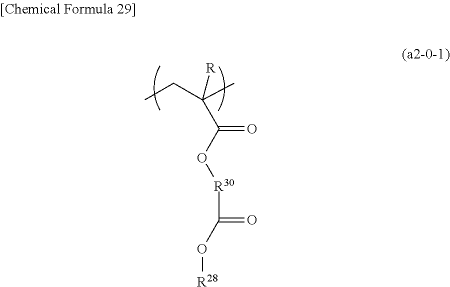

In the formula, R and R²⁸ are the same as defined above; and R³⁰ represents a divalent linking group.

R³⁰ is not particularly limited. For example, the same divalent linking groups as those described for Y² in general formula (a1-0-2) explained above in relation to the structural unit (a1) can be mentioned.

As the divalent linking group for R³⁰, a linear or branched alkylene group, a divalent alicyclic hydrocarbon group or a divalent linking group containing a hetero atom is preferable.

As the linear or branched alkylene group, the divalent alicyclic hydrocarbon group and the divalent linking group containing a hetero atom, the same linear or branched alkylene group, divalent alicyclic hydrocarbon group and divalent linking group containing a hetero atom as those described above as preferable examples of Y² can be mentioned.

Among these, a linear or branched alkylene group, or a divalent linking group containing an oxygen atom as a hetero atom is more preferable.

As the linear alkylene group, a methylene group or an ethylene group is preferable, and a methylene group is particularly desirable.

As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing an oxygen atom, a divalent linking group containing an ether bond or an ester bond is preferable, and a group represented by the aforementioned formula -A-O—B—, -[A-C(═O)—O]ₘ—B— or -A-O—C(═O)—B— is more preferable.

Among these, a group represented by the formula -A-O—C(═O)—B— is preferable, and a group represented by the formula: —(CH₂)_{c}—C(═O)—O—(CH₂)_{d}— is particularly desirable. c represents an integer of 1 to 5, and preferably 1 or 2. d represents an integer of 1 to 5, and preferably 1 or 2.

In particular, as the structural unit (a2^{S}), a structural unit represented by general formula (a0-1-11) or (a0-1-12) shown below is preferable, and a structural unit represented by general formula (a0-1-12) shown below is more preferable.

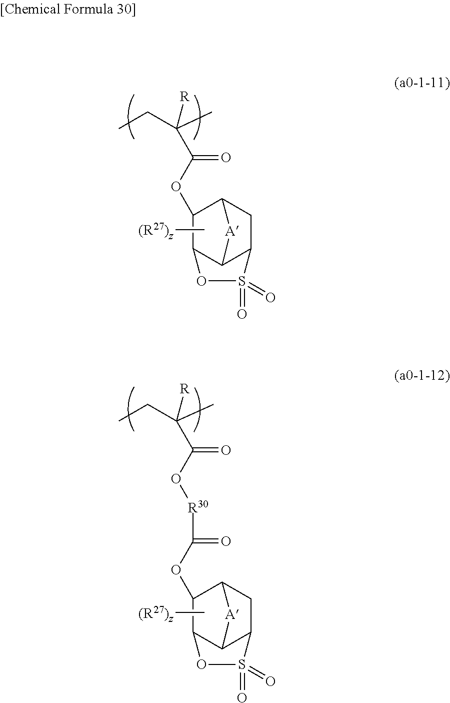

In the formulas, R, A′, R²⁷, z and R³⁰ are the same as defined above.

In general formula (a0-1-11), A′ is preferably a methylene group, an oxygen atom (—O—) or a sulfur atom (—S—).

As R³⁰, a linear or branched alkylene group or a divalent linking group containing an oxygen atom is preferable. As the linear or branched alkylene group and the divalent linking group containing an oxygen atom represented by R³⁰, the same linear or branched alkylene groups and the divalent linking groups containing an oxygen atom as those described above can be mentioned.

As the structural unit represented by general formula (a0-1-12), a structural unit represented by general formula (a0-1-12a) or (a0-1-12b) shown below is particularly desirable.

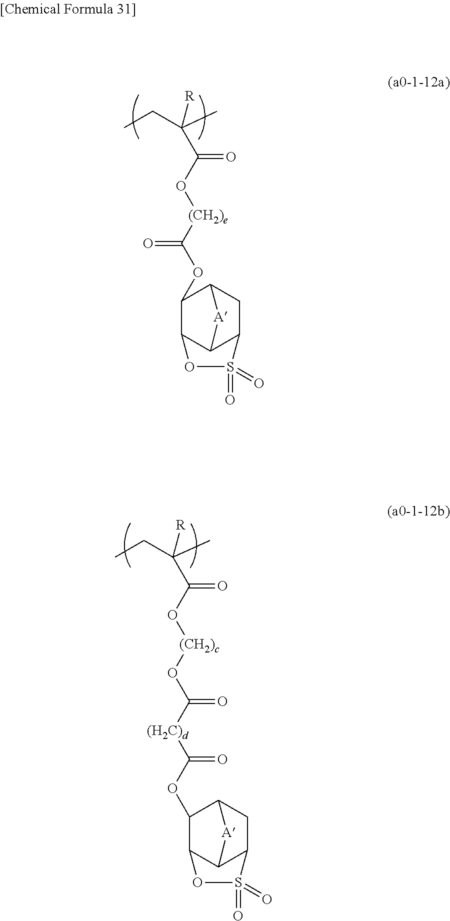

In the formulas, R and A′ are the same as defined above; and each of c to e independently represents an integer of 1 to 3.

Structural Unit (a2^{L}):

The structural unit (a2^{L}) is a structural unit derived from an acrylate ester in which the hydrogen atom bonded to the carbon atom on the α-position may be substituted with a substituent, and is a structural unit derived from an acrylate ester containing a lactone-containing cyclic group.

The term “lactone-containing cyclic group” refers to a cyclic group including a ring containing a —O—C(O)— group within the ring structure thereof (lactone ring). This “lactone ring” is counted as the first ring, so that a lactone-containing cyclic group in which the only ring structure is the lactone ring is referred to as a monocyclic group, and groups that also contain other ring structures are described as polycyclic groups regardless of the structure of the other rings. The lactone-containing cyclic group may be either a monocyclic group or a polycyclic group.

The lactone-containing cyclic group for the structural unit (a2^{L}) is not particularly limited, and an arbitrary structural unit may be used. Specific examples of lactone-containing monocyclic groups include a group in which one hydrogen atom has been removed from a 4- to 6-membered lactone ring, such as a group in which one hydrogen atom has been removed from β-propionolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

Examples of the structural unit (a2^{L}) include structural units represented by the aforementioned general formula (a2-0) in which the R²⁸ group has been substituted with a lactone-containing cyclic group. Specific examples thereof include structural units represented by general formulas (a2-1) to (a2-5) shown below.

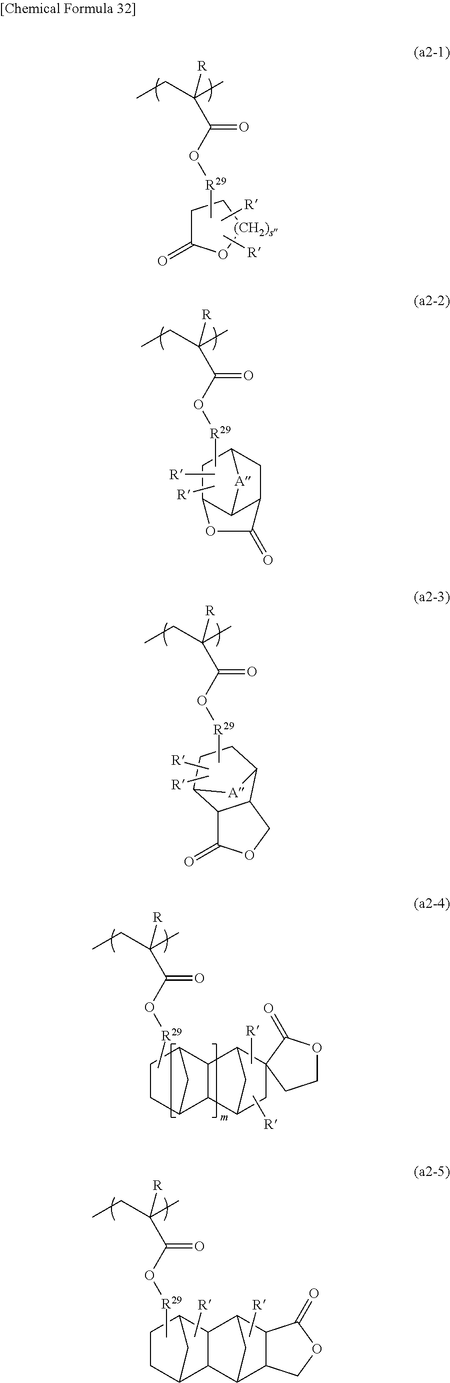

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-1) to (a2-5), R is the same as defined above for R in the structural unit (a1).

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group.

In terms of industrial availability, R′ is preferably a hydrogen atom.

The alkyl group for R″ may be any of linear, branched or cyclic.

In those cases where R″ represents a linear or branched alkyl group, the alkyl group preferably has 1 to 10 carbon atoms, and more preferably 1 to 5 carbon atoms.

In those cases where R″ represents a cyclic alkyl group, the cyclic alkyl group preferably has 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As examples of A″, the same groups as those described above for A′ in general formula (3-1) can be given. A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylethylene group is preferable, and a methylene group is particularly desirable.

R²⁹ is the same as defined for R²⁹ in the aforementioned general formula (a2-0).

In formula (a2-1), s″ is preferably 1 or 2.

Specific examples of structural units represented by general formulas (a2-1) to (a2-5) are shown below. In the formulas shown below, R^{α} represents a hydrogen atom, a methyl group or a trifluoromethyl group.

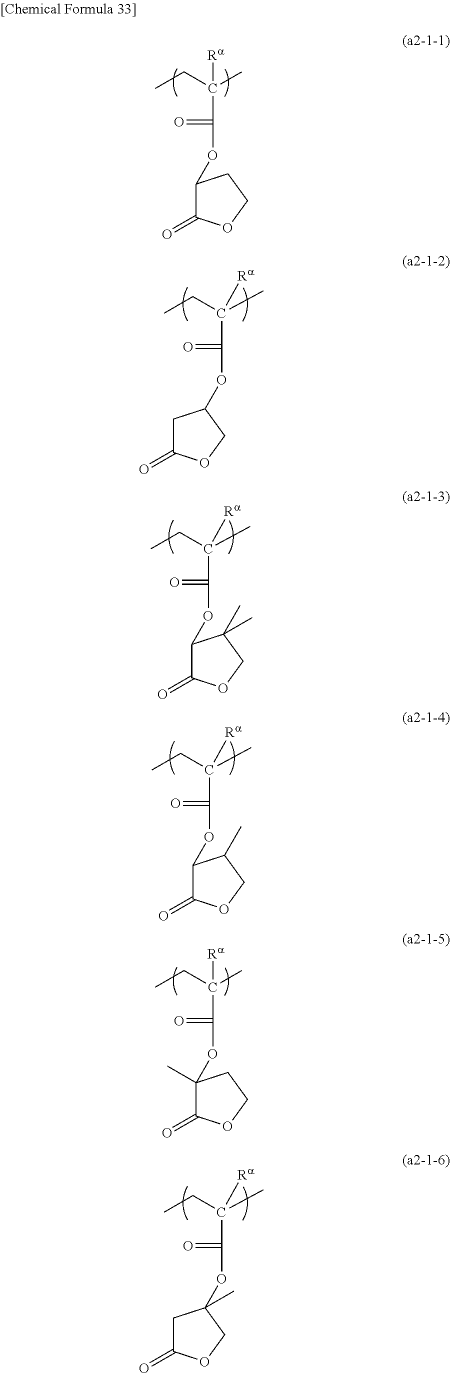

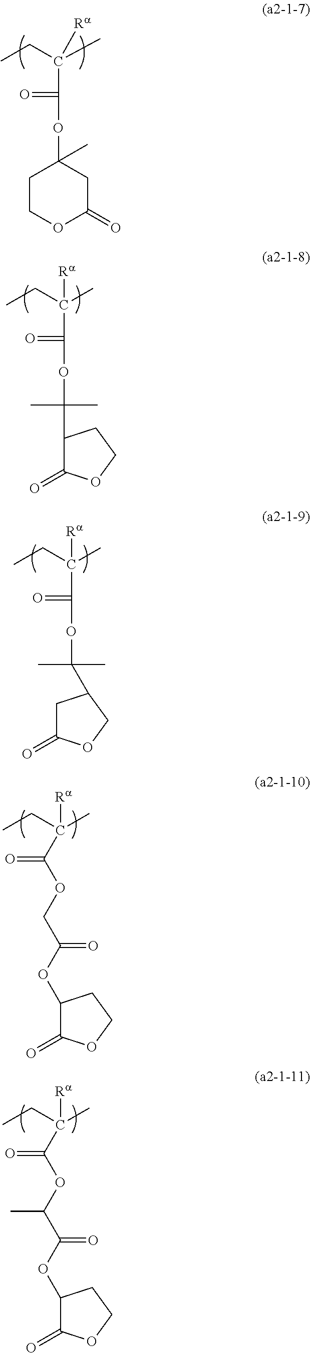

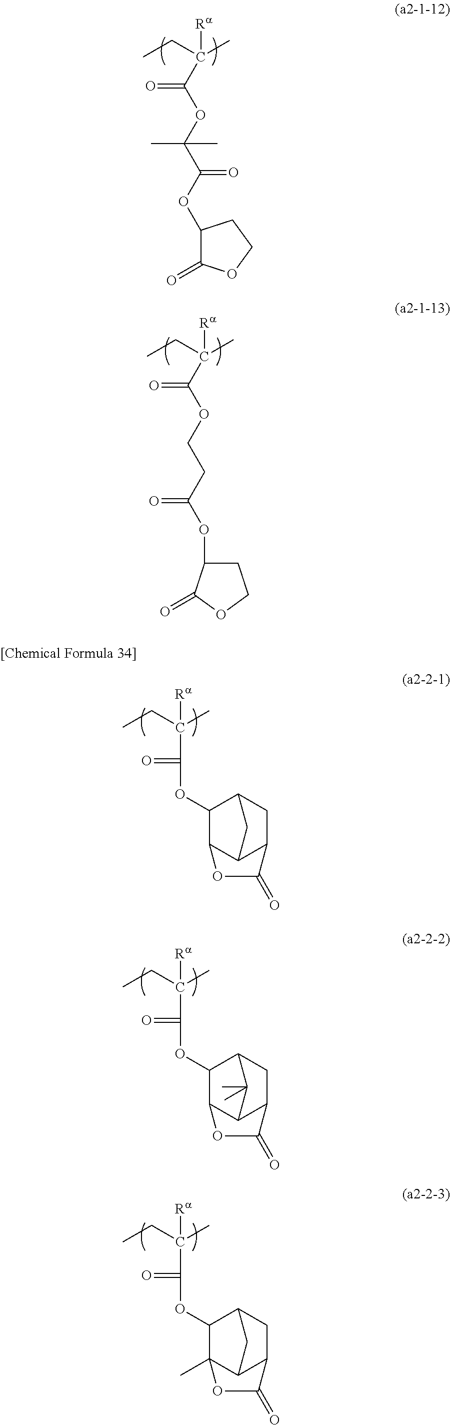

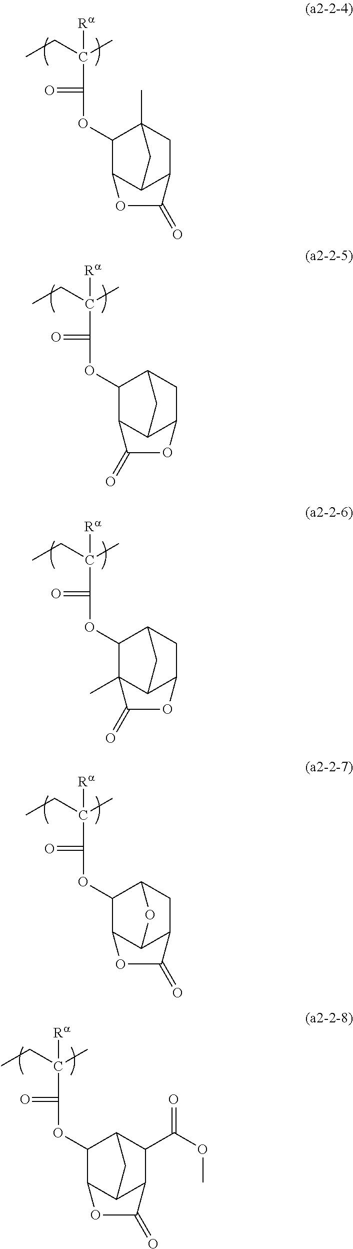

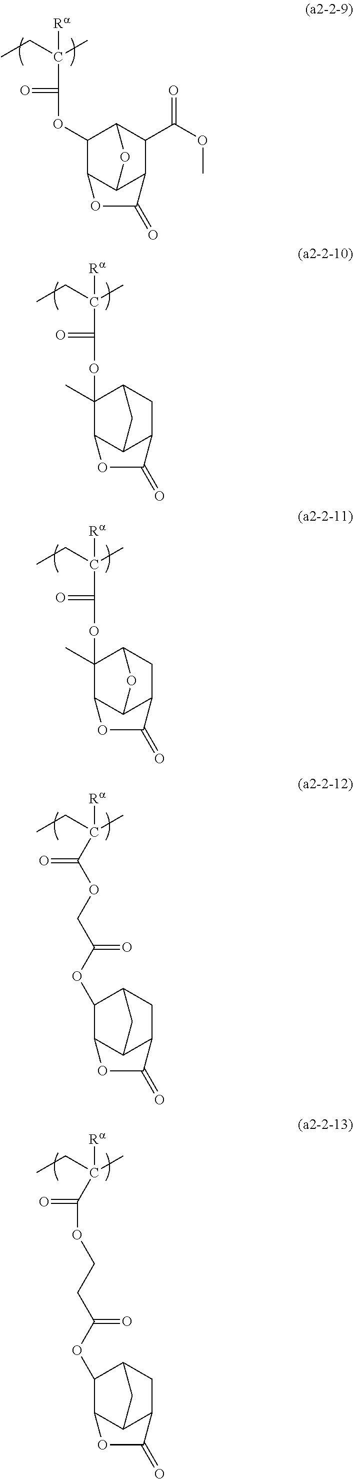

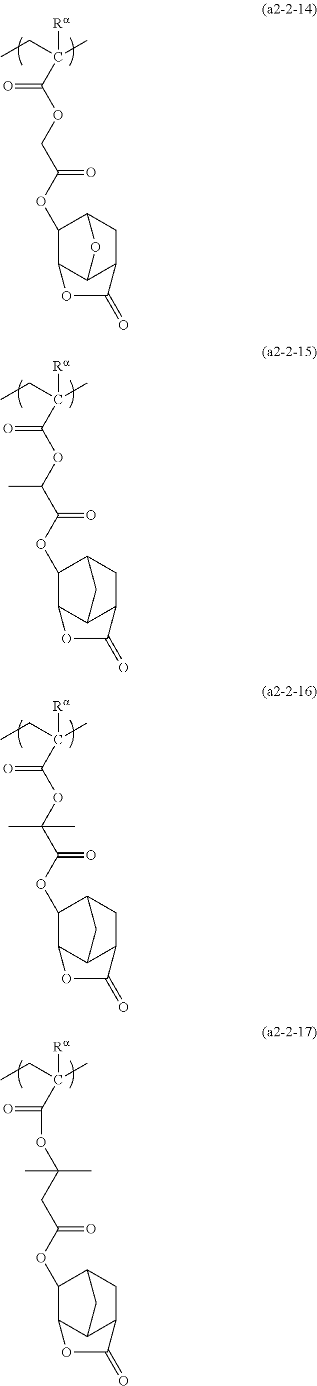

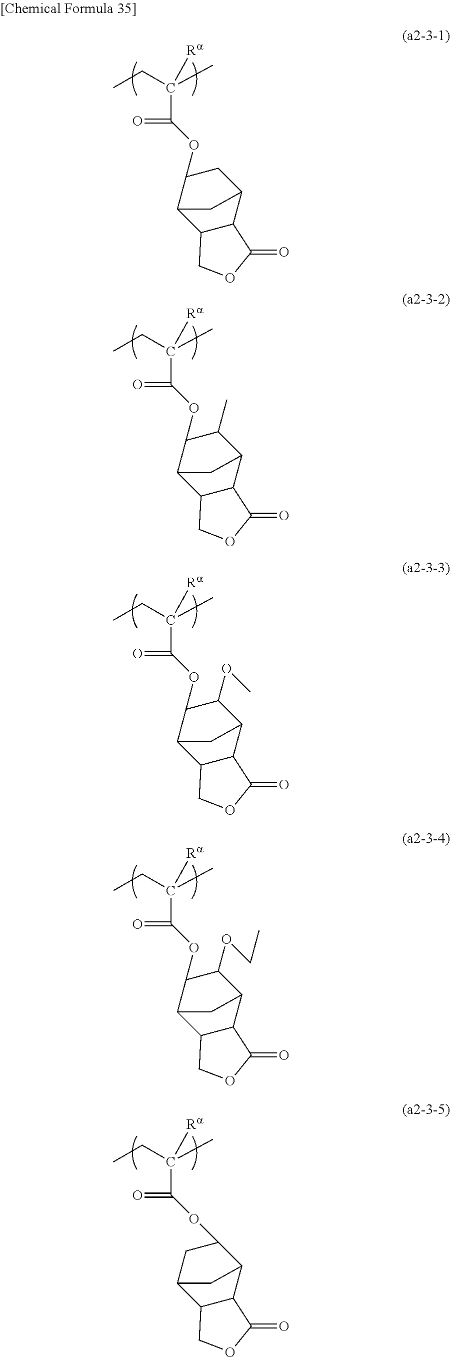

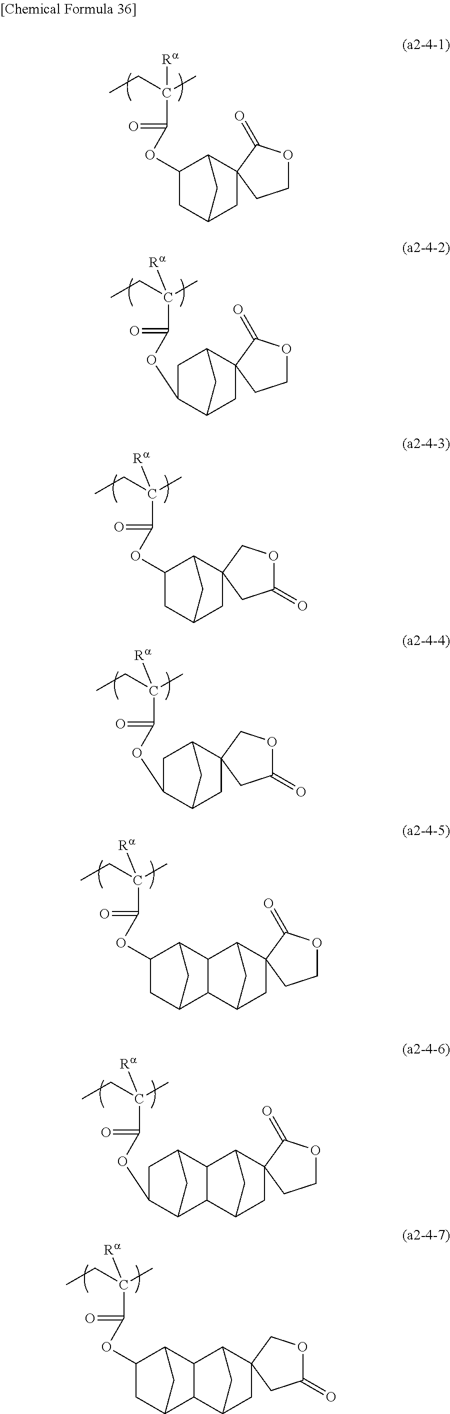

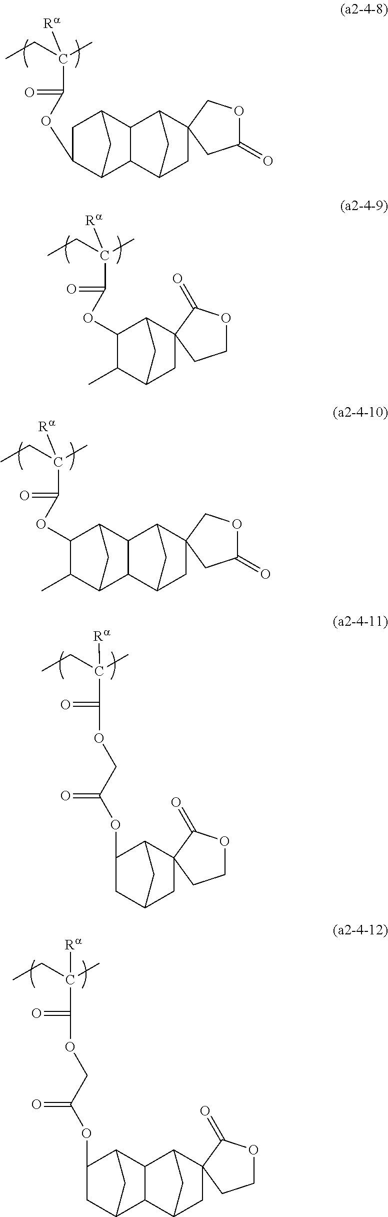

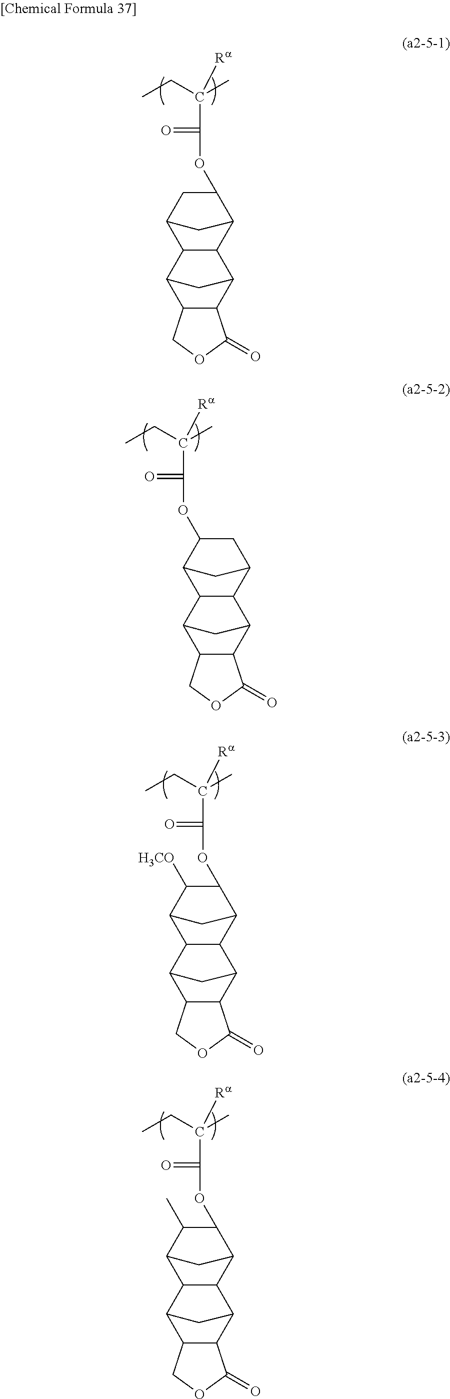

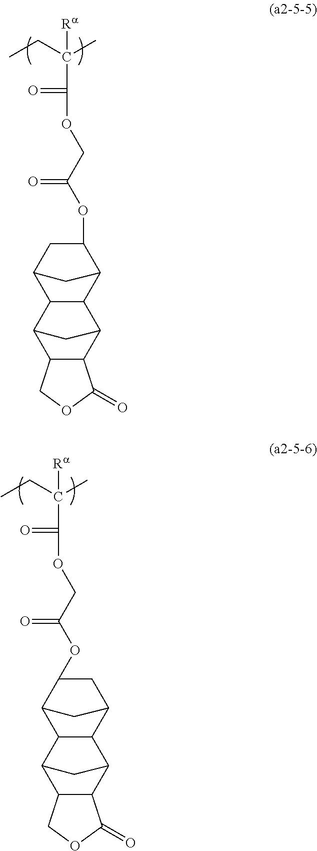

As the structural unit (a2^{L}), at least one structural unit selected from the group consisting of structural units represented by the above general formulas (a2-1) to (a2-5) is preferable, and at least one structural unit selected from the group consisting of structural units represented by general formulas (a2-1) to (a2-3) is more preferable.

Of these, it is particularly desirable to use at least one structural unit selected from the group consisting of structural units represented by the aforementioned formulas (a2-1-1), (a2-1-2), (a2-2-1), (a2-2-7), (a2-2-12), (a2-2-14), (a2-3-1) and (a2-3-5).

In the component (A1), as the structural unit (a2), one type of structural unit may be used alone, or two or more types of structural units may be used in combination. For example, as the structural unit (a2), a structural unit (a2^{S}) may be used alone, or a structural unit (a2^{L}) may be used alone, or a combination of these structural units may be used. Further, as the structural unit (a2^{S}) or the structural unit (a2^{L}), either a single type of structural unit may be used alone, or two or more types of structural units may be used in combination.

In the component (A1), the amount of the structural unit (a2) based on the combined total of all structural units constituting the component (A1) is preferably 1 to 80 mol %, more preferably 10 to 70 mol %, still more preferably 10 to 65 mol %, and most preferably 10 to 60 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

(Structural Unit (a3))

The structural unit (a3) is a structural unit derived from an acrylate ester in which the hydrogen atom bonded to the carbon atom on the α-position may be substituted with a substituent, and is a structural unit derived from an acrylate ester containing a polar group-containing aliphatic hydrocarbon group.

In the case of applying an alkali developing process, when the component (A1) includes the structural unit (a3), the hydrophilicity of the component (A) is improved, and hence, the compatibility of the component (A) with the developing solution is improved. As a result, the alkali solubility of the exposed portions improves, which contributes to favorable improvements in the resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (and preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers. The polycyclic group preferably has 7 to 30 carbon atoms.

Of the various possibilities, structural units derived from an acrylate ester that includes an aliphatic polycyclic group containing a hydroxyl group, cyano group, carboxyl group or a hydroxyalkyl group in which some of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2), (a3-3) and (a3-4) shown below are preferable.

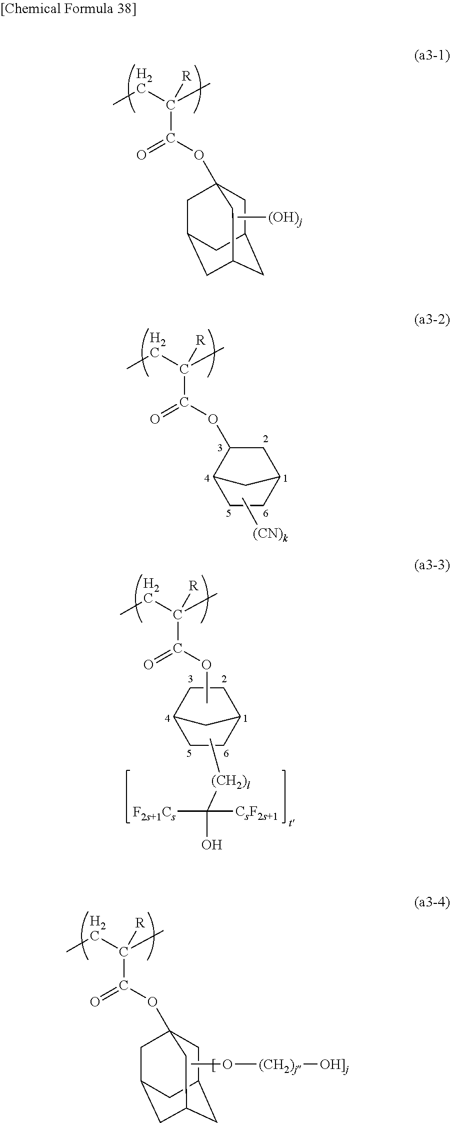

In the formulas, R is the same as defined above; j represents an integer of 1 to 3; j″ represents an integer of 1 to 3; k represents an integer of 1 to 3; t′ represents an integer of 1 to 3; 1 represents an integer of 1 to 5; and s represents an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. 1 is preferably 1. s is preferably 1. Further, in formula (a3-3), it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

In the component (A1), as the structural unit (a3), one type of structural unit may be used, or two or more types may be used in combination.

In the component (A1), the amount of the structural unit (a3) based on the combined total of all structural units constituting the component (A1) is preferably 5 to 50 mol %, more preferably 5 to 40 mol %, and still more preferably 5 to 25 mol %. When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

(Structural Unit (a4))

The component (A1) may also include a structural unit (a4) which is other than the above-mentioned structural units (a1) to (a3), as long as the effects of the present invention are not impaired.

As the structural unit (a4), any other structural unit which cannot be classified as one of the above structural units (a1) to (a3) can be used without any particular limitations, and any of the multitude of conventional structural units used within resist resins for ArF excimer lasers or KrF excimer lasers (and particularly for ArF excimer lasers) can be used.

Preferable examples of the structural unit (a4) include a structural unit derived from an acrylate ester which may have the hydrogen atom bonded to the carbon atom on the α-position substituted with a substituent and contains an acid non-dissociable aliphatic polycyclic group. Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

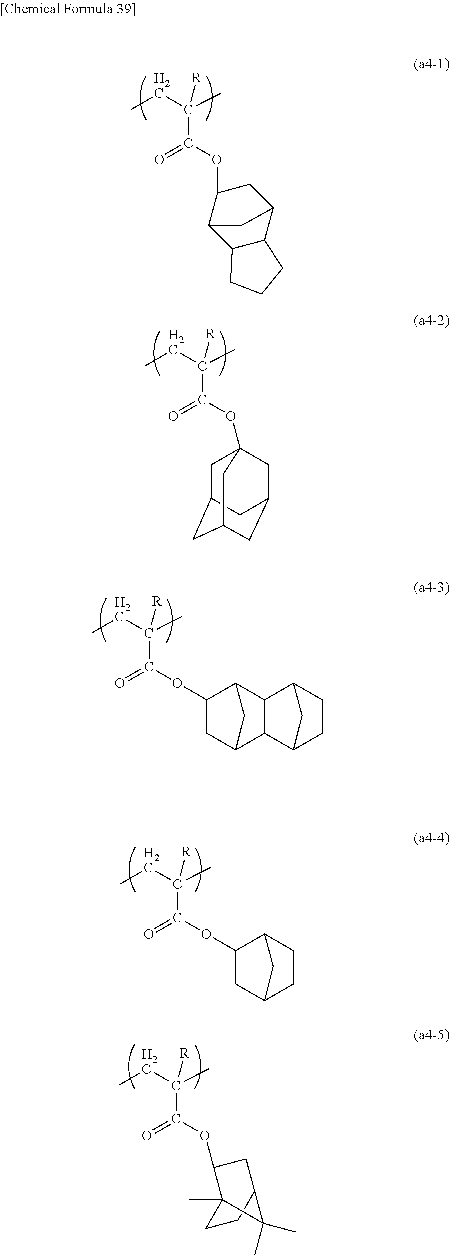

In the formulas, R is the same as defined above.

When the structural unit (a4) is included in the component (A1), the amount of the structural unit (a4) based on the combined total of all the structural units that constitute the component (A1) is preferably within the range from 1 to 30 mol %, and more preferably from 10 to 20 mol %.

The component (A1) is preferably a copolymer containing the structural unit (a1).

Examples of such copolymers include a copolymer consisting of the structural units (a1), (a2) and (a3); a copolymer consisting of the structural units (a1) and (a4); and a copolymer consisting of the structural units (a1), (a2), (a3) and (a4).

In the present invention, it is particularly desirable that the component (A1) include a suitable combination of structural units represented by general formula (A1-11) to (A1-14) shown below. In general formulas shown below, R, R²⁹, s″, R¹³, c, R⁸, j, e, A′, R¹¹, R¹² and h are the same as defined above, and the plurality of R in the formulas may be the same or different from each other.

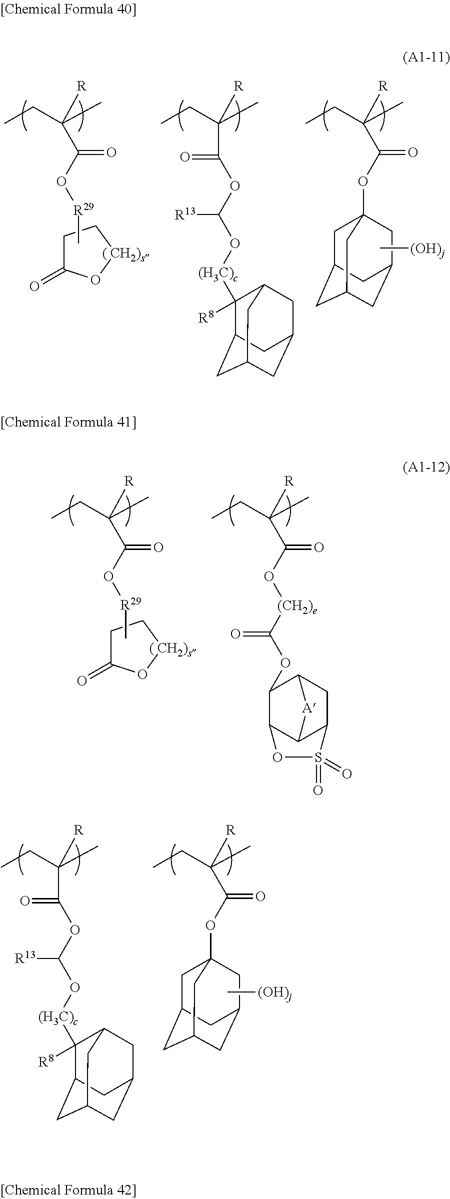

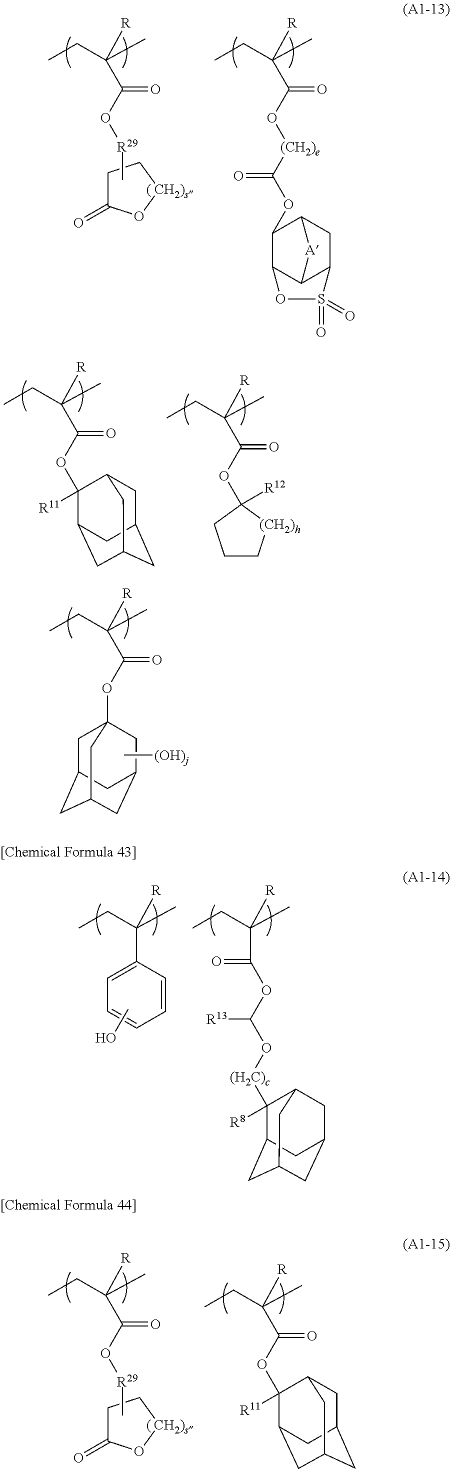

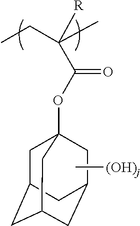

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,500 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A1) is not particularly limited, but is preferably 1.0 to 5.0, more preferably 1.0 to 3.0, and most preferably 1.2 to 2.5.

Here, Mn is the number average molecular weight.

In the component (A), as the component (A1), one type of component may be used alone, or two or more types may be used in combination.

In the component (A), the amount of the component (A1) based on the total weight of the component (A) is preferably 25% by weight or more, more preferably 50% by weight or more, still more preferably 75% by weight or more, and may be even 100% by weight. When the amount of the component (A1) is 25% by weight or more, various lithography properties are improved.

### [Component (A2)]

As the component (A2), it is preferable to use a low molecular weight compound that has a molecular weight of at least 500 and less than 2,500, contains a hydrophilic group, and also contains an acid dissociable group described above in connection with the component (A1).

Specific examples include compounds containing a plurality of phenol skeletons in which a part of the hydrogen atoms within hydroxyl groups have been substituted with the aforementioned acid dissociable groups.

Preferred examples of the component (A2) include low molecular weight phenolic compounds in which a portion of the hydroxyl group hydrogen atoms have been substituted with an aforementioned acid dissociable group. These types of compounds are known, for example, as sensitizers or heat resistance improvers for use in non-chemically amplified g-line or i-line resists, and any of these compounds may be used.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers, tetramers, pentamers and hexamers of formalin condensation products of phenols such as phenol, m-cresol, p-cresol and xylenol. Needless to say, the low molecular weight phenol compound is not limited to these examples. Among these, in terms of achieving excellent resolution and line width roughness (LWR), a phenol compound having 2 to 6 triphenylmethane skeletons is particularly desirable.

Also, there are no particular limitations on the acid dissociable group, and suitable examples include the groups described above.

As the component (A2), one type of resin may be used alone, or two or more types of resins may be used in combination.

In the resist composition for EUV according to the present invention, as the component (A), one type may be used alone, or two or more types of compounds may be used in combination.

Of the examples shown above, as the component (A), it is preferable to use one containing the component (A1).

In the resist composition for EUV according to the present invention, the amount of the component (A) can be appropriately adjusted depending on the thickness of the resist film to be formed, and the like.

### <Component (B)>

As the component (B), there is no particular limitation as long as the resist composition for EUV according to the present invention exhibits a property so that the aforementioned E0_{KrF} is greater than the aforementioned E0_{EUV}, and any of the known acid generators used in conventional chemically amplified resist compositions can be used. Examples of these acid generators are numerous, and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As an onium salt-based acid generator, for example, a compound represented by general formula (b-1) or (b-2) shown below can be used.

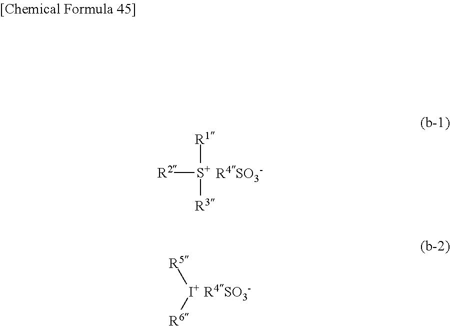

In the formulas, each of R¹″ to R³″ and R⁵″ to R⁶″ independently represents an aryl group, alkyl group or alkenyl group which may have a substituent, wherein two of R¹″ to R³″ in formula (b-1) may be bonded to each other to form a ring with the sulfur atom in the formula; and R⁴″ represents an alkyl group, halogenated alkyl group, aryl group or alkenyl group which may have a substituent.

In formula (b-1), each of R¹″ to R³″ independently represents an aryl group, alkyl group or alkenyl group which may have a substituent. In formula (b-1), two of R¹″ to R³″ may be bonded to each other to form a ring with the sulfur atom in the formula.

Further, the more the number of benzene rings included in an acid generator, the stronger the absorption of DUV region as a whole by the resist composition, which makes it more sensitive to the OoB light. Accordingly, among R¹″ to R³″, the number of aryl groups is preferably not more than 2, more preferably not more than 1, and most preferably 0.

Examples of the aryl groups for R¹″ to R³″ include an unsubstituted aryl group having 6 to 20 carbon atoms; and a substituted aryl group in which a part or all of the hydrogen atoms of the aforementioned unsubstituted aryl group has been substituted with an alkyl group, an alkoxy group, a halogen atom, a hydroxyl group, an oxo group (═O), an aryl group, an alkoxyalkyloxy group, an alkoxycarbonylalkyloxy group, —C(═O)—O—R⁶′, —O—C(═O)—R⁷′, —O—R⁸′ or the like. Each of R⁶′, R⁷′ and R⁸′ represents a linear or branched saturated hydrocarbon group of 1 to 25 carbon atoms, a cyclic saturated hydrocarbon group of 3 to 20 carbon atoms, or a linear or branched aliphatic unsaturated hydrocarbon group of 2 to 5 carbon atoms.

The unsubstituted aryl group for R¹″ to R³″ is preferably an aryl group having 6 to 10 carbon atoms because it can be synthesized at a low cost. Specific examples thereof include a phenyl group and a naphthyl group.

The alkyl group as the substituent for the substituted aryl group represented by R¹″ to R³″ is preferably an alkyl group having 1 to 5 carbon atoms, and a methyl group, an ethyl group, a propyl group, an n-butyl group, or a tert-butyl group is particularly desirable.

The alkoxy group as the substituent for the substituted aryl group is preferably an alkoxy group having 1 to 5 carbon atoms, and a methoxy group, an ethoxy group, an n-propoxy group, an iso-propoxy group, an n-butoxy group or a tert-butoxy group is particularly desirable.

The halogen atom as the substituent for the substituted aryl group is preferably a fluorine atom.

As the aryl group as the substituent for the substituted aryl group, the same aryl groups as those described above for R¹″ to R³″ can be mentioned, and an aryl group of 6 to 20 carbon atoms is preferable, an aryl group of 6 to 10 carbon atoms is more preferable, and a phenyl group or a naphthyl group is still more preferable.

Examples of the alkoxyalkyloxy group as the substituent for the substituted aryl group include groups represented by a general formula shown below:

—O—C(R⁴⁷)(R⁴⁸)—O—R⁴⁹ [wherein each of R⁴⁷ and R⁴⁸ independently represents a hydrogen atom or a linear or branched alkyl group; and R⁴⁹ represents an alkyl group].

The alkyl group for R⁴⁷ and R⁴⁸ preferably has 1 to 5 carbon atoms, and may be either linear or branched. As the alkyl group, an ethyl group or a methyl group is preferable, and a methyl group is most preferable.

It is preferable that at least one of R⁴⁷ and R⁴⁸ be a hydrogen atom. It is particularly desirable that at least one of R⁴⁷ and R⁴⁸ be a hydrogen atom, and the other be a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms. Examples thereof include a methyl group, an ethyl group, a propyl group, an n-butyl group and a tert-butyl group.

The cyclic alkyl group for R⁴⁹ preferably has 4 to 15 carbon atoms, more preferably 4 to 12 carbon atoms, and most preferably 5 to 10 carbon atoms. Specific examples thereof include groups in which one or more hydrogen atoms have been removed from a monocycloalkane or a polycycloalkane such as a bicycloalkane, tricycloalkane or tetracycloalkane, and which may or may not be substituted with an alkyl group of 1 to 5 carbon atoms, a fluorine atom or a fluorinated alkyl group. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Examples of the alkoxycarbonylalkyloxy group as the substituent for the substituted aryl group include groups represented by a general formula shown below: —O—R⁵⁰—C(═O)—R⁵⁶ [wherein R⁵⁰ represents a linear or branched alkylene group; and R⁵⁶ represents a tertiary alkyl group].

The linear or branched alkylene group for R⁵⁰ preferably has 1 to 5 carbon atoms, and examples thereof include a methylene group, an ethylene group, a trimethylene group, a tetramethylene group and a 1,1-dimethylethylene group.

Examples of the tertiary alkyl group for R⁵⁶ include a 2-methyl-2-adamantyl group, a 2-ethyl-2-adamantyl group, a 1-methyl-1-cyclopentyl group, a 1-ethyl-1-cyclopentyl group, a 1-methyl-1-cyclohexyl group, a 1-ethyl-1-cyclohexyl group, a 1-(1-adamantyl)-1-methylethyl group, a 1-(1-adamantyl)-1-methylpropyl group, a 1-(1-adamantyl)-1-methylbutyl group, a 1-(1-adamantyl)-1-methylpentyl group, a 1-(1-cyclopentyl)-1-methylethyl group, a 1-(1-cyclopentyl)-1-methylpropyl group, a 1-(1-cyclopentyl)-1-methylbutyl group, a 1-(1-cyclopentyl)-1-methylpentyl group, a 1-(1-cyclohexyl)-1-methylethyl group, a 1-(1-cyclohexyl)-1-methylpropyl group, a 1-(1-cyclohexyl)-1-methylbutyl group, a 1-(1-cyclohexyl)-1-methylpentyl group, a tert-butyl group, a tert-pentyl group and a tert-hexyl group.

Further, a group in which R⁵⁶ in the group represented by the aforementioned general formula: —O—R⁵⁰—C(═O)—O—R⁵⁶ has been substituted with R⁵⁶′ can also be mentioned. R⁵⁶′ represents a hydrogen atom, an alkyl group, a fluorinated alkyl group or an aliphatic cyclic group which may contain a hetero atom.

The alkyl group for R⁵⁶′ is the same as defined for the alkyl group for the aforementioned R⁴⁹.

Examples of the fluorinated alkyl group for R⁵⁶′ include groups in which part or all of the hydrogen atoms within the alkyl group for R⁴⁹ has been substituted with a fluorine atom.

Examples of the aliphatic cyclic group for R⁵⁶′ which may contain a hetero atom include an aliphatic cyclic group which does not contain a hetero atom, an alipahtic cyclic group containing a hetero atom in the ring structure, and an aliphatic cyclic group in which a hydrogen atom has been substituted with a hetero atom.

As an aliphatic cyclic group for R⁵⁶′ which does not contain a hetero atom, a group in which one or more hydrogen atoms have been removed from a monocycloalkane or a polycycloalkane such as a bicycloalkane, a tricycloalkane or a tetracycloalkane can be mentioned. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Specific examples of the aliphatic cyclic group for R⁵⁶′ containing a hetero atom in the ring structure include groups represented by formulas (L1) to (L6) and (S1) to (S4) described later.

As the aliphatic cyclic group for R⁵⁶′ in which a hydrogen atom has been substituted with a hetero atom, an aliphatic cyclic group in which a hydrogen atom has been substituted with an oxygen atom (═O) can be mentioned.

Each of R⁶′, R⁷′ and R⁸′ in —C(═O)—O—R⁶′, —O—C(═O)—R⁷′ and —O—R⁸′ represents a linear or branched saturated hydrocarbon group of 1 to 25 carbon atoms, a cyclic saturated hydrocarbon group of 3 to 20 carbon atoms, or a linear or branched, aliphatic unsaturated hydrocarbon group of 2 to 5 carbon atoms.

The linear or branched, saturated hydrocarbon group has 1 to 25 carbon atoms, preferably 1 to 15 carbon atoms, and more preferably 4 to 10 carbon atoms.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of the branched, saturated hydrocarbon group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group, but excluding tertiary alkyl groups.

The linear or branched, saturated hydrocarbon group may have a substituent. Examples of the substituent include an alkoxy group, a halogen atom, a halogenated alkyl group, a hydroxyl group, an oxygen atom (═O), a cyano group and a carboxy group.

The alkoxy group as the substituent for the linear or branched saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched, saturated hydrocarbon group include a fluorine atom, a chlorine atom, a bromine atom and an iodine atom, and a fluorine atom is preferable.

Examples of the halogenated alkyl group as the substituent for the linear or branched, saturated hydrocarbon group include a group in which part or all of the hydrogen atoms within the aforementioned linear or branched, saturated hydrocarbon group have been substituted with the aforementioned halogen atoms.

The cyclic saturated hydrocarbon group of 3 to 20 carbon atoms for R⁶′, R⁷′ and R⁸′ may be either a polycyclic group or a monocyclic group, and examples thereof include groups in which one hydrogen atom has been removed from a monocycloalkane, and groups in which one hydrogen atom has been removed from a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one or more hydrogen atoms have been removed from a polycycloalkane such as adamantane, norbornane, isobornane, tricyclodecane or tetracyclododecane.

The cyclic, saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one or more hydrogen atoms have been removed therefrom, can be used. Further, the ring may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter example, as the substituent, the same substituent groups as those for the aforementioned linear or branched alkyl group, or a lower alkyl group can be used.

Alternatively, R⁶′, R⁷′ and R⁸′ may be a combination of a linear or branched alkyl group and a cyclic alkyl group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

Examples of the linear aliphatic unsaturated hydrocarbon group for R⁶′, R⁷′ and R⁸′ include a vinyl group, a propenyl group (an allyl group) and a butynyl group.

Examples of the branched aliphatic unsaturated hydrocarbon group for R⁶′, R⁷′ and R⁸′ include a 1-methylpropenyl group and a 2-methylpropenyl group.

The aforementioned linear or branched, aliphatic unsaturated hydrocarbon group may have a substituent. Examples of the substituents include the same substituents as those which the aforementioned linear or branched alkyl group may have.

Among the aforementioned examples, as R⁷′ and R⁸′, in terms of improvement in lithography properties and shape of the resist pattern, a linear or branched, saturated hydrocarbon group of 1 to 15 carbon atoms or a cyclic saturated hydrocarbon group of 3 to 20 carbon atoms is preferable.

The aryl group for each of R¹″ to R³″ is preferably a phenyl group or a naphthyl group.

Examples of the alkyl group for R¹″ to R³″ include linear, branched or cyclic alkyl groups of 1 to 10 carbon atoms. Among these, alkyl groups of 1 to 5 carbon atoms are preferable as the resolution becomes excellent. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

The alkenyl group for R¹″ to R³″ preferably has 2 to 10 carbon atoms, more preferably 2 to 5 carbon atoms, and still more preferably 2 to 4 carbon atoms. Specific examples thereof include a vinyl group, a propenyl group (an allyl group), a butynyl group, a 1-methylpropenyl group and a 2-methylpropenyl group.

When two of R¹″ to R³″ are bonded to each other to form a ring with the sulfur atom in the formula, it is preferable that the two of R¹″ to R³″ form a 3 to 10-membered ring including the sulfur atom, and it is particularly desirable that the two of R¹″ to R³″ form a 5 to 7-membered ring including the sulfur atom.

When two of R¹″ to R³″ are bonded to each other to form a ring with the sulfur atom in the formula, the remaining one of R¹″ to R³″ is preferably an aryl group. As examples of the aryl group, the same as the above-mentioned aryl groups for R¹″ to R³″ can be given.

Specific examples of cation moiety of the compound represented by the above general formula (b-1) include triphenylsulfonium, (3,5-dimethylphenyl)diphenylsulfonium, (4-(2-adamantoxymethyloxy)-3,5-dimethylphenyl)diphenylsulfonium, (4-(2-adamantoxymethyloxy)phenyl)diphenylsulfonium, (4-(tert-butoxycarbonylmethyloxy)phenyl)diphenylsulfonium, (4-(tert-butoxycarbonylmethyloxy)-3,5-dimethylphenyl)diphenylsulfonium, (4-(2-methyl-2-adamantyloxycarbonylmethyloxy)phenyl)diphenylsulfonium, (4-(2-methyl-2-adamantyloxycarbonylmethyloxy)-3,5-dimethylphenyl)diphenylsulfonium, tri(4-methylphenyl)sulfonium, dimethyl(4-hydroxynaphthyl)sulfonium, monophenyldimethylsulfonium, diphenylmonomethylsulfonium, (4-methylphenyl)diphenylsulfonium, (4-methoxyphenyl)diphenylsulfonium, tri(4-tert-butyl)phenylsulfonium, diphenyl(1-(4-methoxy)naphthyl)sulfonium, di(1-naphthyl)phenylsulfonium, 1-phenyltetrahydrothiophenium, 1-(4-methylphenyl)tetrahydrothiophenium, 1-(3,5-dimethyl-4-hydroxyphenyl)tetrahydrothiophenium, 1-(4-methoxynaphthalene-1-yl)tetrahydrothiophenium, 1-(4-ethoxynaphthalene-1-yl)tetrahydrothiophenium, 1-(4-n-butoxynaphthalene-1-yl)tetrahydrothiophenium, 1-phenyltetrahydrothiopyranium, 1-(4-hydroxyphenyl)tetrahydrothiopyranium, 1-(3,5-dimethyl-4-hydroxyphenyl)tetrahydrothiopyranium and 1-(4-methylphenyl)tetrahydrothiopyranium.

Further, specific examples of the cation moiety for the compound represented by the above formula (b-1) include cation moieties shown below.

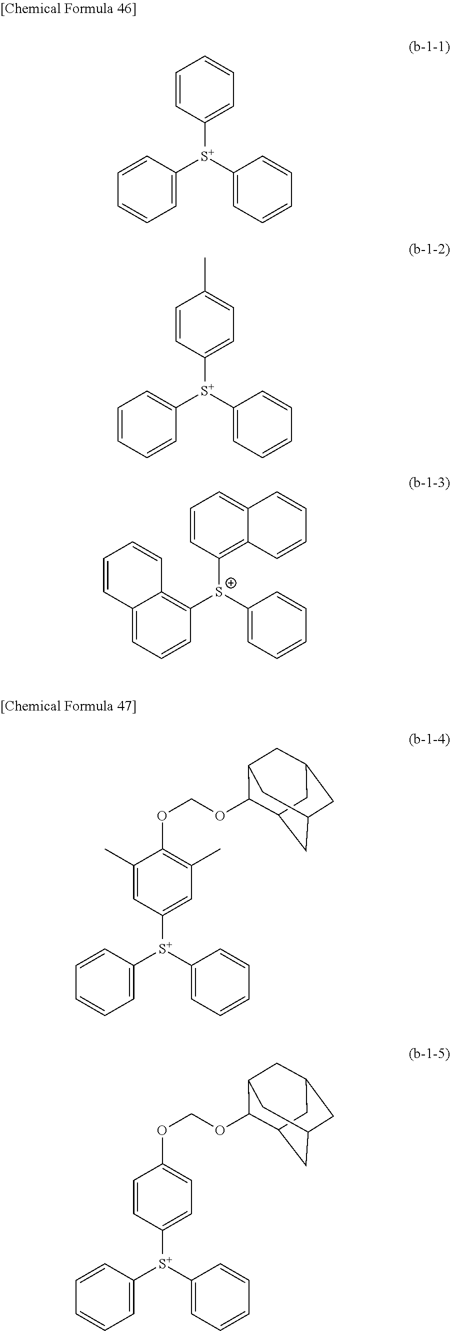

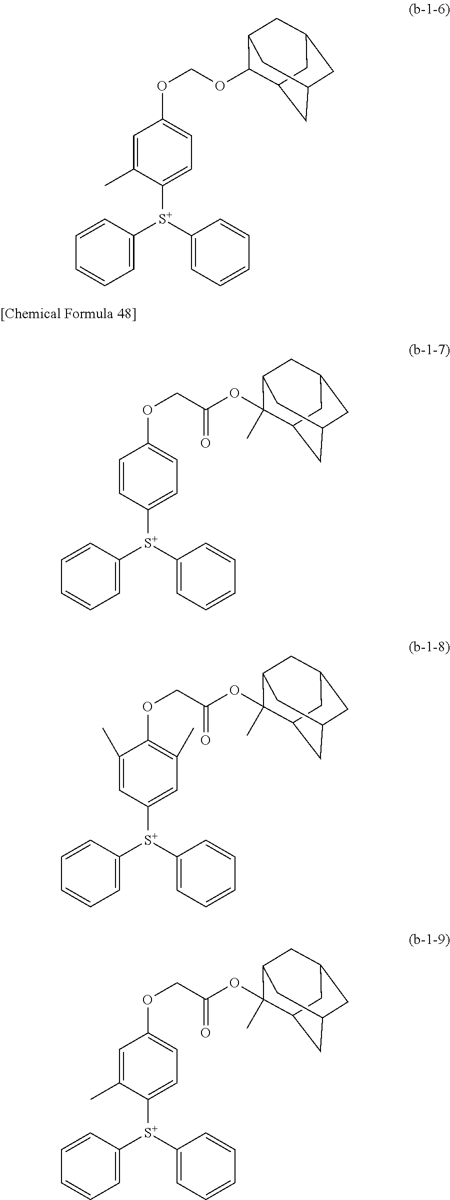

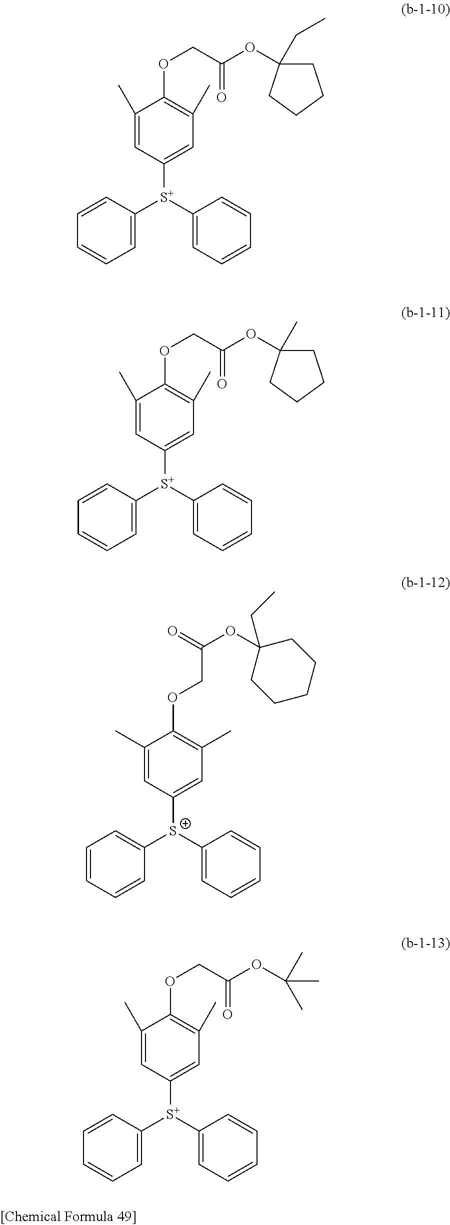

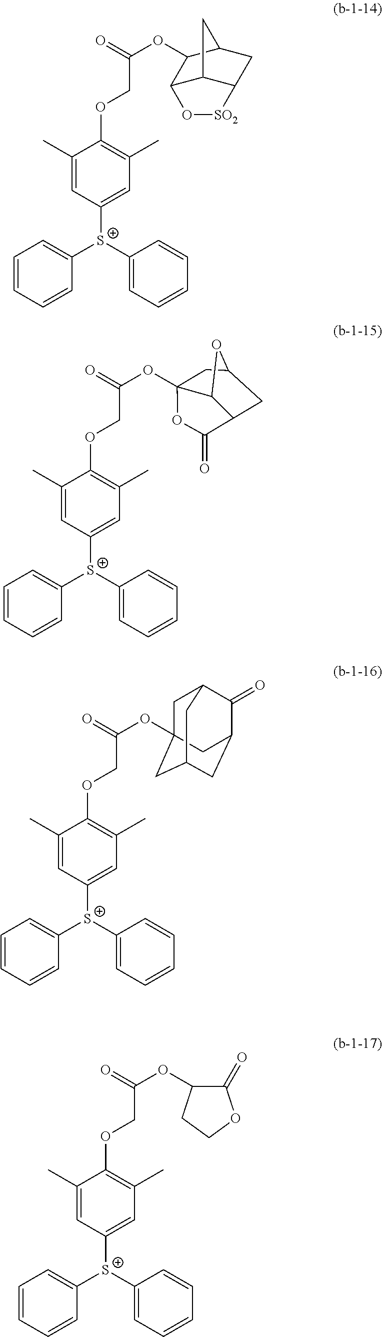

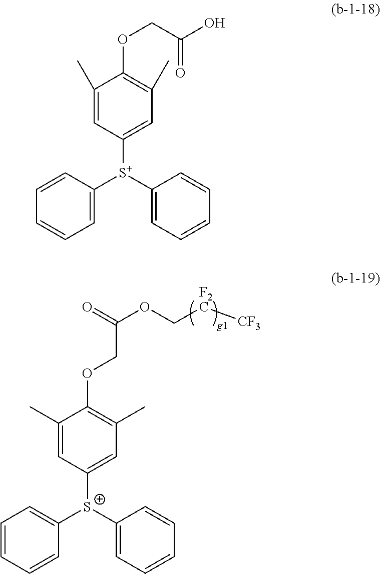

In the formula, g1 represents a recurring number, and is an integer of 1 to 5.

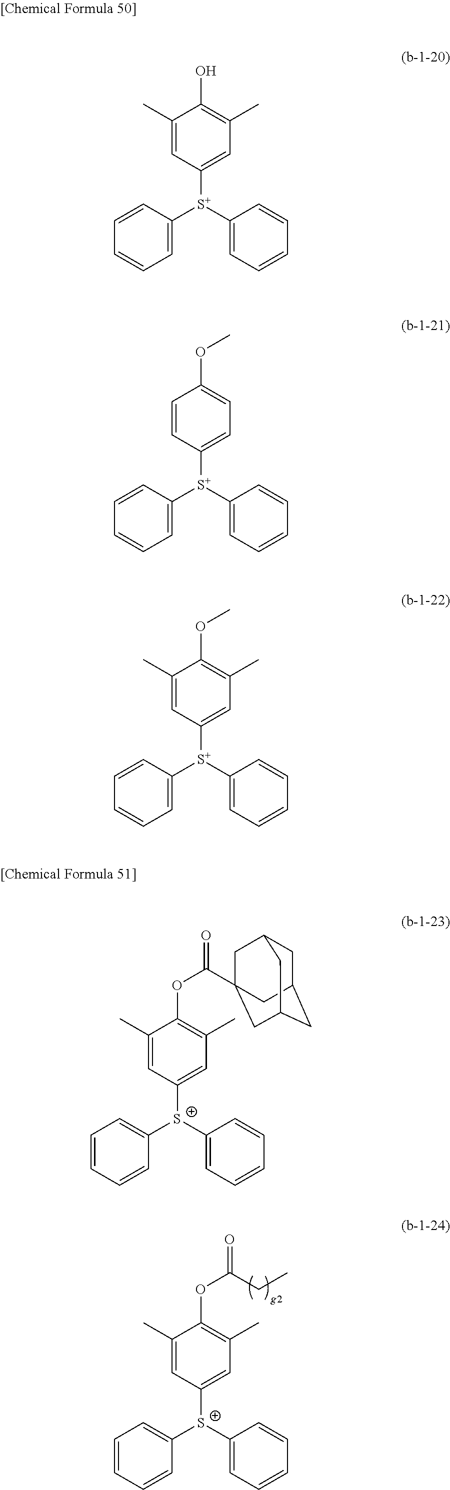

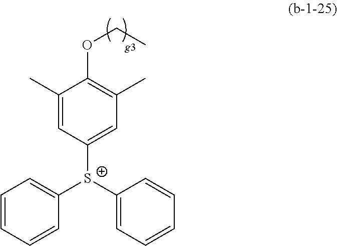

In the formula, g2 and g3 represent recurring numbers, wherein g2 is an integer of 0 to 20, and g3 is an integer of 0 to 20.

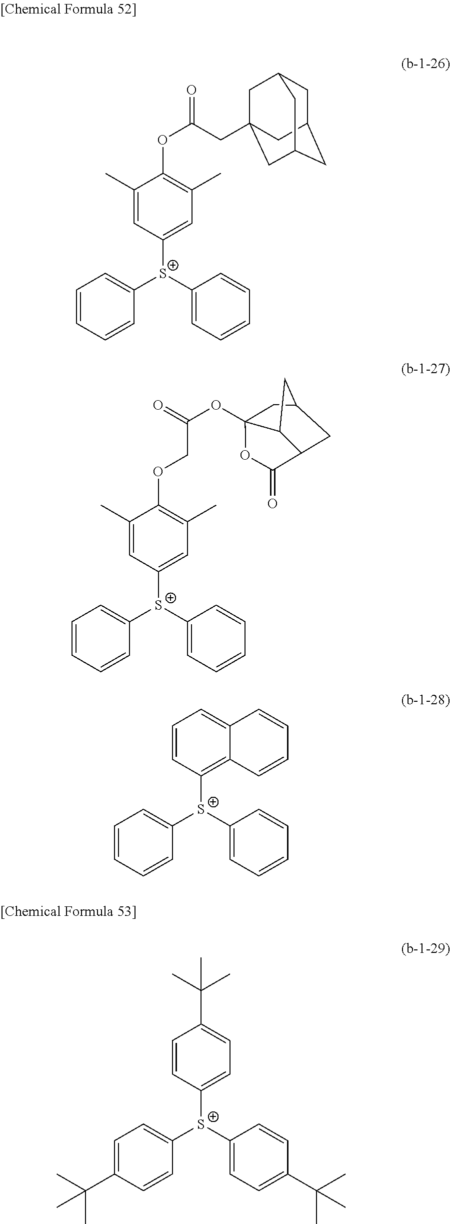

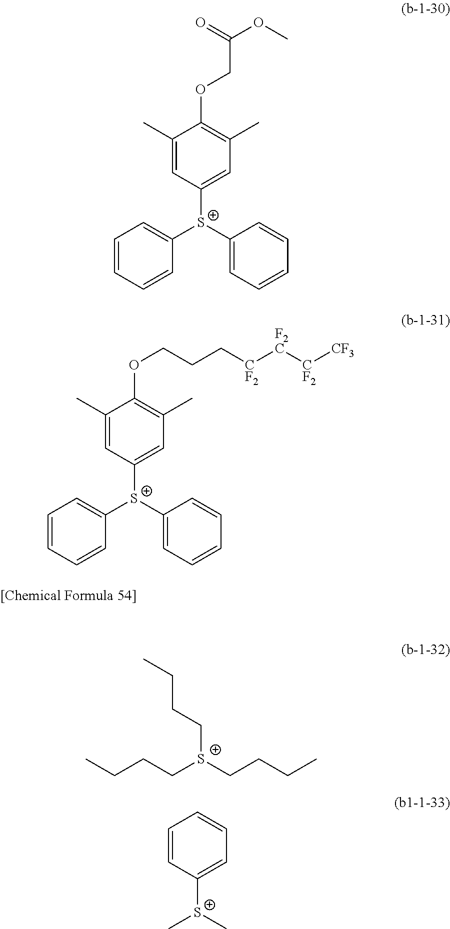

In the above formula (b-1), R⁴″ represents an alkyl group, halogenated alkyl group, aryl group or alkenyl group which may have a substituent.

The alkyl group for R⁴″ may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

As an example of the halogenated alkyl group for R⁴″, a group in which part of or all of the hydrogen atoms of the aforementioned linear, branched or cyclic alkyl group have been substituted with halogen atoms can be given. Examples of the aforementioned halogen atom include a fluorine atom, a chlorine atom, a bromine atom and an iodine atom, and a fluorine atom is preferable.

In the halogenated alkyl group, the percentage of the number of halogen atoms based on the total number of halogen atoms and hydrogen atoms (halogenation ratio (%)) is preferably 10 to 100%, more preferably 50 to 100%, and most preferably 100%. Higher halogenation ratios are preferable, as they result in increased acid strength.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X-Q¹-[in the formula, Q¹ represents a divalent linking group containing an oxygen atom; and X represents a hydrocarbon group of 3 to 30 carbon atoms which may have a substituent].

Examples of halogen atoms and alkyl groups as substituents for R⁴″ include the same halogen atoms and alkyl groups as those described above with respect to the halogenated alkyl group for R⁴″.

Examples of hetero atoms include an oxygen atom, a nitrogen atom, and a sulfur atom.

In the group represented by formula X-Q¹-, Q¹ represents a divalent linking group containing an oxygen atom.

Q¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amido bond (—C(═O)—NH—), a carbonyl group (—C(═O)—) and a carbonate bond (—O—C(═O)—O—); and combinations of the aforementioned non-hydrocarbon, hetero atom-containing linking groups with an alkylene group.

Specific examples of the combinations of the aforementioned non-hydrocarbon, hetero atom-containing linking groups and an alkylene group include —R⁹¹—O—, —R⁹²—O—C(═O)—, —C(═O)—O—R⁹³—O—C(═O)— (in the formulas, each of R⁹¹ to R⁹³ independently represents an alkylene group).

The alkylene group for R⁹¹ to R⁹³ is preferably a linear or branched alkylene group, and preferably has 1 to 12 carbon atoms, more preferably 1 to 5 carbon atoms, and most preferably 1 to 3 carbon atoms.

Specific examples of alkylene groups include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

Q¹ is preferably a divalent linking group containing an ester bond or ether bond, and more preferably a group represented by —R⁹¹—O—, —R⁹²—O—C(═O)— or —C(═O)—O—R⁹³—O—C(═O)—.

In the group represented by the formula X-Q¹-, the hydrocarbon group for X may be either an aromatic hydrocarbon group or an aliphatic hydrocarbon group.

The aromatic hydrocarbon group is a hydrocarbon group having an aromatic ring. The aromatic hydrocarbon group preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an arylalkyl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2 carbon atoms, and most preferably 1 carbon atom.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned hetero atom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly desirable.

The alkoxy group as the sub stituent for the aromatic hydrocarbon group is preferably an alkoxy group having 1 to 5 carbon atoms, more preferably a methoxy group, an ethoxy group, a n-propoxy group, an iso-propoxy group, a n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X, there is no particular limitation as long as it is an atom other than carbon and hydrogen. Examples of hetero atoms include a halogen atom, an oxygen atom, a sulfur atom and a nitrogen atom. Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting part of the carbon atoms include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, the aliphatic hydrocarbon group may contain any of these sub stituent groups in the ring structure.

Examples of the substituent group for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, a n-propoxy group, an iso-propoxy group, a n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15 carbon atoms, and most preferably 1 to 10 carbon atoms. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

Examples of the aliphatic cyclic group include groups in which one or more hydrogen atoms have been removed from a monocycloalkane, and groups in which one or more hydrogen atoms have been removed from a polycycloalkane such as a bicycloalkane, tricycloalkane or tetracycloalkane. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing sub stituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

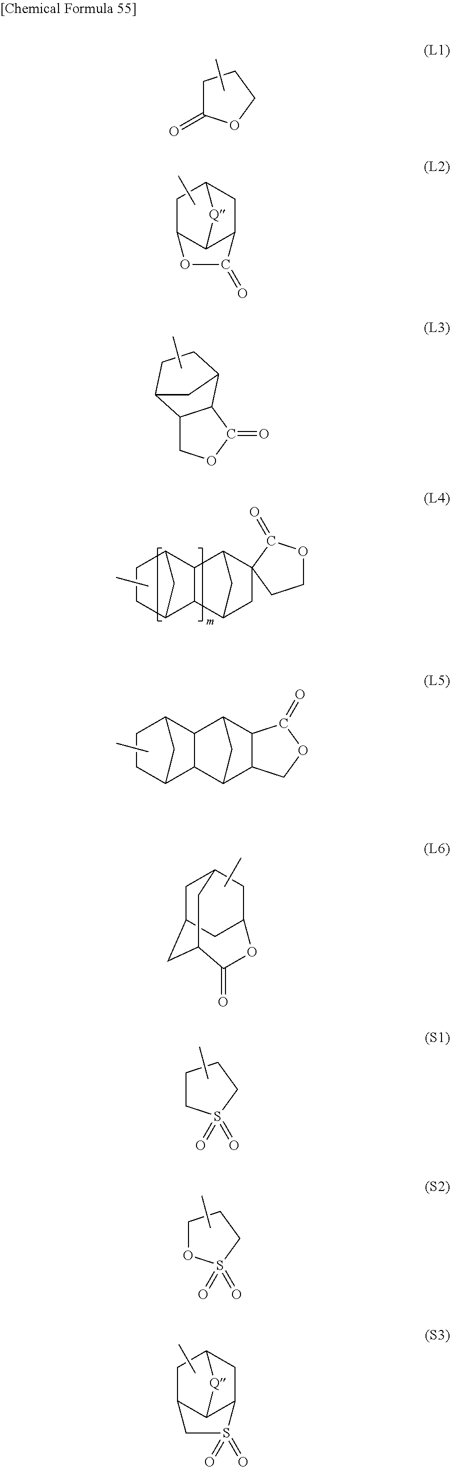

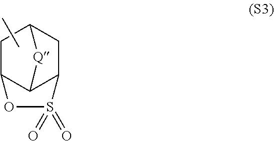

In the formulas, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms); and m represents an integer of 0 or 1.

As the alkylene group for Q″, R⁹⁴ and R⁹⁵, the same alkylene groups as those described above for R⁹¹ to R⁹³ can be used.

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

In the present invention, X is preferably a cyclic group which may have a substituent. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a group having no benzene rings, that is, a group having no naphthyl group or phenyl group is preferable.

As the aliphatic cyclic group which may have a substituent, an aliphatic polycyclic group which may have a sub stituent is preferable. As the aliphatic polycyclic group, the aforementioned group in which one or more hydrogen atoms have been removed from a polycycloalkane, and groups represented by the aforementioned formulas (L2) to (L6), (S3) and (S4) are preferable.

In the present invention, R⁴″ preferably has X-Q¹- as a substituent. In such a case, R⁴″ is preferably a group represented by the formula X-Q¹-Y¹— [in the formula, Q¹ and X are the same as defined above; and Y¹ represents an alkylene group of 1 to 4 carbon atoms which may have a substituent, or a fluorinated alkylene group of 1 to 4 carbon atoms which may have a sub stituent].

In the group by the formula X-Q¹-Y¹—, as the alkylene group for Y¹, the same alkylene group as those described above for Q¹ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y¹ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

Y¹ is preferably a fluorinated alkylene group, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of sub stituents which the alkylene group or fluorinated alkylene group may have include an alkyl group of 1 to 4 carbon atoms, an alkoxy group of 1 to 4 carbon atoms, and a hydroxyl group.

In formula (b-2), R⁵″ and R⁶″ each independently represents an aryl group or an alkyl group. At least one of R⁵″ and R⁶″ represents an aryl group. It is preferable that one of R⁵″ and R⁶″ represent an aryl group.

As the aryl group for R⁵″ and R⁶″, the same aryl groups as those described above for R¹″ to R³″ can be used.

As the alkyl group for R⁵″ and R⁶″, the same alkyl groups as those described above for R¹″ to R³″ can be used.

Specific examples of the cation moiety of the compound represented by general formula (b-2) include diphenyliodonium and bis(4-tert-butylphenyl)iodonium.

As R⁴″ in the above formula (b-2), the same groups as those mentioned above for R⁴″ in formula (b-1) can be used.

Specific examples of suitable onium salt-based acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts is replaced by an alkyl sulfonate, such as methanesulfonate, n-propanesulfonate, n-butanesulfonate, n-octanesulfonate, 1-adamantanesulfonate, 2-norbornanesulfonate or d-camphor-10-sulfonate; or replaced by an aromatic sulfonate, such as benzenesulfonate, perfluorobenzenesulfonate or p-toluenesulfonate.

Furthermore, onium salts in which the anion moiety of these onium salts are replaced by an anion moiety represented by any one of formulas (b1) to (b7) shown below can also be used.

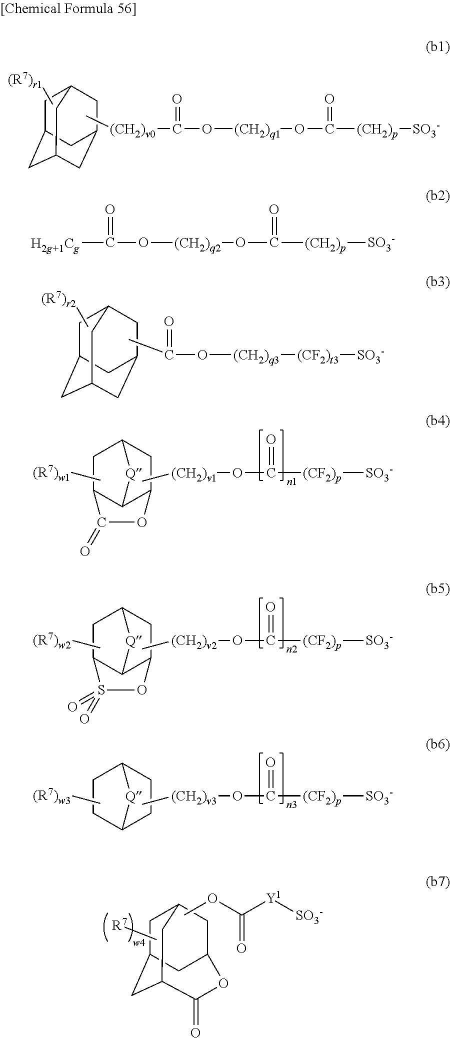

In the formulas, p represents an integer of 1 to 3; each of q1 and q2 independently represents an integer of 1 to 5; q3 represents an integer of 1 to 12; t3 represents an integer of 1 to 3; each of r1 and r2 independently represents an integer of 0 to 3; g represents an integer of 1 to 20; R⁷ represents a substituent; each of n1 to n4 independently represents 0 or 1; each of v0 to v3 independently represents an integer of 0 to 3; each of w1 to w4 independently represents an integer of 0 to 3; and Y¹ and Q″ are the same as defined above.

As the substituent for R⁷, the same groups as those which the aforementioned aliphatic hydrocarbon group for X may have as a substituent can be used.

If there are two or more of the R⁷ group, as indicated by the values r1, r2, and w1 to w4, then the two or more of the R⁷ groups may be the same or different from each other.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may be used.

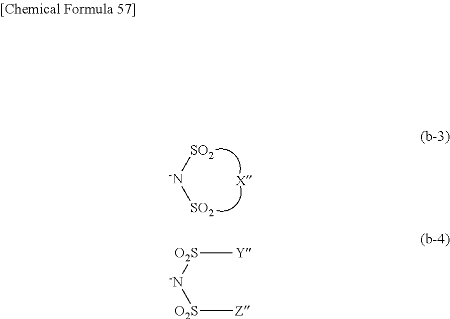

In the formulas, X″ represents an alkylene group of 2 to 6 carbon atoms in which at least one hydrogen atom has been substituted with a fluorine atom; and each of Y″ and Z″ independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to EUV light is improved. The fluorination ratio of the alkylene group or alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

Further, an onium salt-based acid generator in which the anion moiety (R⁴″SO₃⁻) in general formula (b-1) or (b-2) has been replaced with R^{a}—COO⁻ [in the formula, R^{a} represents an alkyl group or a fluorinated alkyl group] (and the cation moiety is the same as cation moiety within formula (b-1) or (b-2)) may also be used as the onium salt-based acid generator.

In the formula above, as R^{a}, the same groups as those described above for R⁴″ can be used.

Specific examples of the group represented by the formula “R^{a}—COO⁻” include a trifluoroacetic acid ion, an acetic acid ion, and a 1-adamantanecarboxylic acid ion.

Furthermore, as an onium salt-based acid generator, a sulfonium salt having a cation moiety represented by general formula (b-5) or (b-6) shown below may also be used.

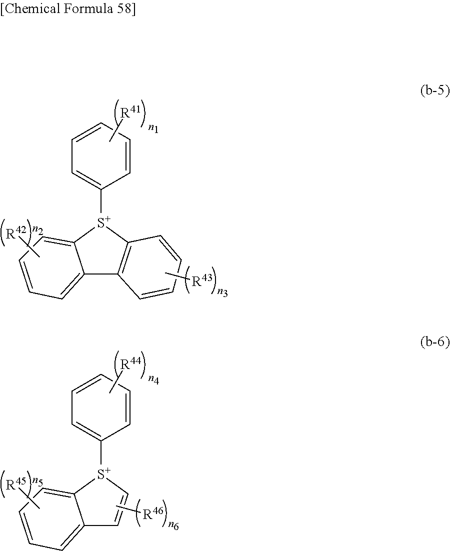

In formulas (b-5) and (b-6) above, each of R⁴¹ to R⁴⁶ independently represents an alkyl group, an acetyl group, an alkoxy group, a carboxy group, a hydroxyl group or a hydroxyalkyl group; each of n₁ to n₅ independently represents an integer of 0 to 3; and n₆ represents an integer of 0 to 2.

With respect to R⁴¹ to R⁴⁶, the alkyl group is preferably an alkyl group of 1 to 5 carbon atoms, more preferably a linear or branched alkyl group, and most preferably a methyl group, an ethyl group, a propyl group, an isopropyl group, a n-butyl group or a tert butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁴¹ to R⁴⁶ group, as indicated by the corresponding value of n₁ to n₆, then the two or more of the individual R⁴¹ to R⁴⁶ group may be the same or different from each other.

n₁ is preferably 0 to 2, more preferably 0 or 1, and still more preferably 0.

It is preferable that n₂ and n₃ each independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Examples of the cation represented by the above formula (b-5) or (b-6) include the cations shown below.

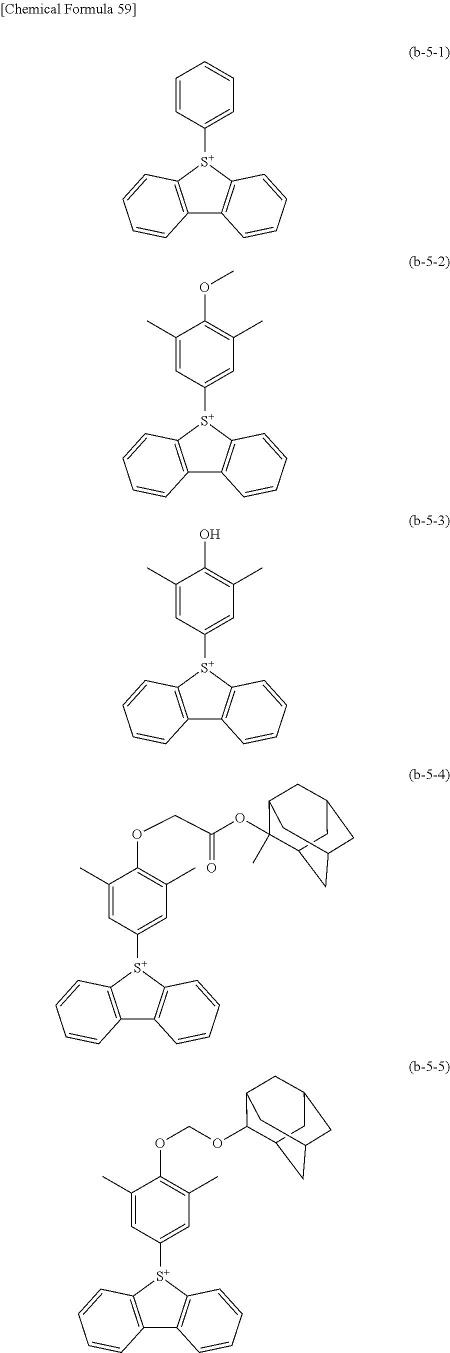

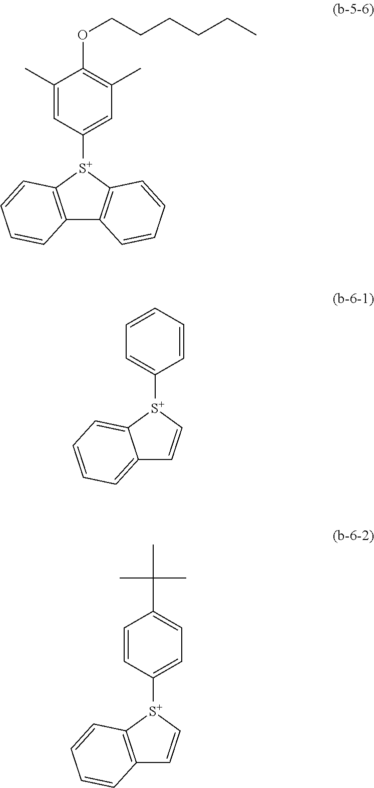

Furthermore, a sulfonium salt having a cation represented by general formula (b-7) or (b-8) shown below as the cation moiety may also be used.

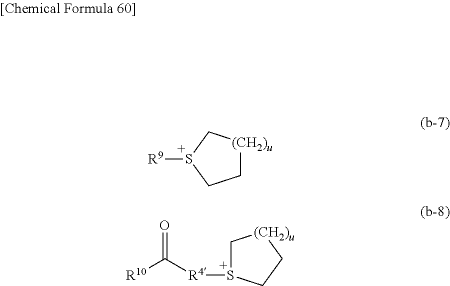

In formulas (b-7) and (b-8) shown below, each of R⁹ and R¹⁰ independently represents a phenyl group or naphthyl group which may have a sub stituent, an alkyl group of 1 to 5 carbon atoms, an alkoxy group or a hydroxyl group. Examples of the substituent are the same as the substituents described above in relation to the substituted aryl group for R¹″ to R³″ (i.e., an alkyl group, an alkoxy group, an alkoxyalkyloxy group, an alkoxycarbonylalkyloxy group, a halogen atom, a hydroxyl group, an oxo group (═O), an aryl group, —C(═O)—O—R⁶′, —O—C(═O)—R⁷′, —O—R⁸′, a group in which R⁵⁶ in the aforementioned general formula —O—R⁵⁰—C(═O)—O—R⁵⁶ has been substituted with R⁵⁶′).

R⁴′ represents an alkylene group of 1 to 5 carbon atoms.

u represents an integer of 1 to 3, and is most preferably 1 or 2.

Preferable examples of the cation represented by the above formula (b-7) or (b-8) include the cations shown below. In the formulas, R^{c} is the same as the substituents described above in relation to the substituted aryl group (i.e., an alkyl group, an alkoxy group, an alkoxyalkyloxy group, an alkoxycarbonylalkyloxy group, a halogen atom, a hydroxyl group, an oxo group (═O), an aryl group, —C(═O)—O—R⁶′, —O—C(═O)—R⁷′ and —O—R⁸′).

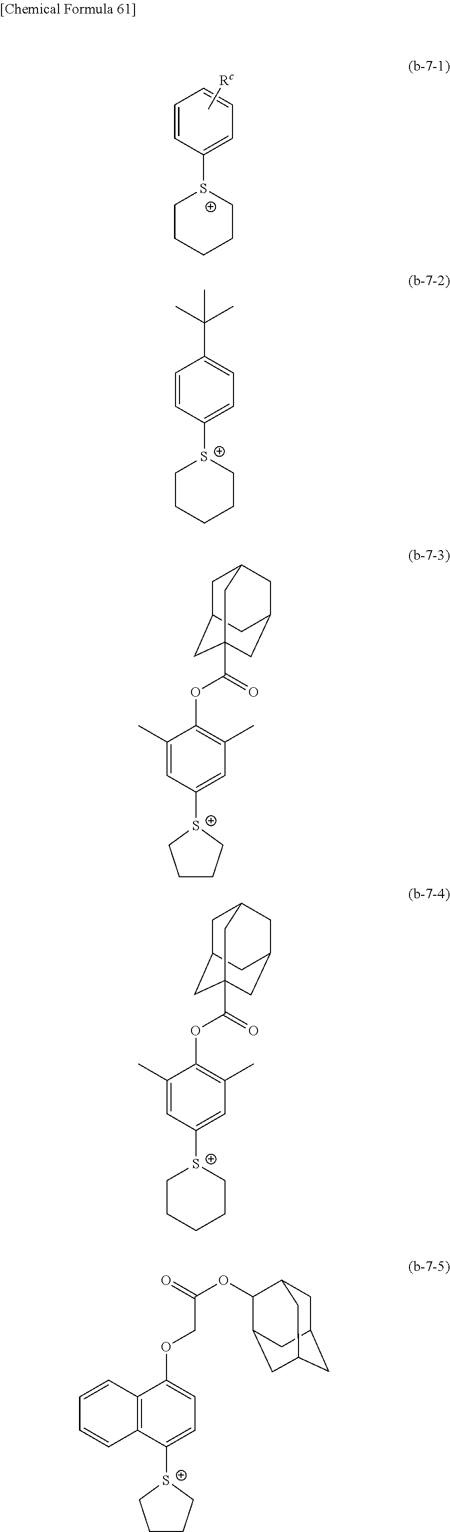

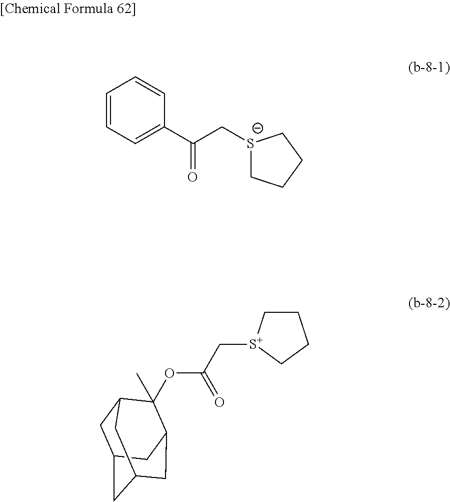

The anion moiety of the sulfonium salt having a cation represented by general formulas (b-5) to (b-8) for the cation moiety is not particularly limited, and the same anion moieties for onium salt-based acid generators which have been proposed may be used. Examples of such anion moieties include fluorinated alkylsulfonic acid ions such as anion moieties (R⁴″SO₃⁻) for onium salt-based acid generators represented by general formula (b-1) or (b-2) shown above; anion moieties represented by general formula (b-3) or (b-4) shown above; and anion moieties represented by any one of formulas (b1) to (b7) shown above.

In the present description, an oxime sulfonate-based acid generator is a compound having at least one group represented by general formula (B-1) shown below, and has a feature of generating acid by irradiation. Such oxime sulfonate acid generators are widely used for a chemically amplified resist composition, and can be appropriately selected.

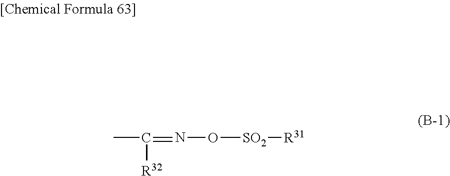

In formula (B-1), each of R³¹ and R³² independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

Examples of the organic group for R³¹ include a linear, branched, or cyclic alkyl group or aryl group, and a linear, branched, or cyclic alkyl group is preferable. The alkyl group or the aryl group may have a substituent. The substituent is not particularly limited, and examples thereof include a fluorine atom and a linear, branched, or cyclic alkyl group having 1 to 6 carbon atoms. The expression that the alkyl group or aryl group “may have a substituent” means that some or all of the hydrogen atoms of the alkyl group or aryl group may be substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, a partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

Examples of the organic group for R³² include a linear, branched, or cyclic alkyl group, an aryl group or a cyano group, and a linear, branched, or cyclic alkyl group or a cyano group is preferable. Examples of the alkyl group and the aryl group for R³² include the same alkyl groups and aryl groups as those described above for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below.

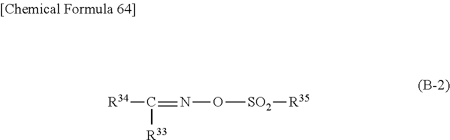

In the formula, R³³ represents a cyano group, an alkyl group having no substituent or a halogenated alkyl group; R³⁴ represents an aryl group; and R³⁵ represents an alkyl group having no substituent or a halogenated alkyl group.

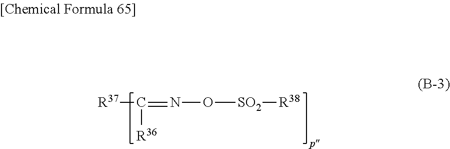

In the formula, R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the sub stituent preferably has 1 to 8 carbon atoms, and more preferably 1 to 4 carbon atoms. Further, the halogenated alkyl group is preferably a fluorinated alkyl group.

The alkyl group having no sub stituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

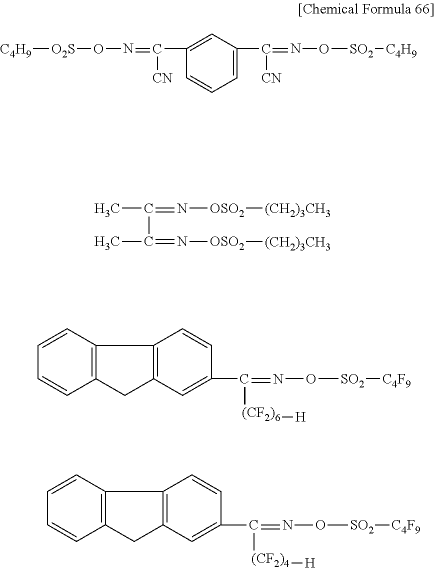

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may also be used.

Furthermore, as examples of poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be given.

As the component (B), one type of acid generator may be used alone, or two or more types of acid generators may be used in combination.

The component (B) in the present invention is preferably an acid generator (hereafter, referred to as “component (B1)”) represented by any one of general formulas (B1-1) to (B1-7) shown below in which the number of benzene rings within the skeletons of cation moiety and anion moiety. In other words, those having a diphenyl skeleton are more preferable than those having a triphenyl skeleton, and those having no benzene ring are particularly desirable.

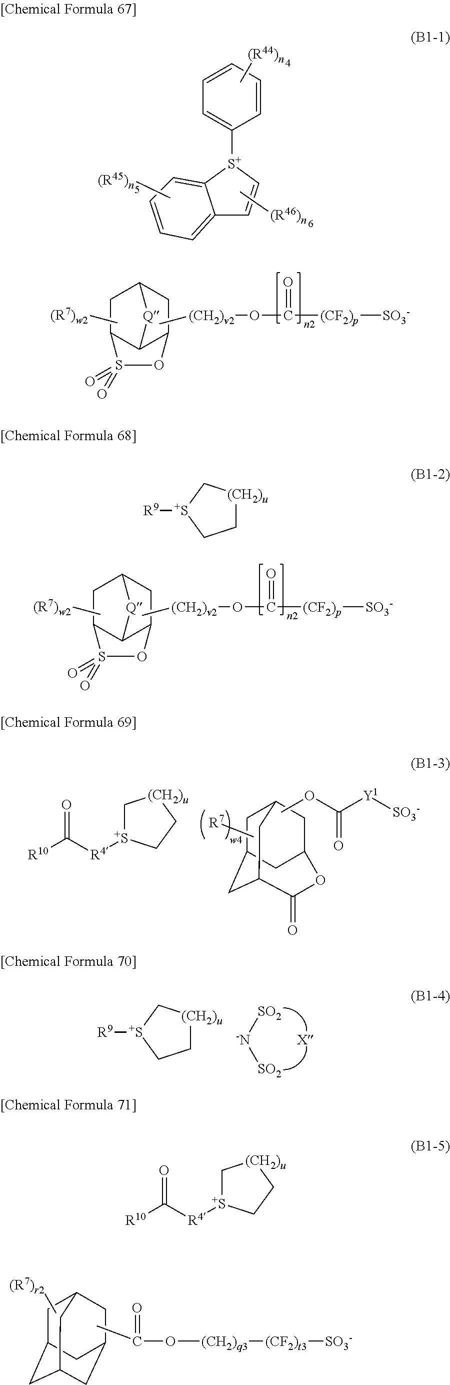

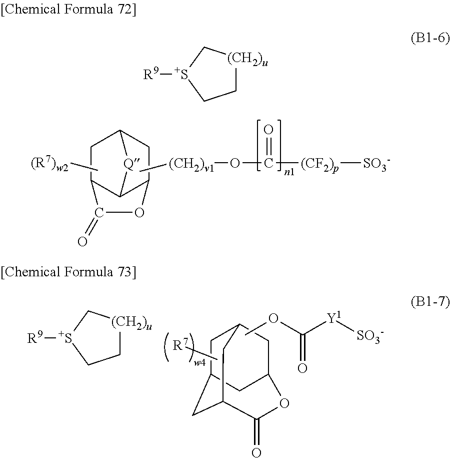

In the above formulas, R⁴′, R⁷, R⁹, R¹⁰, R⁴⁴, R⁴⁵, R⁴⁶, n1, n2, n4 to n6, p, v1, v2, w1, w2, w4, Q″, u, Y′, X″, r2, q3 and t3 are the same as defined above.

Further, an acid generator having a triphenyl skeleton and/or dinaphthyl skeleton (hereafter, referred to as “component (B2)) may also be included as the component (B), as long as the effects of the present invention are not lost. As the acid generator having a triphenyl skeleton and/or dinaphthyl skeleton, for example, an acid generator represented by general formulas (B2-8) to (B2-11) shown below can be used. In general formulas shown below, R⁷, n2, p, v2, w2, w4, Q″, Y¹ and X″ are the same as defined above.

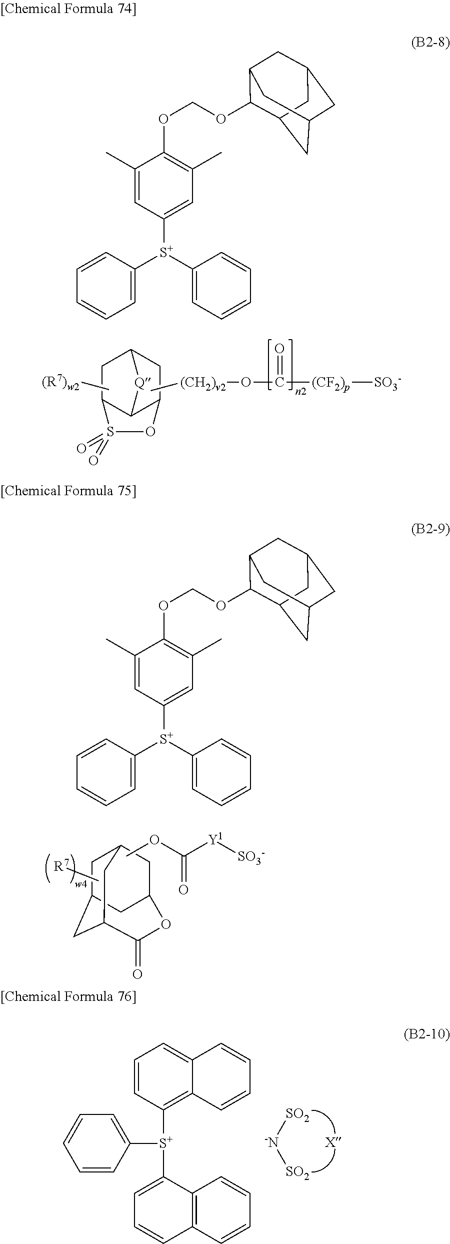

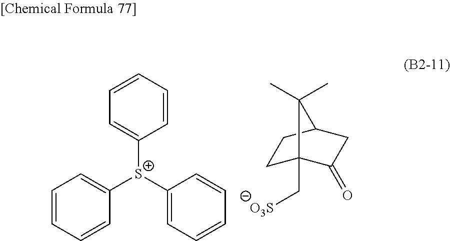

With respect to the ratio of the aforementioned component (B1) and the aforementioned component (B2) in the component (B), when assuming the combined total of the component (B1) and the component (B2) accounts for 100 mol %, the percentage of the component (B2) is preferably not more than 60 mol %, and more preferably not more than 50 mol %.

The total amount of the component (B) within the resist composition for EUV according to the present invention is preferably from 0.5 to 60 parts by weight, and more preferably from 10 to 50 parts by weight, relative to 100 parts by weight of the component (A). When the amount of the component (B) is within the above-mentioned range, formation of a resist pattern can be satisfactorily performed. Further, by virtue of the above-mentioned range, a uniform solution can be obtained and the storage stability becomes satisfactory.

### <Optional Component—Component (D)>

The resist composition for EUV according to the present invention may further contain a nitrogen-containing organic compound (D) (hereafter referred to as the component (D)) as an optional component.

As the component (D), there is no particular limitation as long as it functions as an acid diffusion control agent, i.e., a quencher which traps the acid generated from the component (B) upon exposure. A multitude of these components (D) have already been proposed, and any of these known compounds may be used, although an aliphatic amine, and particularly a secondary aliphatic amine or tertiary aliphatic amine is preferable. An aliphatic amine is an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of no more than 20 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, tri-n-octanolamine, stearyldiethanolamine and lauryldiethanolamine. Among these, trialkylamines and/or alkylalcoholamines are preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of aromatic amines include aniline, pyridine, 4-dimethylaminopyridine, pyrrole, indole, pyrazole, imidazole and derivatives thereof, as well as diphenylamine, triphenylamine and tribenzylamine.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

These compounds can be used either alone, or in combinations of two or more different compounds.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

### <Optional Component—Component (E)>

Furthermore, in the resist composition for EUV according to the present invention, for preventing any deterioration in sensitivity, and improving the resist pattern shape and the post exposure stability of the latent image formed by the pattern-wise exposure of the resist layer, at least one compound (E) (hereafter referred to as “component (E)”) selected from the group consisting of an organic carboxylic acid, or a phosphorus oxo acid or derivative thereof can be added as an optional component.

Examples of suitable organic carboxylic acids include acetic acid, malonic acid, citric acid, malic acid, succinic acid, benzoic acid, and salicylic acid.

Examples of phosphorus oxo acids or derivatives thereof include phosphoric acid, phosphonic acid and phosphinic acid. Among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

As the component (E), an organic carboxylic acid is preferable.

The component (E) is typically used in an amount within a range from 0.01 to 5.0 parts by weight, relative to 100 parts by weight of the component (A).

If desired, other miscible additives can also be added to the resist composition for EUV according to the present invention. Examples of such miscible additives include additive resins for improving the performance of the resist film, surfactants for improving the applicability, dissolution inhibitors, plasticizers, stabilizers, colorants, halation prevention agents, and dyes.

### <Optional Component—Component (S)>

The resist composition for EUV according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone;

ketones such as acetone, methyl ethyl ketone, cyclohexanone, methyl-n-pentyl ketone, methyl isopentyl ketone, and 2-heptanone;

polyhydric alcohols, such as ethylene glycol, diethylene glycol, propylene glycol and dipropylene glycol;

compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable);

cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate;

and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These organic solvents can be used individually, or in combination as a mixed solvent.

Among these, propylene glycol monomethyl ether acetate (PGMEA), propylene glycol monomethyl ether (PGME), ethyl lactate (EL) and cyclohexanone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range from 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3.

Alternatively, when cyclohexanone is mixed as the polar solvent, the PGMEA:cyclohexanone weight ratio is preferably from 1:9 to 9:1, more preferably from 2:8 to 8:2, and still more preferably 3:7 to 7:3. Further, the PGMEA:PGME:cyclohexanone weight ratio is preferably (2 to 9):(0 to 5):(0 to 4.5), and more preferably (3 to 9):(0 to 4):(0 to 3.5).

Further, as the component (S), a mixed solvent of at least one of PGMEA, EL and any of the aforementioned mixed solvents with γ-butyrolactone is also preferable. The mixing ratio (former:latter) of such a mixed solvent is preferably from 70:30 to 95:5.

The amount of the organic solvent is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, and preferably from 1 to 15% by weight.

Dissolving of the components to be added to the resist composition in the component (S) can be conducted, for example, by simply mixing and stirring each of the above components together using conventional methods, and where required, the composition may also be mixed and dispersed using a dispersion device such as a dissolver, a homogenizer, or a triple roll mill. Furthermore, following mixing, the composition may also be filtered using a mesh, or a membrane filter or the like.

According to the resist composition for EUV of the present invention, it is possible to form a resist film that is highly sensitive to the EUV light while exhibiting a low sensitivity to the DUV light. Further, the resist composition for EUV according to the present invention improves various lithography properties, such as LWR, and the pattern shape.

In order to obtain the above effects, it is essential that E0_{KrF} (which is a minimum exposure dose of a KrF light of 248 nm required to completely dissolve the aforementioned resist film by exposure and developing using the KrF light) is greater than E0_{EUV} (which is a minimum exposure dose of an EUV light of 13.5 nm required to completely dissolve the aforementioned resist film by exposure and developing using the EUV light).

Further, in order to improve such effects, the aforementioned E0_{KrF} is preferably at least 1.2 times as large as the aforementioned E0_{EUV}.

It is thought that because the resist composition for EUV according to the present invention exhibits low sensitivity to the DUV light which is particularly problematic among the OoB light, a decrease in the image contrast at the time of EUV exposure is suppressed, thereby improving the lithography properties and the pattern shape.

### <<Method of Producing Resist Composition for EUV>>

Next, a method of producing a resist composition for EUV according to the second aspect of the present invention will be described.

The method of producing a resist composition for EUV according to the present invention includes a step of preparing a resist composition so that E0_{KrF} (which is a sensitivity to KrF light of 248 nm) is greater than E0_{EUV} (which is a sensitivity to EUV light).

More specifically, the method of producing a resist composition for EUV according to the second aspect of the present invention is a method of producing a resist composition for EUV for forming a resist film which is used in EUV lithography, and includes a step of preparing the aforementioned resist composition so that E0_{KrF} (which is a minimum exposure dose of a KrF light of 248 nm required to completely dissolve the aforementioned resist film by exposure and developing of the resist film using the aforementioned KrF light) is greater than E0_{EUV} (which is a minimum exposure dose of an EUV light of 13.5 nm required to completely dissolve the aforementioned resist film by exposure and developing of the resist film using the aforementioned EUV light).

This production method is not particularly limited as long as the step of preparing a resist composition so that the aforementioned E0_{KrF} is greater than the aforementioned E0_{EUV} is included, and, for example, the resist composition described above in the section <<Resist composition for EUV>> can be used in this step.

By using the method of producing a resist composition for EUV according to the present invention, a resist composition for EUV provided with a property to exhibit low sensitivity to the DUV light and also exhibit high sensitivity to the EUV light can be obtained.

Furthermore, in order to improve such a property, it is preferable to prepare a resist composition so that the aforementioned E0_{KrF} is at least 1.2 times as large as the aforementioned E0_{EUV} in the above step.

### <<Method of Forming a Resist Pattern>>

Next, a method of forming a resist pattern according to a third aspect of the present invention will be described.

The method of forming a resist pattern according to the present invention includes applying the EUV composition according to the first aspect of the present invention to a substrate to form a resist film on the substrate, subjecting the resist film to EUV exposure, and subjecting the resist film to developing to form a resist pattern.

The method of forming a resist pattern according to the present invention can be performed, for example, as follows.

Firstly, a resist composition for EUV according to the present invention is applied onto a substrate using a spinner or the like, and a bake treatment (post applied bake (PAB)) is conducted at a temperature of 80 to 150° C. for 40 to 120 seconds, preferably 60 to 90 seconds, to form a resist film.

Subsequently, the thus formed resist film is subjected to selective exposure using an EUV exposure apparatus through a mask pattern (a mask where a predetermined pattern has been formed), and PEB (post exposure baking) is then conducted under temperature conditions of 80 to 150° C. for 40 to 120 seconds, preferably 60 to 90 seconds.

Next, the resist film is subjected to a developing treatment.

The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinse treatment, the developing solution or the rinse solution remaining on the pattern can be removed by a treatment using a supercritical fluid.

After the developing treatment or the rinse treatment, drying is conducted. If desired, a bake treatment (post bake) may be conducted following the above developing treatment. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which preferably have a boiling point within a range from 70 to 180° C. and more preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution to be used in the developing treatment in a solvent developing process, any of the solvents appropriately selected from amongst conventional organic solvents can be used which are capable of dissolving the component (A) (prior to exposure). More specifically, polar solvents such as ketone-based solvents, ester-based solvents, alcohol-based solvents, amide-based solvents and ether-based solvents, and hydrocarbon-based solvents can be used.

If required, known additives can be added to the organic developing solution. Examples of the additive include surfactants. The surfactant is not particularly limited, and for example, an ionic or nonionic fluorine-based surfactant and/or silicon-based surfactant can be used.

When a surfactant is added, the amount thereof based on the total amount of the developing solution is generally 0.001 to 5% by weight, preferably 0.005 to 2% by weight, and more preferably 0.01 to 0.5% by weight.

The developing treatment can be conducted using a known developing method. Examples of these methods include a method in which the substrate is immersed in the developing solution for a certain period of time (dipping method), a method in which the developing solution is accumulated by surface tension to remain still at the surface of the substrate for a certain period of time (puddle method), a method in which the developing solution is sprayed onto the surface of the substrate (spraying method), and a method in which a developing-solution ejecting nozzle ejects the developing solution continuously while scanning the substrate rotating at a constant rate so as to apply the developing solution onto the substrate (dynamic dispensing method).

As the organic solvent contained in the rinse liquid used in the rinse treatment after the developing treatment in the case of a solvent developing process, any of the aforementioned organic solvents contained in the developing solution can be used which hardly dissolves the resist pattern. In general, at least one type of solvent selected from the group consisting of hydrocarbon-based solvents, ketone-based solvents, ester-based solvents, alcohol-based solvents, amide-based solvents and ether-based solvents is used. Of these, at least one type of solvent selected from the group consisting of hydrocarbon-based solvents, ketone-based solvents, ester-based solvents, alcohol-based solvents and amide-based solvents is preferable, more preferably at least one type of solvent selected from the group consisting of alcohol-based solvents and ester-based solvents; and an alcohol-based solvent is particularly desirable.

The rinsing treatment (washing treatment) using the rinse solution can be conducted using a known rinse method. Examples of these methods include a method in which the rinse solution is continuously applied onto the substrate rotating at a constant speed (rotational coating method), a method in which the substrate is immersed in the rinse solution for a certain period of time (dipping method), and a method in which the rinse solution is sprayed onto the surface of the substrate (spraying method).

### EXAMPLES

As follows is a description of examples of the present invention, although the scope of the present invention is in no way limited by these examples.

### Examples 1 to 15, Comparative Examples 1 to 5

The components shown in Tables 1 and 2 were mixed together and dissolved to obtain positive resist compositions.

TABLE 1

| | Component (A) | Component (B) | | | Component (D) | Component (E) | Component (S) | |
|---|---|---|---|---|---|---|---|---|
| Comp. | (A)-1 | (B)-1 | — | (B)-14 | — | — | (S)-1 | (S)-2 |
| Ex. 1 | [100] | [38.6] | | [1.4] | | | [200] | [5,000] |
| Comp. | (A)-1 | (B)-1 | — | (B)-14 | — | — | (S)-1 | (S)-2 |
| Ex. 2 | [100] | [57.9] | | [2.1] | | | [200] | [5,000] |
| Comp. | (A)-1 | (B)-1 | (B)-2 | (B)-14 | — | — | (S)-1 | (S)-2 |
| Ex. 3 | [100] | [38.6] | [13.8] | [2.1] | | | [200] | [5,000] |
| Comp. | (A)-2 | (B)-3 | — | (B)-14 | — | — | (S)-1 | (S)-2 |
| Ex. 4 | [100] | [27.7] | | [1.4] | | | [200] | [5,000] |
| Comp. | (A)-3 | (B)-4 | (B)-5 | | (D)-1 | (E)-1 | (S)-3 | — |
| Ex. 5 | [100] | [14.7] | [12.5] | | [1.95] | [0.75] | [5,000] | |
| Ex. 1 | (A)-1 | (B)-2 | — | (B)-14 | — | — | (S)-1 | (S)-2 |
| | [100] | [27.6] | | [1.4] | | | [200] | [5,000] |
| Ex. 2 | (A)-1 | (B)-6 | — | (B)-14 | — | — | (S)-1 | (S)-2 |
| | [100] | [32.9] | | [1.4] | | | [200] | [5,000] |
| Ex. 3 | (A)-1 | (B)-2 | — | (B)-14 | — | — | (S)-1 | (S)-2 |
| | [100] | [41.4] | | [2.1] | | | [200] | [5,000] |
| Ex. 4 | (A)-1 | (B)-6 | — | (B)-14 | — | — | (S)-1 | (S)-2 |
| | [100] | [49.35] | | [2.1] | | | [200] | [5,000] |
| Ex. 5 | (A)-1 | (B)-1 | (B)-6 | (B)-14 | — | — | (S)-1 | (S)-2 |
| | [100] | [38.6] | [16.45] | [2.1] | | | [200] | [5,000] |

TABLE 2

| | Component (A) | Component (B) | | | Component (D) | Component (E) | Component (S) | |
|---|---|---|---|---|---|---|---|---|
| Ex. 6 | (A)-1 | (B)-1 | (B)-6 | (B)-14 | — | — | (S)-1 | (S)-2 |
| | [100] | [19.3] | [32.9] | [2.1] | | | [200] | [5,000] |
| Ex. 7 | (A)-1 | (B)-1 | (B)-2 | (B)-14 | — | — | (S)-1 | (S)-2 |
| | [100] | [19.3] | [27.6] | [2.1] | | | [200] | [5,000] |
| Ex. 8 | (A)-2 | (B)-7 | — | (B)-14 | — | — | (S)-1 | (S)-2 |
| | [100] | [28.5] | | [1.4] | | | [200] | [5,000] |
| Ex. 9 | (A)-2 | (B)-7 | — | (B)-14 | — | — | (S)-1 | (S)-2 |
| | [100] | [42.8] | | [2.1] | | | [200] | [5,000] |
| Ex. 10 | (A)-2 | (B)-8 | (B)-7 | (B)-14 | — | — | (S)-1 | (S)-2 |
| | [100] | [38.2] | [14.3] | [2.1] | | | [200] | [5,000] |
| Ex. 11 | (A)-2 | (B)-8 | (B)-7 | (B)-14 | — | — | (S)-1 | (S)-2 |
| | [100] | [19.1] | [28.5] | [2.1] | | | [200] | [5,000] |
| Ex. 12 | (A)-3 | (B)-4 | (B)-9 | — | (D)-1 | (E)-1 | (S)-3 | — |
| | [100] | [14.7] | [12.0] | | [1.95] | [0.75] | [5,000] | |
| Ex. 13 | (A)-3 | (B)-10 | — | — | (D)-1 | (E)-1 | (S)-3 | — |
| | [100] | [26.4] | | | [1.95] | [0.75] | [5,000] | |
| Ex. 14 | (A)-4 | (B)-11 | (B)-12 | — | (D)-1 | (E)-1 | — | (S)-2 |
| | [100] | [5.0] | [20.0] | | [1.5] | [0.6] | | [5,000] |
| Ex. 15 | (A)-5 | (B)-13 | — | (B)-14 | — | — | (S)-1 | (S)-2 |
| | [100] | [32.0] | | [2.0] | | | [200] | [5,000] |

In Tables 1 and 2, the reference characters indicate the following. Further, the values in brackets [ ] indicate the amount (in terms of parts by weight) of the component added.

(A)-1 to (A)-5: polymeric compounds (A)-1 to (A)-5 shown below.

(B)-1 to (B)-14: compounds (B)-1 to (B)-14 shown below.

(D)-1: tri-n-octylamine.

(E)-1: salicylic acid.

(S)-1: γ-butyrolactone.

(S)-2: a mixed solvent of PGMEA/PGME/cyclohexanone=2,250/1,500/1,250 (weight ratio).

(S)-3: a mixed solvent of PGMEA/PGME=3,000/2,000 (weight ratio).

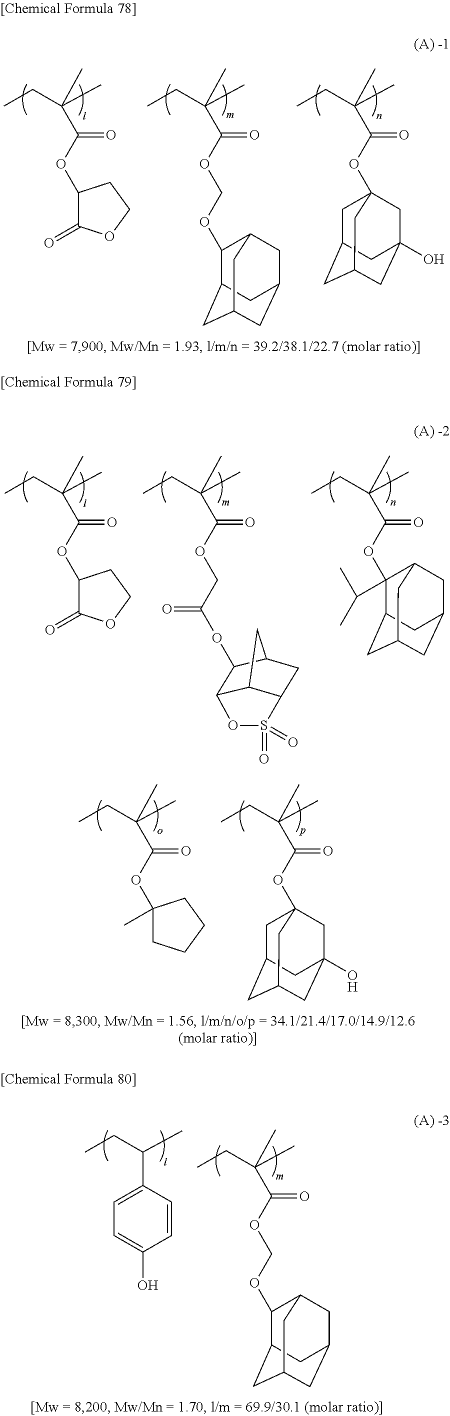

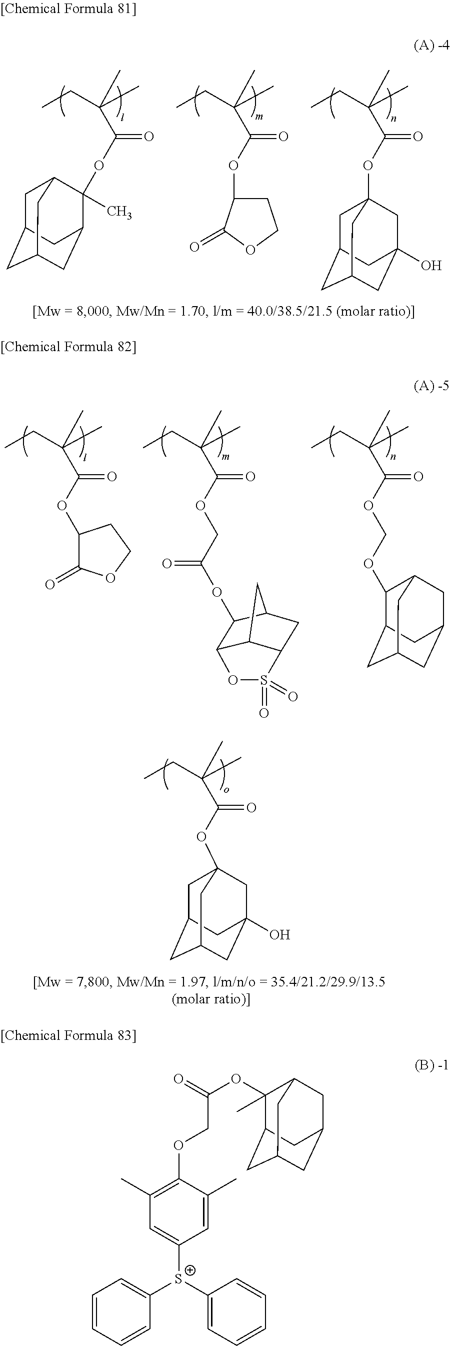

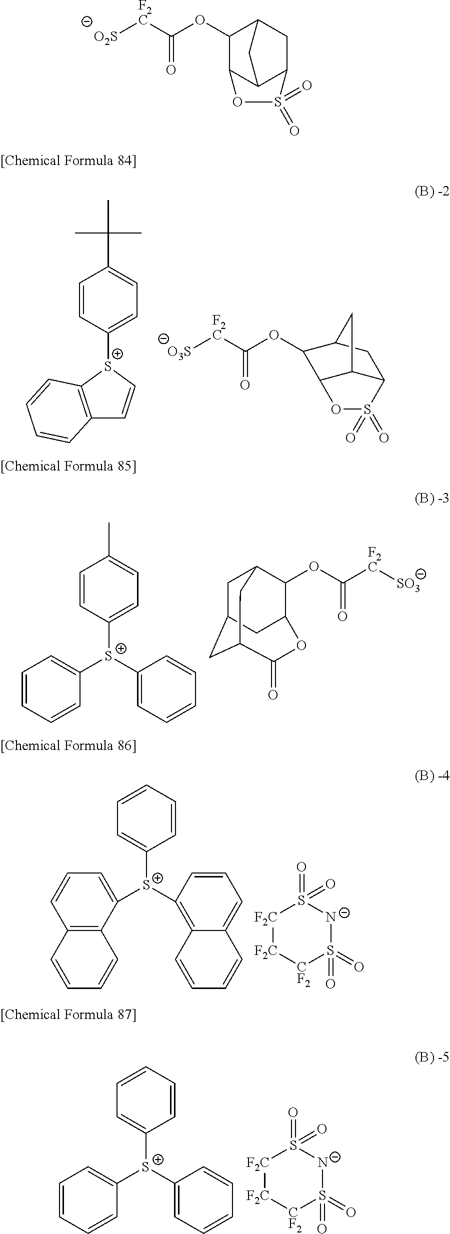

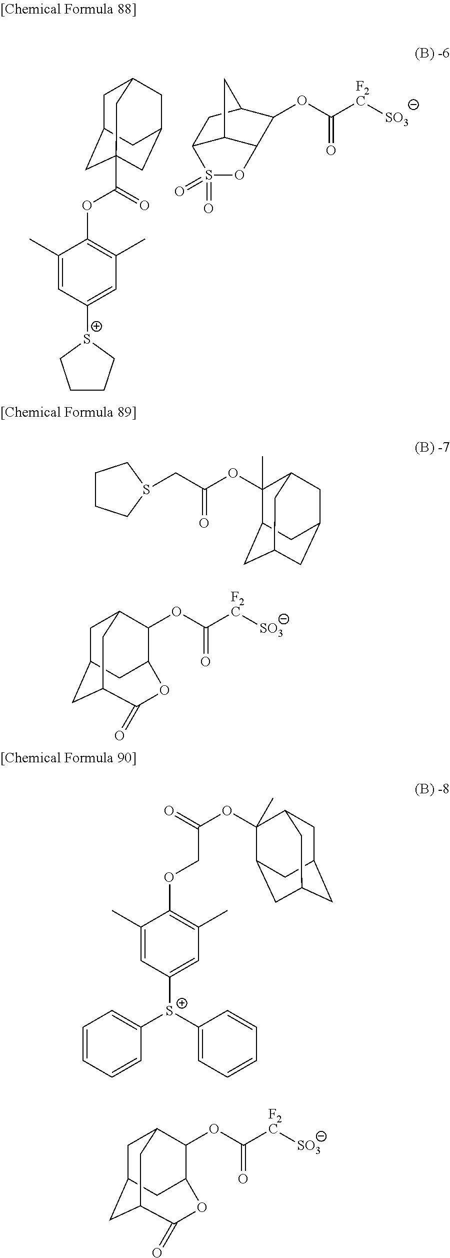

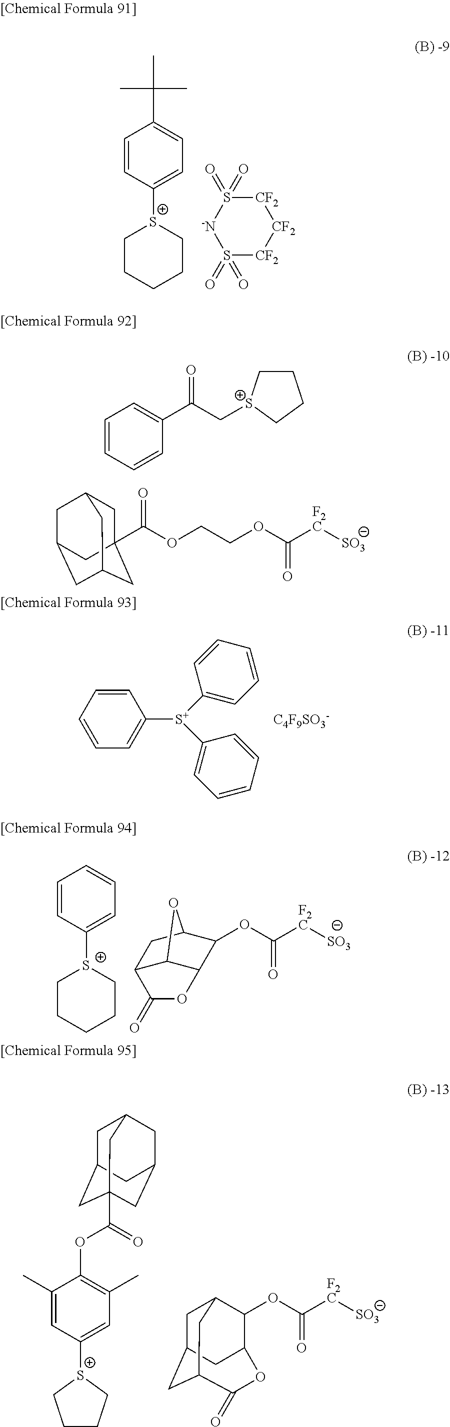

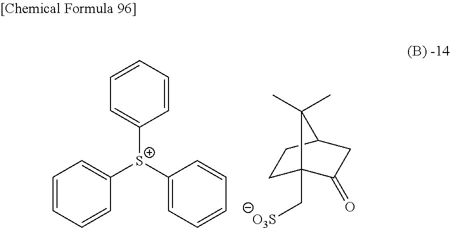

### <Evaluation of Lithography Properties and Resist Pattern Shape>

Using the obtained positive resist compositions, resist patterns were formed in the following manner, and the following evaluations were conducted.

### [Formation of Resist Pattern]

A lower-layer film composition (product name: BSI. X07333, manufactured by Brewer Science Ltd.) was applied onto an 8-inch silicon wafer using a spinner, and the composition was then baked and dried on a hotplate at 205° C. for 60 seconds, thereby forming a lower-layer film having a film thickness of 60 nm.

Then, the above positive resist composition was applied onto the lower-layer film using a spinner, and was then prebaked (PAB) on a hotplate at the PAB temperature indicated in Table 3 for 60 seconds and dried, thereby forming a resist film having a film thickness of 60 nm.

Subsequently, the resist film was selectively irradiated with the EUV light (13.5 nm) through a mask, using the Electron Mask Exposure Tool (eMET manufactured by Albany; NA (numerical aperture)=0.30, Quadrupole).

Thereafter, a post exposure bake (PEB) treatment was conducted under the PEB temperature indicated in Table 3 for 60 seconds, followed by alkali developing for 30 seconds at 23° C. in a 2.38% by weight aqueous solution of tetramethylammonium hydroxide (TMAH). Then, the resist film was rinsed for 30 seconds with pure water, and then spun dry.

As a result, in each of the examples, a line and space resist pattern (hereafter, referred to as “LS pattern”) in which lines having a line width of 30 nm were spaced at equal intervals (pitch: 60 nm) was formed on the resist film.

### [Evaluation of Line Width Roughness (LWR)]

With respect to the LS pattern having a line width of 30 nm and a pitch of 60 nm that was formed with the optimum exposure dose in accordance with the same procedure as described above for the formation of resist patterns, the space width at 400 points in the lengthwise direction of the space was measured using a measuring scanning electron microscope (SEM) (product name: S-9380, manufactured by Hitachi, Ltd.; acceleration voltage: 800V). From the results, the value of 3 times the standard deviation s (i.e., 3s) was determined, and the average of the 3s values at 5 points was calculated as a yardstick of LWR.

The results are shown in Table 3.

The smaller this 3s value is, the lower the level of roughness of the line width, indicating that a LS pattern with a uniform width was obtained.

### [Evaluation of Pattern Shape]

The cross-sectional shape of the LS pattern which was formed with the optimum exposure dose for forming the above 1:1 LS pattern having a line width of 30 nm was observed using a scanning electron microscope (product name: SU8000, manufactured by Hitachi, Ltd.), and the shape was evaluated in accordance with the following criteria. The results are shown in Table 3.

∘: favorable shape with high rectangularity.

x: Round top shape with low rectangularity.

### [E0_{KrF} (A1) Measurement]

Using a spinner, the prepared resist composition was applied onto an 8-inch silicon substrate that had been surface-treated with hexamethyldisilazane (HMDS) for 36 seconds at 90° C., and a prebake (PAB) was then conducted for 60 seconds at the PAB temperature indicated in Table 3, thereby forming a resist film having a film thickness of 60 nm.

Subsequently, the resist film was subjected to exposure using a KrF exposure apparatus NSR-S203B (manufactured by Nikon Corporation; NA (numerical aperture)=0.68, σ=0.75). Thereafter, a post exposure bake (PEB) treatment was conducted at the PEB temperature indicated in Table 3 for 60 seconds, followed by development for 60 seconds at 23° C. in a 2.38% by weight aqueous solution of tetramethylammonium hydroxide (TMAH). Then, the resist film was rinsed for 30 seconds with pure water, and then spun dry. The minimum exposure dose at which the resist film disappeared was measured as the E0_{KrF} sensitivity (A1). The results are shown in Table 3.

### [E0_{EUV} (A2) Measurement]

A lower-layer film composition (product name: BSI. X07333, manufactured by Brewer Science Ltd.) was applied onto an 8-inch silicon wafer using a spinner, and the composition was then baked and dried on a hotplate at 205° C. for 60 seconds, thereby forming a lower-layer film having a film thickness of 60 nm.

Then, the above positive resist composition was applied onto the lower-layer film using a spinner, and was then prebaked (PAB) on a hotplate at the PAB temperature indicated in Table 3 for 60 seconds and dried, thereby forming a resist film having a film thickness of 60 nm.

Subsequently, the resist film was subjected to exposure using the Electron Mask Exposure Tool (eMET manufactured by Albany; NA (numerical aperture)=0.30, Quadrupole).

Thereafter, a post exposure bake (PEB) treatment was conducted at the PEB temperature indicated in Table 3 for 60 seconds, followed by development for 60 seconds at 23° C. in a 2.38% by weight aqueous solution of tetramethylammonium hydroxide (TMAH). Then, the resist film was rinsed for 30 seconds with pure water, and then spun dry. The minimum exposure dose at which the resist film disappeared was measured as the E0_{EUV} sensitivity (A2). The results are shown in Table 3.

### [A1/A2]

The ratio of the aforementioned E0_{EUV} (A2) to the aforementioned E0_{KrF} (A1) was calculated as A1/A2. The results are shown in Table 3.

TABLE 3

| | PAB | PEB | A1:E0 at KrF | A2:E0 at KrF | | LWR | Pattern |
|---|---|---|---|---|---|---|---|
| | (° C.) | (° C.) | [mJ/cm²] | [mJ/cm²] | A1/A2 | (nm) | shape |
| Comp. | 100 | 90 | 6.0 | 6.2 | 0.97 | 7.5 | x |
| Ex. 1 | | | | | | | |
| Comp. | 100 | 90 | 3.5 | 5.3 | 0.66 | 9.1 | x |
| Ex. 2 | | | | | | | |
| Comp. | 100 | 90 | 4.5 | 5.1 | 0.88 | 7.7 | x |
| Ex. 3 | | | | | | | |
| Comp. | 110 | 90 | 5.5 | 6.0 | 0.92 | 8.0 | x |
| Ex. 4 | | | | | | | |
| Comp. | 120 | 100 | 4.5 | 6.0 | 0.75 | 9.0 | x |
| Ex. 5 | | | | | | | |
| Ex. 1 | 100 | 90 | 13.0 | 5.0 | 2.65 | 5.7 | ∘ |
| Ex. 2 | 100 | 90 | 49.0 | 14 | 3.45 | 5.2 | ∘ |
| Ex. 3 | 100 | 90 | 11.5 | 6.0 | 1.92 | 4.8 | ∘ |
| Ex. 4 | 100 | 90 | 43.0 | 11 | 3.87 | 4.5 | ∘ |
| Ex. 5 | 100 | 90 | 5.5 | 4.2 | 1.31 | 5.7 | ∘ |
| Ex. 6 | 100 | 90 | 12.5 | 8.0 | 1.49 | 4.0 | ∘ |
| Ex. 7 | 100 | 90 | 6.0 | 4.0 | 1.50 | 6.1 | ∘ |
| Ex. 8 | 110 | 90 | >50 | 10 | >5.0 | 5.0 | ∘ |
| Ex. 9 | 110 | 90 | >50 | 8.0 | >6.25 | 5.1 | ∘ |
| Ex. 10 | 110 | 90 | 12 | 4.4 | 2.73 | 4.5 | ∘ |
| Ex. 11 | 110 | 90 | 20 | 4.6 | 4.35 | 4.2 | ∘ |
| Ex. 12 | 120 | 100 | 8.0 | 6.2 | 1.29 | 6.0 | ∘ |
| Ex. 13 | 120 | 100 | 12 | 6.2 | 1.94 | 6.2 | ∘ |
| Ex. 14 | 120 | 110 | 7.0 | 4.0 | 1.75 | 6.1 | ∘ |
| Ex. 15 | 100 | 90 | 30 | 9.0 | 3.33 | 4.6 | ∘ |

From the results shown in Table 3, it was confirmed that the resist compositions of Examples 1 to 15 which had A1 values greater than the A2 values (i.e., the A1/A2 ratio was greater than 1) exhibited superior LWR and pattern shape, as compared to the resist compositions of Comparative Examples 1 to 5 which had A1 values smaller than the A2 values (i.e., the A1/A2 ratio was smaller than 1).

From the results shown above, it was confirmed that by using the resist composition for EUV according to the present invention, a resist pattern exhibiting excellent lithography properties and pattern shape can be formed in EUV lithography.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

What is claimed is:

1. A resist composition for EUV exhibiting E0_{KrF} greater E0_{EUV}, wherein E0_{KrF} is a sensitivity to KrF light of 248 nm, and E0_{EUV} is a sensitivity to EUV light.

2. The resist composition for EUV according to claim 1, wherein said E0_{KrF} is at least 1.2 times as large as said E0_{EUV}.

3. A method of producing the resist composition for EUV described in claim 1 or 2, comprising: preparing said resist composition so that E0_{KrF} is greater than E0_{EUV}, wherein E0_{KrF} is a sensitivity to KrF light of 248 nm, and E0_{EUV} is a sensitivity to EUV light.

4. A method of forming a resist pattern, comprising:
Applying the resist composition for EUV described in claim 1 or 2 to a substrate to form a resist film on the substrate;
conducting EUV exposure of said resist film; and
developing said resist film to form a resist pattern.
